(19) United States
(12) Patent Application Publication
(10) Pub. No.: US 2024/0147856 A1
(43) Pub. Date: May 2, 2024

(54) ORGANIC ELECTROLUMINESCENCE ELEMENT, METHOD FOR DESIGNING LUMINOUS COMPOSITION, AND PROGRAM

(71) Applicant: KYULUX, INC., Fukuoka-shi, Fukuoka (JP)

(72) Inventors: Shinya OTSU, Fukuoka-shi, Fukuoka (JP); Ayataka ENDO, Fukuoka-shi, Fukuoka (JP); Makoto YOSHIZAKI, Fukuoka-shi, Fukuoka (JP)

(21) Appl. No.: 18/263,778

(22) PCT Filed: Feb. 1, 2022
(86) PCT No.: PCT/JP2022/003800

§ 371 Date: Aug. 1, 2023

(30) Foreign Application Priority Data
Feb. 4, 2021 (JP) 2021-016209

(51) Int. Cl. H10K 85/60

(52) U.S. Cl. CPC H10K 85/658; H10K 85/624; H10K 85/633; H10K 85/654; H10K 85/6572; H10K 2101/30

(57) ABSTRACT

An organic electroluminescent device having a light emitting layer that contains the first to third compounds satisfying the following formulae has a low drive voltage and a high light emission efficiency. E_{S1}(1)>E_{S1}(2)>E_{S1}(3), E_{LUMO}(2)≤E_{LUMO}(3). E_{S1}(m) is the lowest excited singlet energy of the m'th compound, E_{LUMO}(n) is the LUMO energy of the n'th compound (m, n=1 to 3).

### TECHNICAL FIELD

The present invention relates to an organic electroluminescent device characterized by the light emitting layer thereof, and to a method for designing a light emitting composition, and a program.

### BACKGROUND ART

Studies for enhancing the light emission efficiency of light emitting devices such as organic electroluminescent devices (organic EL devices) are being made actively. In particular, various kinds of efforts have been made for increasing light emission efficiency by newly developing and combining an electron transporting material, a hole transporting material and a light emitting material to constitute an organic electroluminescent device. Among them, there is seen an organic electroluminescent device that utilizes a delayed fluorescent material.

A delayed fluorescent material is a material which, in an excited state, after having undergone reverse intersystem crossing from an excited triplet state to an excited singlet state, emits fluorescence when returning back from the excited singlet state to a ground state thereof. Fluorescence through the route is observed later than fluorescence from the excited singlet state directly occurring from the ground state (ordinary fluorescence), and is therefore referred to as delayed fluorescence. Here, for example, in the case where a light emitting compound is excited through carrier injection thereinto, the occurring probability of the excited singlet state to the excited triplet state is statistically 25%/75%, and therefore improvement of light emission efficiency by the fluorescence alone from the directly occurring excited singlet state is limited. On the other hand, in a delayed fluorescent material, not only the excited singlet state thereof but also the excited triplet state can be utilized for fluorescent emission through the route via the above-mentioned reverse intersystem crossing, and therefore as compared with an ordinary fluorescent material, a delayed fluorescent material can realize a higher emission efficiency.

After the characteristics of such a delayed fluorescent material have been clarified, various methods of effectively utilizing a delayed fluorescent material have been further investigated. For example, PTL 1 describes adding, to a light emitting layer containing a light emitting material and a host material, a delayed fluorescent material whose lowest excited singlet energy is lower than that of the host material and higher than that of the light emitting material. By adding such a delayed fluorescent material, the lowest excited singlet energy of the delayed fluorescent material transfers to the light emitting material to enhance the light emission efficiency of the light emitting material.

### CITATION LIST

### Patent Literature

PTL 1: JP5669163B

### SUMMARY OF INVENTION

### Technical Problem

By adding, to the light emitting layer containing a light emitting material and a host material, a delayed fluorescent material whose lowest excited singlet energy is lower than that of the host material and higher than that of the light emitting material, the light emission efficiency of the organic electroluminescent device surely improves. However, the organic electroluminescent material in which a delayed fluorescent material is added to the light emitting layer tends to have an increased drive voltage and has room for improvement in point of practicability. Consequently, there is a need to provide an organic electroluminescent device having a reduced drive voltage while achieving a high light emission efficiency.

### Solution to Problem

As a result of having advanced assiduous studies for solving the problems in the prior art, the present inventors have found that, by combining the compounds to be added to the light emitting layer of an organic electroluminescent device so as to satisfy specific requirements, a high light emission efficiency can be attained while suppressing the drive voltage. The present invention has been proposed on the basis of such findings, and specifically has the following constitution.

[1] An organic electroluminescent device having an anode, a cathode, and at least one organic layer containing a light emitting: layer between the anode and the cathode, in which:
the light emitting layer contains a first organic compound, a second organic compound and a third organic compound,
the second organic compound is a delayed fluorescent material,
the maximum component of light emission from the device is light emission from the third organic compound,
the first organic compound, the second organic compound and the third organic compound satisfy the following formula (a) and. the following formula (b),

E_{S1}(1)>E_{S1}(2)>E_{S1}(3) Formula (a)

E_{LUMO}(2)≤E_{LUMO}(3) Formula (b)

wherein:
E_{S1}(1) represents the lowest excited singlet energy of the first organic compound,
E_{S1}(2) represents the lowest excited singlet energy of the second organic compound,
E_{S1}(3) represents the lowest excited singlet energy of the third organic compound,
E_{LUMO}(2) represents the LUMO energy of the second organic compound,
E_{LUMO}(3) represents the LUMO energy of the third organic compound.

[2] The organic electroluminescent device according to [1], satisfying the following formula (c).

E_{LUMO}(2)≤E_{LUMO}(3)−0.13 eV Formula (c)

[3] The organic electroluminescent device according to [1] or [2], in which the maximum emission wavelength of the third compound is longer than 570 nm.

[4] The organic electroluminescent device according to any one of [1] to [3], in which the LUMO energy of the third organic compound, E_{LUMO}(3) is larger than −3.5 eV.

[5] The organic electroluminescent device according to any one of [1] to [4], in which the third organic compound is a compound represented by the following general formula (1).

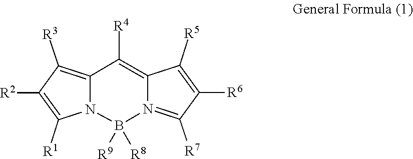

wherein R¹ to R⁷ each independently represent a hydrogen atom or a substituent; R⁸ and R⁹ each independently represent a hydrogen atom, a halogen atom, a substituted or unsubstituted alkyl group, a substituted or unsubstituted alkoxy group, a substituted or unsubstituted aryloxy group, or a cyano group.

[6] The organic electroluminescent device according to [5], in which at least one of R′ to R⁷ is a group represented by the following general formula (2).

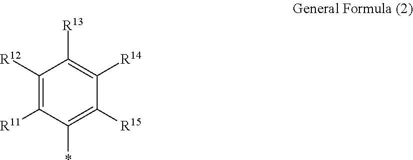

wherein R¹¹ to R¹⁵ each independently represent a hydrogen atom or a substituent, and * indicates a bonding position.

[7] The organic electroluminescent device according to [6], in which at least four of R¹ to R⁷ in the general formula (1) each are independently a group represented by the general formula (2).

[8] The organic electroluminescent device according to [7], in which R¹, R³, R⁵, and R⁷ in the general formula (1) each are independently a group represented by the general formula (2).

[9] The organic electroluminescent device according to any one of [5] to [8], in which the total of the substituted or unsubstituted alkoxy group, the substituted or unsubstituted aryloxy group and the substituted or unsubstituted amino group existing in R¹ to R⁹ in the general formula (1) is 3 or more.

[10] The organic electroluminescent device according to any one of [5] to [8], in which the number of the substituents having a Hammett's op value of less than −0.2 existing in R¹ to R⁹ in the general formula (1) is 3 or more.

[11] The organic electroluminescent device according to any one of [1] to [10], in which the second organic compound is a compound represented by the following general formula (3).

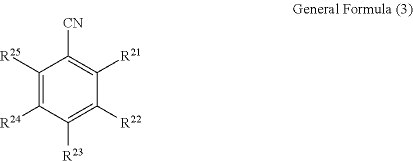

wherein one of R²¹ to R²³ represents a cyano group or a group represented by the following general formula (4), the remaining two of R²¹ to R²³ and at least one of R²⁴ and R²⁵ each independently represent a group represented by the following general formula (5), and the rest of R²¹ to R²⁵ each independently represent a hydrogen atom or a substituent, provided that the substituent is not a cyano group, a group represented by the following general formula (4) and a group represented by the following general formula (5);

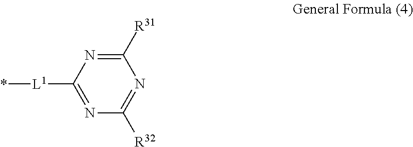

wherein L¹ represents a single bond or a divalent linking group, R³¹ and R³² each independently represent a hydrogen atom or a substituent, * indicates a bonding position.

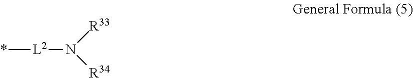

wherein L² represents a single bond or a divalent linking group, R³³ and R³⁴ each independently represent a hydrogen atom or a substituent, * indicates a bonding position.

[12] The organic electroluminescent device according to [11], in which one of R²¹ to R²³ in the general formula (3) is a group represented by the general formula (4).

[13] The organic electroluminescent device according to of [12], in which one of R²¹ and R²² in the general formula (3) is a cyano group or a group represented by the general formula (4).

[14] The organic electroluminescent device according to any one of to [13], in which the general formula (5) is a group represented by the following general formula (6).

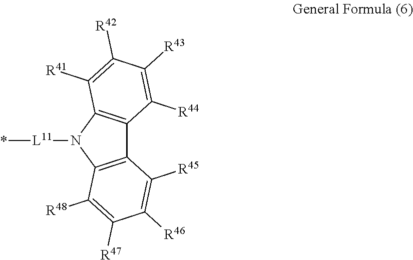

wherein L¹¹ represents a single bond or a divalent linking group, R⁴¹ to R⁴⁸ each independently represent a hydrogen atom or a substituent, * indicates a bonding position, the carbon atoms to which R⁴¹ to R⁴⁸ bond can be each independently substituted with a nitrogen atom.

[15] The organic electroluminescent device according to any one of to [13], in which the general formula (5) is a group represented by any of the following general formulae (7) to (12).

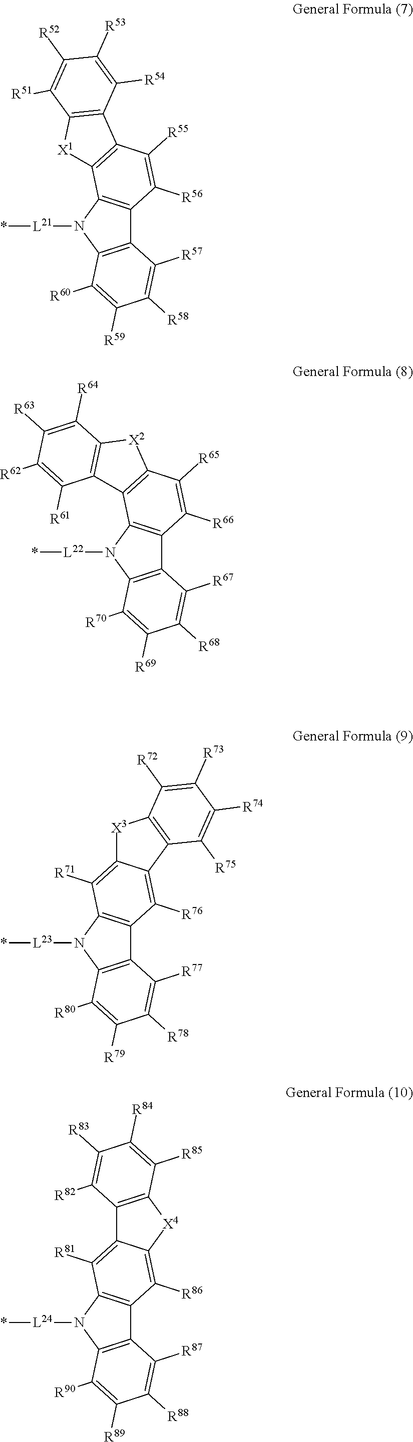

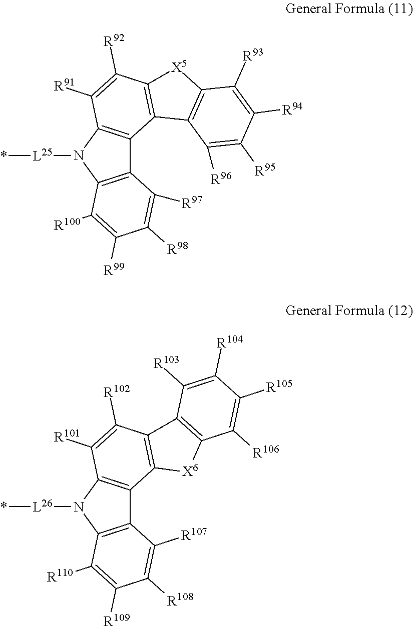

wherein L²¹ to L²⁶ each represent a single bond or a divalent linking group, R⁵¹ to R¹¹⁰ each independently represent a hydrogen atom or a substituent, X¹ to X⁶ each represent an oxygen atom, a sulfur atom or N—R, R represents a hydrogen atom or a substituent, * indicates a bonding position, the carbon atoms to which R⁵¹ to R¹¹⁰ bond each can be independently substituted with a nitrogen atom.

[16] The organic electroluminescent device according to any one of [1] to [15], in which the light emitting layer contains a carbon atom, a hydrogen atom, a nitrogen atom, a boron atom, an oxygen atom and a fluorine atom, and does not contain any other element.

[17] A method for designing a light emitting composition, including:

[Step 1] evaluating at least one of the light emission efficiency and the drive voltage of a composition containing a first organic compound, a second organic compound of a delayed fluorescent material and a third organic compound, and satisfying the following formula (a) and the following formula (b),

[Step 2] carrying out at least once evaluating at least one of the light emission efficiency and the drive voltage of a composition prepared by replacing at least one of the first organic compound, the second organic compound of a delayed fluorescent material and the third organic compound within the range satisfying the following formula (a) and the following formula (b), and

[Step 3] selecting a combination of compounds providing the best results of the light emission efficiency and the drive voltage evaluated.

E_{S1}(1)>E_{S1}(2)>E_{S1}(3) Formula (a)

E_{LUMO}(2)≤E_{LUMO}(3) Formula (b)

wherein:
E_{S1}(1) represents the lowest excited singlet energy of the first organic compound,
E_{S1}(2) represents the lowest excited singlet energy of the second organic compound,
E_{S1}(3) represents the lowest excited singlet energy of the third organic compound,
E_{LUMO}(2) represents the LUMO energy of the second organic compound,
E_{LUMO}(3) represents the LUMO energy of the third organic compound.

A program of carrying out the method of [17].

### Advantageous Effects of Invention

The organic electroluminescent device of the present invention can attain a low drive voltage and a high light emission efficiency. According to the method for designing a light emitting composition of the present invention, there can be provided a light emitting composition capable of realizing a light emitting device having a low drive voltage and a high light emission efficiency.

### BRIEF DESCRIPTION OF DRAWINGS

FIG. 1 This is a schematic cross-sectional view showing a layer configuration example of an organic electroluminescent device.

FIG. 2 This is a graph showing a relationship between the energy difference ΔE_{LUMO} of LUMO between the second organic compound and the third organic compound in the devices 1 to 3 for electron mobility measurement, and the ratio REM of an electron mobility depending on the presence or absence of the third organic compound therein.

### DESCRIPTION OF EMBODIMENTS

The contents of the invention will be described in detail below. The constitutional elements may be described below with reference to representative embodiments and specific examples of the invention, but the invention is not limited to the embodiments and the examples. In the description herein, a numerical range expressed as “to” means a range that includes the numerical values described before and after “to” as the lower limit and the upper limit. The isotope species of the hydrogen atom existing in the molecule of the compound used in the present invention is not specifically limited, and for example, all hydrogen atoms in the molecule can be ¹H, or a part or all can be ²H (deuterium D). In a preferred embodiment of the present invention, all hydrogen atoms in the molecule are ¹H. In one embodiment of the present invention, all hydrogen atoms in the molecule are ²H (deuterium D). In one embodiment of the present invention, some of hydrogen atoms in the molecule are ¹H, and the rest are ²H (deuterium D). In the description of the present invention, the term “substitution” or “substituent” does not include a hydrogen atom isotope except ¹H such as ²H (deuterium D).

### (Organic Electroluminescent Device)

The organic electroluminescent device of the present invention has an anode, a cathode and at least one organic layer containing a light emitting layer between the anode and the cathode. The light emitting layer contains a first organic compound, a second organic compound and a third organic compound, the second organic compound is a delayed fluorescent material, the maximum component of light emission from the organic electroluminescent device is light emission from the third organic compound. The first organic compound, the second organic compound and the third organic compound satisfy the following formula (a) and the following formula (b).

E_{S1}(1)>E_{S1}(2)>E_{S1}(3) Formula (a)

E_{LUMO}(2)≤E_{LUMO}(3) Formula (b)

In the formula (a), E_{S1}(1) represents the lowest excited singlet energy of the first organic compound, E_{S1}(2) represents the lowest excited singlet energy of the second organic compound, E_{S1}(3) represents the lowest excited singlet energy of the third organic compound. In the present invention, eV is employed as the unit. The lowest excited singlet energy can be determined by preparing a thin film or a toluene solution (concentration: 10⁻⁵ mol/L) of the targeted compound and measuring the fluorescent spectrum thereof at room temperature (300 K). For the details thereof, referred to is the measurement method for lowest excited singlet energy in the section of description of the second organic compound.

The present invention satisfies the formula (a), and therefore, among the first organic compound, the second organic compound and the third organic compound contained in the light emitting layer, the lowest excited singlet energy of the first organic compound is the largest, that of the second organic compound is the next largest, and that of the third organic compound is the smallest. E_{S1}(1)-E_{S1}(2) can be, for example, within a range of 0.20 eV or more, or within a range of 0.40 eV or more, or within a range of 0.60 eV or more. It can also be within a range of 1.50 eV or less, or within a range of 1.20 eV or less, or within a range of 0.80 eV or less. E_{S1}(2)-E_{S1}(3) can be, for example, within a range of 0.05 eV or more, or within a range of 0.10 eV or more, or within a range of 0.15 eV or more. It can also be within a range of 0.50 eV or less, or within a range of 0.30 eV or less, or within a range of 0.20 eV or less. E_{S1}(1)-E_{S1}(3) can be, for example, within a range of 0.25 eV or more, or within a range of 0.45 eV or more, or within a range of 0.65 eV or more. It can also be within a range of 2.00 eV or less, or within a range of 1.70 eV or less, or within a range of 1.30 eV or less.

In the formula (b), E_{LUMO}(2) represents the LUMO energy of the second organic compound, and E_{LUMO}(3) represents the LUMO energy of the third organic compound. LUMO is an abbreviation for Lowest Unoccupied Molecular Orbital, and can be determined according to air photoelectron spectroscopy (e.g., AC-3, by Riken Keiki Co., Ltd.).

The present invention satisfies the relationship of the formula (b), and therefore the LUMO energy of the second organic compound contained in the light emitting layer is lower than or equal to the LUMO energy of the third organic compound therein. The LUMO energy difference [E_{LUMO}(3)-E_{LUMO}(2)] can be within a range of 0.05 eV or more, within a range of 0.10 eV or more, or within a range of 0.13 eV or more, and can be within a range of 0.40 eV or less, within a range of 0.30 eV or less, or within a range of 0.20 eV or less. In one embodiment of the present invention, as the second organic compound, a compound whose LUMO energy falls within a range of −3.40 to −3.70 eV, or a compound whose LUMO energy falls within a range of −3.50 to −3.60 eV can be employed. In one embodiment of the present invention, as the third organic compound, a compound whose LUMO energy is larger than −3.50, a compound whose LUMO energy falls within a range of −3.51 to −3.25 eV, or a compound whose LUMO energy falls within a range of −3.45 to −3.35 eV can be employed.

When the content of the first organic compound, the second organic compound and the third organic compound in the light emitting layer of the organic electroluminescent device of the present invention is represented by Conc(1), Conc(2) and Conc(3), respectively, the relationship of the following formula (d) is preferably satisfied.

Conc(1)>Conc(2)>Conc(3) Formula (d)

Conc(1) is preferably 30% by weight or more, and can be within a range of 50% by weight or more, or can be within a range of 60% by weight or more, and can be within a range of 99% by weight or less, can be within a range of 85% by weight or less, or can be within a range of 70% by weight or less.

Conc(2) is preferably 5% by weight or more, and can be within a range of 15% by weight or more, or can be within a range of 30% by weight or more, and can be within a range of 45% by weight or less, can be within a range of 40% by weight or less, or can be within a range of 35% by weight or less.

Conc(3) is preferably 5% by weight or less, more preferably 3% by weight or less. Conc(3) can be within a range of 0.01% by weight or more, can be within a range of 0.1% by weight or more, or can be within a range of 0.3% by weight or more, and can also be within a range of 2% by weight or less, or can be within a range of 1% by weight or less.

Conc(1)/Conc(3) can be within a range of 10 or more, can be within a range of 50 or more, or can be within a range of 90 or more, and can also be within a range of 10000 or less, can be within a range of 1000 or less, or can be within a range of 200 or less.

Conc(2)/Conc(3) can be within a range of 5 or more, can be within a range of 10 or more, can be within a range of 20 or more, or can be within a range of 30 or more, and can also be within a range of 500 or less, can be within a range of 300 or less, or can be within a range of 100 or less.

Preferably, the light emitting layer of the organic electroluminescent device of the present invention does not contain a metal element other than boron. For example, the light emitting layer cam be composed of only a compound consisting of atoms selected from the group consisting of a carbon atom, a hydrogen atom, a nitrogen atom, an oxygen atom, a sulfur atom, a fluorine atom and a boron atom. For example, the light emitting layer can be composed of only a compound consisting of atoms selected from the group consisting of a carbon atom, a hydrogen atom, a nitrogen atom, an oxygen atom, a fluorine atom and a boron atom.

### (First Organic Compound)

The first organic compound used in the light emitting layer of the organic electroluminescent device of the present invention is selected from compounds having a larger lowest excited singlet energy than the second organic compound and the third organic compound. Preferably, the first organic compound has a function as a host material responsible for carrier transport. Also preferably, the first organic compound has a function of confining the energy of the third organic compound in the compound. With that, the third organic compound can efficiently convert the energy generated by recombination of holes and electrons in the molecule and the energy received from the first organic compound and the second organic compound into light emission.

The first organic compound is preferably an organic compound having a hole transport function and an electron transport function, capable of preventing the wavelength of the light emitted from being prolonged, and having a high glass transition temperature. In one preferred embodiment of the present invention, the first organic compound is selected from compounds not radiating delayed fluorescence. The light emission from the first organic compound is preferably less than 1% of the light emission from the organic electroluminescent device of the present invention, more preferably less than 0.1%, and can be, for example, less than 0.01%, or less than detection limit.

Preferably, the first organic compound does not contain a metal atom. For example, as the first organic compound, a compound composed of atoms selected from the group consisting of a carbon atom, a hydrogen atom, a nitrogen atom, an oxygen atom and a sulfur atom. For example, as the first organic compound, a compound composed of atoms selected from the group consisting of a carbon atom, a hydrogen atom, a nitrogen atom and an oxygen atom can be selected. For example, as the first organic compound, a compound consisting of a carbon atom, a hydrogen atom, and a nitrogen atom can be selected.

Hereinunder shown are preferred compounds for use as the first organic compound,

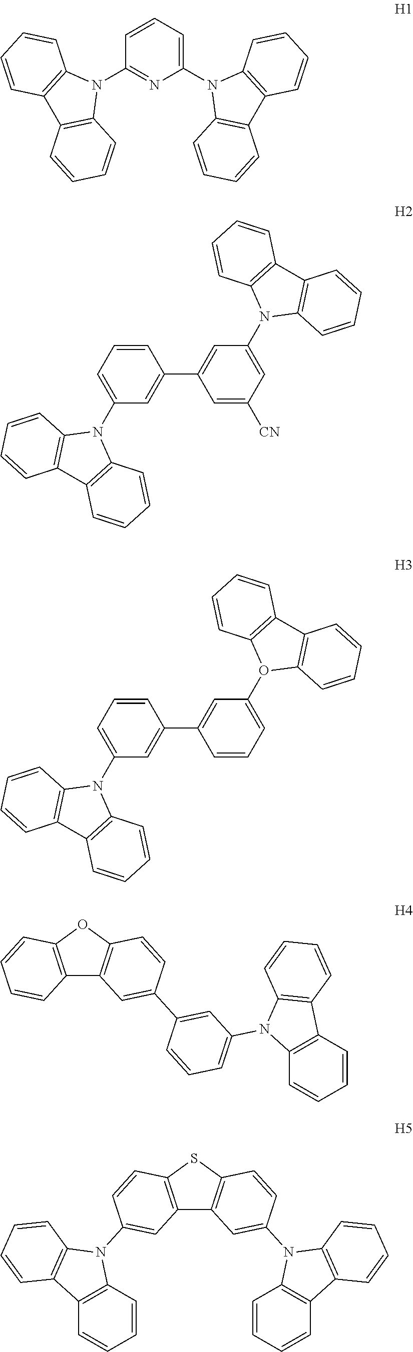

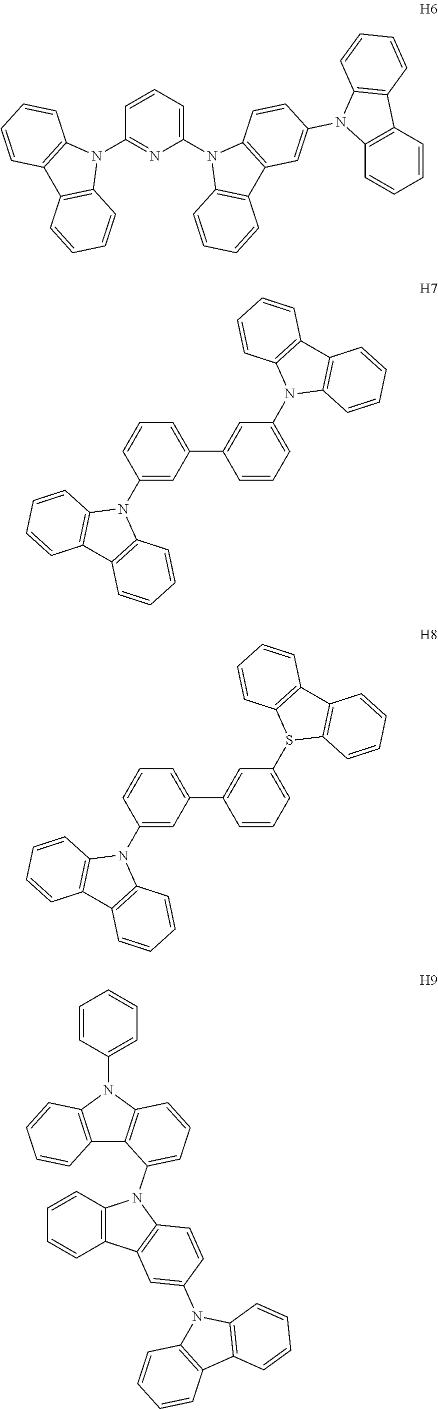

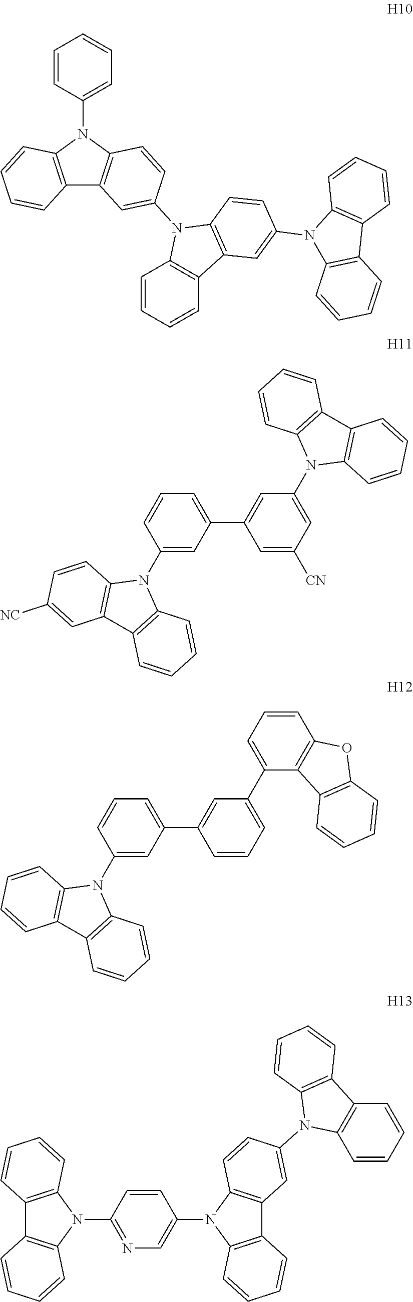 [SMILES: c1ccc(-n2c3ccccc3c3cc(-n4c5ccccc5c5cc(-n6c7ccccc7c7ccccc76)ccc54)ccc32)cc1 ; N#Cc1cc(-c2cccc(-n3c4ccccc4c4cc(C#N)ccc43)c2)cc(-n2c3ccccc3c3ccccc32)c1 ; c1cc(-c2cccc(-n3c4ccccc4c4ccccc43)c2)cc(-c2cccc3oc4ccccc4c23)c1 ; c1ccc2c(c1)c1ccccc1n2-c1ccc2c(c1)c1ccccc1n2-c1ccc(-n2c3ccccc3c3ccccc32)nc1]

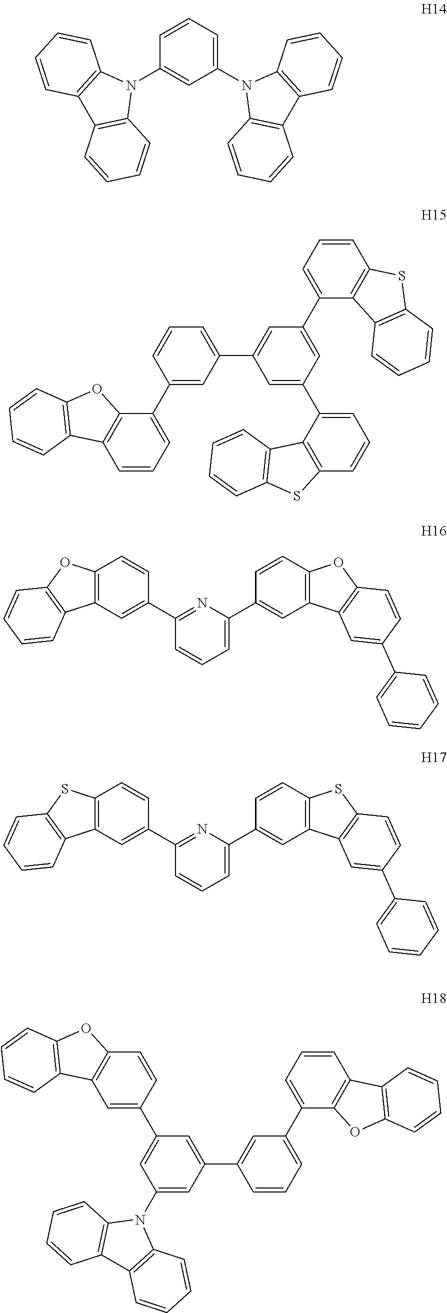 [SMILES: c1cc(-n2c3ccccc3c3ccccc32)cc(-n2c3ccccc3c3ccccc32)c1 ; c1cc(-c2cc(-c3cccc4sc5ccccc5c34)cc(-c3cccc4sc5ccccc5c34)c2)cc(-c2cccc3c2oc2ccccc23)c1 ; c1ccc(-c2ccc3oc4ccc(-c5cccc(-c6ccc7oc8ccccc8c7c6)n5)cc4c3c2)cc1 ; c1ccc(-c2ccc3sc4ccc(-c5cccc(-c6ccc7sc8ccccc8c7c6)n5)cc4c3c2)cc1 ; c1cc(-c2cc(-c3ccc4oc5ccccc5c4c3)cc(-n3c4ccccc4c4ccccc43)c2)cc(-c2cccc3c2oc2ccccc23)c1]

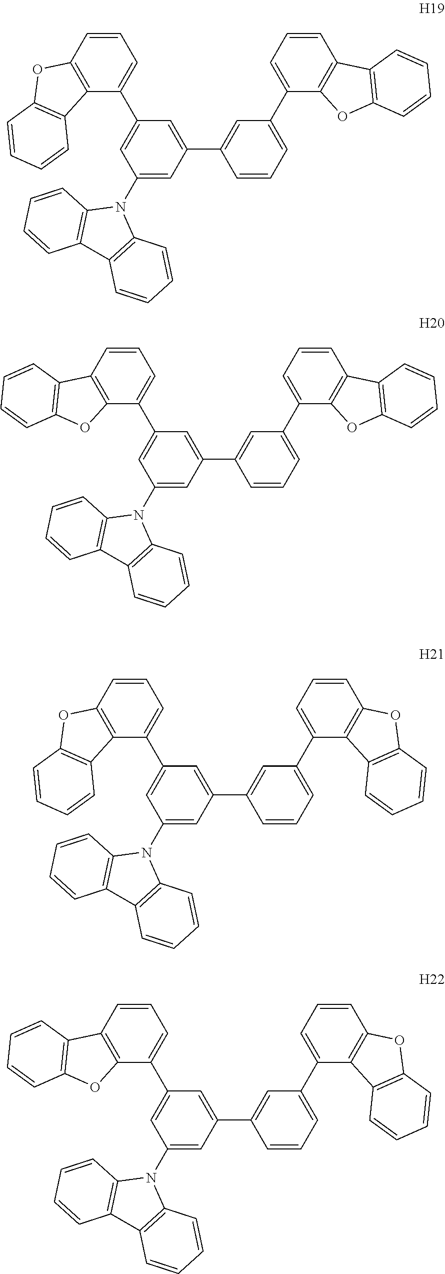

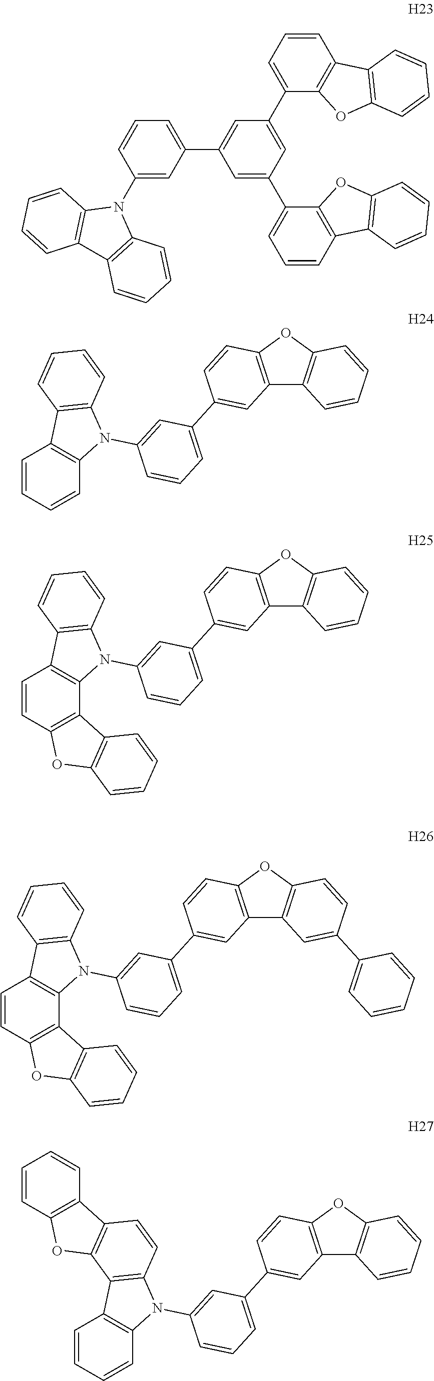 [SMILES: c1cc(-c2cc(-c3cccc4c3oc3ccccc34)cc(-c3cccc4c3oc3ccccc34)c2)cc(-n2c3ccccc3c3ccccc32)c1 ; c1cc(-c2ccc3oc4ccccc4c3c2)cc(-n2c3ccccc3c3ccccc32)c1 ; c1cc(-c2ccc3oc4ccccc4c3c2)cc(-n2c3ccccc3c3ccc4oc5ccccc5c4c32)c1 ; c1ccc(-c2ccc3oc4ccc(-c5cccc(-n6c7ccccc7c7ccc8oc9ccccc9c8c76)c5)cc4c3c2)cc1 ; c1cc(-c2ccc3oc4ccccc4c3c2)cc(-n2c3ccccc3c3c4oc5ccccc5c4ccc32)c1]

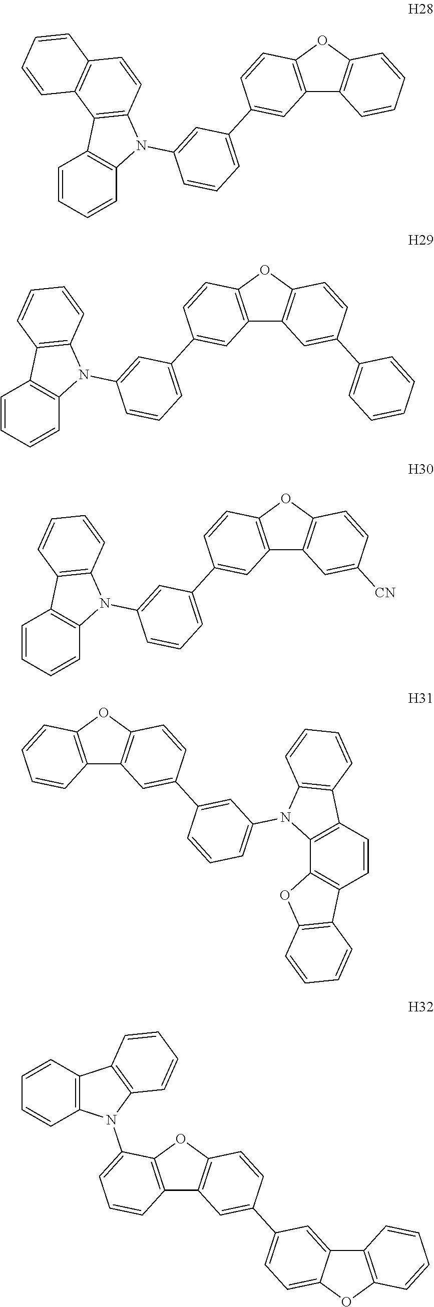 [SMILES: c1cc(-c2ccc3oc4ccccc4c3c2)cc(-n2c3ccccc3c3c4ccccc4ccc32)c1 ; c1ccc(-c2ccc3oc4ccc(-c5cccc(-n6c7ccccc7c7ccccc76)c5)cc4c3c2)cc1 ; N#Cc1ccc2oc3ccc(-c4cccc(-n5c6ccccc6c6ccccc65)c4)cc3c2c1 ; c1cc(-c2ccc3oc4ccccc4c3c2)cc(-n2c3ccccc3c3ccc4c5ccccc5oc4c32)c1 ; c1ccc2c(c1)oc1ccc(-c3ccc4oc5c(-n6c7ccccc7c7ccccc76)cccc5c4c3)cc12]

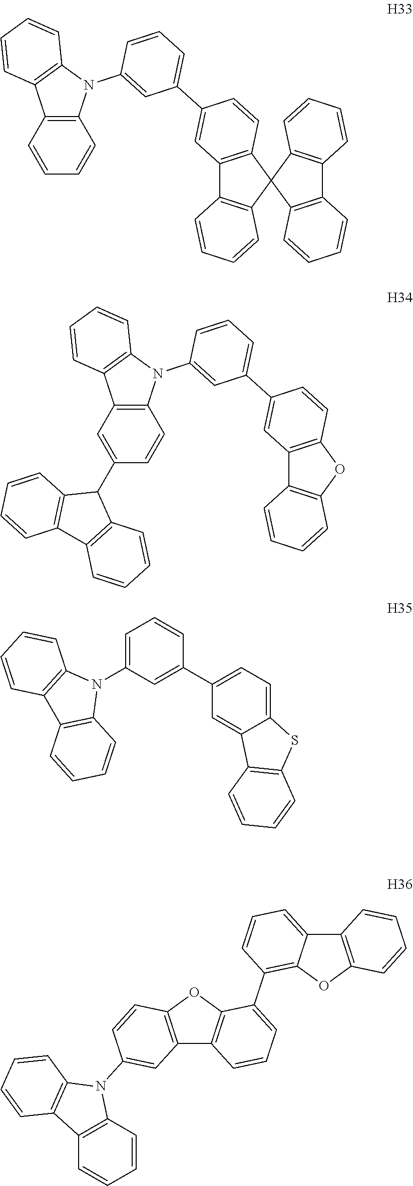

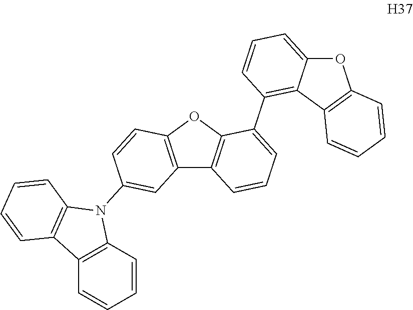 [SMILES: c1ccc2c(c1)oc1cccc(-c3cccc4c3oc3ccc(-n5c6ccccc6c6ccccc65)cc34)c12]

### (Second Organic Compound)

The second organic compound used in the light emitting layer of the organic electroluminescent device of the present invention is a delayed fluorescent material having a lowest excited singlet energy smaller than that of the first organic compound and larger than that of the third organic compound, and having a LUMO energy smaller than that of the third organic compound. In the present invention, “delayed fluorescent material” is an organic compound which, in an excited state, undergoes reverse intersystem crossing from an excited triplet state to an excited singlet state, and which emits fluorescence (delayed fluorescence) in returning back from the excited singlet state to a ground state. In the invention, a compound which gives fluorescence having an emission lifetime of 100 ns (nanoseconds) or longer, when the emission lifetime is measured with a fluorescence lifetime measuring system (e.g., streak camera system by Hamamatsu Photonics KK), is referred to as a delayed fluorescent material. The second organic compound is a material capable of radiating delayed fluorescence, but radiation of delayed fluorescence derived from the second organic compound when used in the organic electroluminescent device of the present invention is not indispensable. Light emission from the second organic compound is preferably less than 10% of the light emission from the organic electroluminescent device of the present invention, and can be, for example, less than 1%, or less than 0.1%, or less than 0.01%, or less than detection limit.

In the organic LI device of the present invention, the second organic compound receives the energy from the first organic compound in an excited singlet state to transition into an excited singlet state. Also, the second organic compound can receive the energy from the first organic compound in an excited triplet state to transition into an excited triplet state. Since the difference between the excited singlet state and the excited triplet state (ΔE_{ST}) of the second organic compound is small, the second organic compound in an excited triplet state can readily undergo reverse intersystem crossing to be the second organic compound in an excited singlet state. The second organic compound in the excited singlet state formed through the route gives the energy to the third organic compound to make the third organic compound transition into an excited singlet state.

The second organic compound is preferably such that the difference ΔE_{ST} between the lowest excited singlet energy and the lowest excited triplet energy at 77K is 0.3 eV or less, more preferably 0.25 eV or less, even more preferably 0.2 eV or less, further more preferably 0.15 eV or less, further more preferably 0.1 eV or less, further more preferably 0.07 eV or less, further more preferably 0.05 eV or less, further more preferably 0.03 eV or less, particularly preferably 0.01 eV or less.

When ΔE_{ST} is smaller, reverse intersystem crossing from an excited triplet state to an excited singlet state can more readily occur through thermal energy absorption, and therefore the second organic compound can function as a thermal activation type delayed fluorescent material. A thermal activation type delayed fluorescent material can absorb heat generated by a device to relatively readily undergo reverse intersystem crossing from an excited triplet state to an excited singlet state, and can make the excited triplet energy efficiently contribute toward light emission.

In the invention, the difference ΔE_{ST} between a lowest excited singlet energy level (E_{S1}) and a lowest excited triplet energy level (E_{T1}) of a compound is determined according to the following process. ΔE_{ST} is a value determined by calculating E_{S1}−E_{T1}.

### (1) Lowest Excited Singlet Energy (E_{S1})

A thin film or a toluene solution (concentration: 10⁻⁵ mol/L) of the targeted compound is prepared as a measurement sample. The fluorescent spectrum of the sample is measured at room temperature (300 K). For the fluorescent spectrum, the emission intensity is on the vertical axis and the wavelength is on the horizontal axis. A tangent line is drawn to the rising of the emission spectrum on the short wavelength side, and the wavelength value λedge [nm] at the intersection between the tangent line and the horizontal axis is read. The wavelength value is converted into an energy value according to the following conversion expression to calculate E_{S1}.

Conversion Expression: E_{S1}[eV]=1239.85/λedge

For the measurement of the emission spectrum in Examples given below, an LED light source (by Thorlabs Corporation, M340L4) was used as an excitation light source along with a detector (by Hamamatsu Photonics K.K., PMA-12 Multichannel Spectroscope C10027-01).

### (2) Lowest Excited Triplet Energy (E_{T1})

The same sample as that for measurement of the lowest excited singlet energy (E_{S1}) is cooled to 77 [K] with liquid nitrogen, and the sample for phosphorescence measurement is irradiated with excitation light (300 nm), and using a detector, the phosphorescence thereof is measured. The emission after 100 milliseconds from irradiation with the excitation light is drawn as a phosphorescent spectrum. A tangent line is drawn to the rising of the phosphorescent spectrum on the short wavelength side, and the wavelength value kedge [nm] at the intersection between the tangent line and the horizontal axis is read. The wavelength value is converted into an energy value according to the following conversion expression to calculate E_{T1}.

Conversion Expression: E_{T1}[eV]=1239.85/λedge

The tangent line to the rising of the phosphorescent spectrum on the short wavelength side is drawn as follows. While moving on the spectral curve from the short wavelength side of the phosphorescent spectrum toward the maximum value on the shortest wavelength side among the maximum values of the spectrum, a tangent line at each point on the curve toward the long wavelength side is taken into consideration. With rising thereof (that is, with increase in the vertical axis), the inclination of the tangent line increases. The tangent line drawn at the point at which the inclination value has a maximum value is referred to as the tangent line to the rising on the short wavelength side of the phosphorescent spectrum.

The maximum point having a peak intensity of 10% or less of the maximum peak intensity of the spectrum is not included in the maximum value on the above-mentioned shortest wavelength side, and the tangent line drawn at the point which is closest to the maximum value on the shortest wavelength side and at which the inclination value has a maximum value is referred to as the tangent line to the rising on the short wavelength side of the phosphorescent spectrum.

In one preferred embodiment of the present invention, a compound represented by the following general formula (3) is used as the second compound.

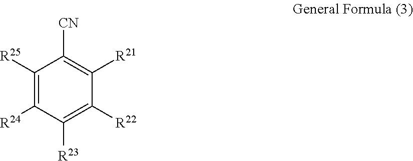

In the general formula (3), one of R²¹ to R²³ represents a cyano group or a group represented by the following general formula (4), the remaining two of R²¹ to R²³ and at least one of R²⁴ and R²⁵ each independently represent a group represented by the following general formula (5), and the rest of R²¹ to R²⁵ each independently represent a hydrogen atom or a substituent, provided that the substituent is not a cyano group, a group represented by the following general formula (4) and a group represented by the following general formula (5).

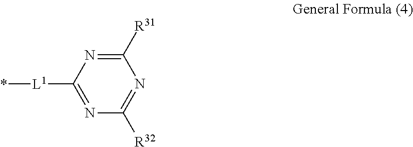

In the general formula (4), L¹ represents a single bond or a divalent linking group, R³¹ and R³² each independently represent a hydrogen atom or a substituent, * indicates a bonding position.

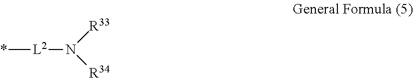

In the general formula (5), L² represents a single bond or a divalent linking group, R³³ and R³⁴ each independently represent a hydrogen atom or a substituent, * indicates a bonding position.

Of R²¹ to R²³, preferably R²¹ of R²² is a cyano group or a group represented by the general formula (4). In one preferred embodiment of the present invention, R²² is a cyano group. In one preferred embodiment of the present invention, R²² is a group represented by the general formula (4). In one embodiment of the present invention, R²¹ is a cyano group or a group represented by the general formula (4). In one embodiment of the present invention, R²³ is a cyano group or a group represented by the general formula (4). In one embodiment of the present invention, one of R²¹ to R²³ is a cyano group. In one embodiment of the present invention, one of R²¹ to R²³ is a group represented by the general formula (4).

In one preferred embodiment of the present invention, L¹ in the general formula (4) is a single bond. In one embodiment of the present invention, L¹ is a divalent linking group, preferably a substituted or unsubstituted arylene group, or a substituted or unsubstituted heteroarylene group, more preferably a substituted or unsubstituted arylene group, even more preferably a substituted or unsubstituted 1,4-phenylene group (in which the substituent is, for example, an alkyl group having 1 to 3 carbon atoms).

In one embodiment of the present invention, R³¹ and R³² in the general formula (4) each are independently a group or a combination of two or more groups selected from the group consisting of an alkyl group (for example, having 1 to 40 carbon atoms), an aryl group (for example, having 6 to 30 carbon atoms), a heteroaryl group (for example, having 5 to 30 ring skeleton-constituting atoms), an alkenyl group (for example, having 1 to 40 carbon atoms) and an alkynyl group (for example, having 1 to 40 carbon atoms) (hereinunder these groups are referred to as “groups of Substituent Group A”). In one preferred embodiment of the present invention, R³¹ and R³² each are independently a substituted or unsubstituted aryl group (for example, having 6 to 30 carbon atoms), and the substituent for the aryl group includes the groups of Substituent Group A. In one preferred embodiment of the present invention, R³¹ and R³² are the same.

In one preferred embodiment of the present invention, L² in the general formula (5) is a single bond. In one embodiment of the present invention, L² is a divalent linking group, preferably a substituted ohr unsubstituted arylene group, or a substituted or unsubstituted heteroarylene group, more preferably a substituted or unsubstituted arylene group, even more preferably a substituted or unsubstituted 1,4-phenylene group (in which the substituent is, for example, an alkyl group having 1 to 3 carbon atoms).

In one embodiment of the present invention, R³³ and R³⁴ in the general formula (5) each are independently a substituted or unsubstituted alkyl group (for example, having 1 to 40 carbon atoms), a substituted or unsubstituted alkenyl group (for example, having 1 to 40 carbon atoms), a substituted or unsubstituted aryl group (for example, having 6 to 30 carbon atoms), or a substituted or unsubstituted heteroaryl group (for example, having 5 to 30 carbon atoms. The substituent for the alkyl group, the alkenyl group, the aryl group and the heteroaryl group as referred to herein includes a group or a combination of two or more groups selected from the group consisting of a hydroxy group, a halogen atom (for example, a fluorine atom, a chlorine atom, a bromine atom, an iodine atom), an alkyl group (for example, having 1 to 40 carbon atoms), an alkoxy group (for example, having 1 to 40 carbon atoms), an alkylthio group (for example, having 1 to 40 carbon atoms), an aryl group (for example, having 6 to 30 carbon atoms), an aryloxy group (for example, having 6 to 30 carbon atoms), an arylthio group (for example, having 6 to 30 carbon atoms), a heteroaryl group (for example, having 5 to 30 ring skeleton-constituting atoms), a heteroaryloxy group (for example, having 5 to 30 ring skeleton-constituting carbon atoms), a heteroarylthio group (for example, having 5 to 30 ring skeleton-constituting atoms), an acyl group (for example, having 1 to 40 carbon atoms), an alkenyl group (for example, having 1 to 40 carbon atoms), an alkynyl group (for example, having 1 to 40 carbon atoms), an alkoxycarbonyl group (for example, having 1 to 40 carbon atoms), an aryloxycarbonyl group (for example, having 1 to 40 carbon atoms), a heteroaryloxycarbonyl group (for example, having 1 to 40 carbon atoms), a silyl group (for example, a trialkylsilyl group having 1 to 40 carbon atoms), a nitro group and a cyano group. Hereinunder these groups are referred to as “groups of Substituent Group B”.

R³³ and R³⁴ can bond to each other via a single bond or a linking group to form a cyclic structure. Especially in the case where R³³ and R³⁴ each are an aryl group, it is preferable that they bond to each other via a single bond or a linking group to form a cyclic structure. The linking group as referred to herein includes —O—, —S—, —N(R³⁵)—, —C(R³⁶)(R³⁷)—, and —C(═O)—, and preferred are —O—, —S—, —N(R³⁵)—, and —C(R³⁶)(R³⁷)—, more preferred are —O—, —S—, and —N(R³⁵)—. R³⁵ to R³⁷ each independently represent a hydrogen atom or a substituent. The substituent can be selected from the groups of Substituent Group A or the groups of Substituent Group B mentioned above, or from the groups of Substituent Group C to be mentioned below. Preferably, the substituent is a group or a combination of two or more groups selected from the group consisting of an alkyl group having 1 to 10 carbon atoms and an aryl group having 6 to 14 carbon atoms.

The group represented by the general formula (5) is preferably a group represented by the following general formula (6).

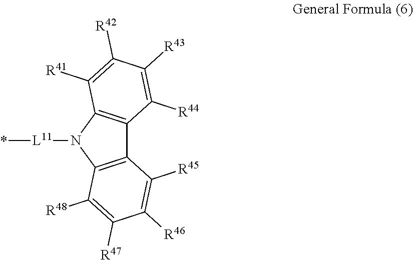

More preferably, the group represented by the general formula (6) is a group represented by any of the following general formulae (7) to (12).

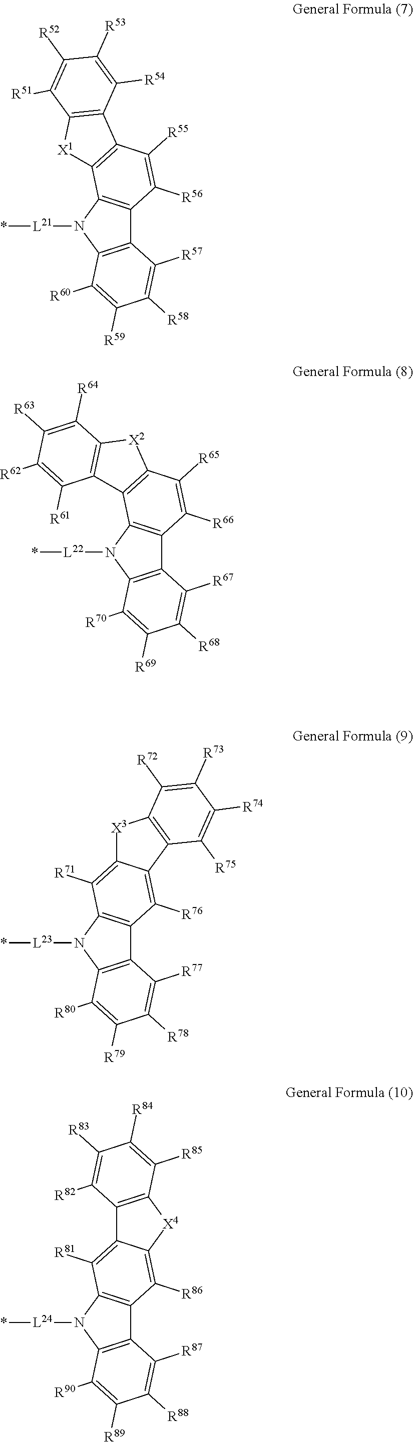

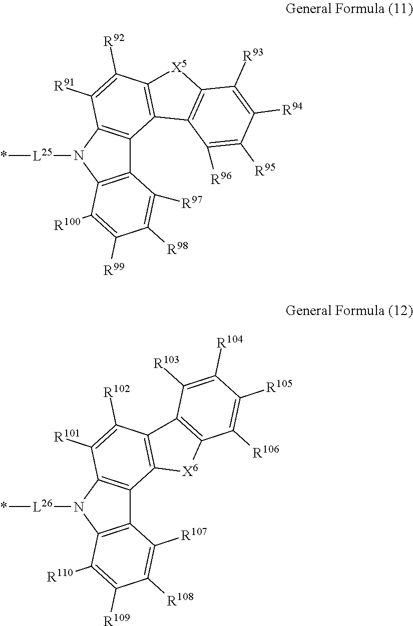

In the general formulae (6) to (12), L¹¹ and L²¹ to L²⁶ each represent a single bond or a divalent linking group. For the description and the preferred range of L¹¹ and L²¹ to L²⁶, reference can be made to the description and the preferred range of L² described hereinabove.

In the general formulae (6) to (12), R⁴¹ to R¹¹⁰ each independently represent a hydrogen atom or a substituent. R⁴¹ and R⁴², R⁴² and R⁴³, R⁴³ and R⁴⁴, R⁴⁴ and R⁴⁵, R⁴⁵ and R⁴⁶, R⁴⁶ and R⁴⁷, R⁴⁷ and R⁴⁸, R⁵¹ and R⁵², R⁵² and R⁵³, R⁵³ and R⁵⁴, R⁵⁴ and R⁵⁵, R⁵⁵ and R⁵⁶, R⁵⁶ and R⁵⁷, R⁵⁷ and R⁵⁸, R⁵⁸ and R⁵⁹, R⁵⁹ and R⁶⁰, R⁶¹ and R⁶², R⁶² and R⁶³, R⁶³ and R⁶⁴, R⁶⁵ and R⁶⁶, R⁶⁶ and R⁶⁷, R⁶⁷ and R⁶⁸, R⁶⁸ and R⁶⁹, R⁶⁹ and R⁷⁰, R⁷² and R⁷³, R⁷³ and R⁷⁴, R⁷⁴ and R⁷⁵, R⁷⁵ and R⁷⁶, R⁷⁶ and R⁷⁷, R⁷⁷ and R⁷⁸, R⁷⁸ and R⁷⁹, R⁷⁹ and R⁸⁰, R⁸¹ and R⁸², R⁸² and R⁸³, R⁸³ and R⁸⁴, R⁸⁴ and R⁸⁵, R⁸⁶ and R⁸⁷, R⁸⁷ and R⁸⁸, R⁸⁸ and R⁸⁹, R⁸⁹ and R⁹⁰, R⁹¹ and R⁹², R⁹³ and R⁹⁴, R⁹⁴ and R⁹⁵, R⁹⁵ and R⁹⁶, R⁹⁶ and R⁹⁷, R⁹⁷ and R⁹⁸, R⁹⁹ and R¹⁰⁰, R¹⁰¹ and R¹⁰², R¹⁰² and R¹⁰³, R¹⁰³ and R¹⁰⁴, R^{ψ}and R¹⁰⁵, R¹⁰⁵ and R¹⁰⁶, R¹⁰⁷ and R¹⁰⁸, R¹⁰⁸ and R¹⁰⁹, and R¹⁰⁹ and R¹¹⁰ each can bond to each other to form a cyclic structure. The cyclic structure to be formed by bonding can be an aromatic ring or an aliphatic ring, or can contain a hetero atom, and the cyclic structure can also be a condensed ring of two or more rings. The hetero atom as referred to herein is preferably selected from the group consisting of a nitrogen atom, an oxygen atom and a sulfur atom. Examples of the cyclic structure to be formed include a benzene ring, a naphthalene ring, a pyridine ring, a pyridazine ring, a pyrimidine ring, a pyrazine ring, a pyrrole ring, an imidazole ring, a pyrazole ring, an imidazoline ring, an oxazole ring, an isoxazole ring, a thiazole ring, an isothiazole ring, a cyclohexadiene ring, a cyclohexene ring, a cyclopentaene ring, a cycloheptatriene ring, a cycloheptadiene ring, a cyclopentaene ring, a furan ring, a thiophene ring, a naphthyridine ring, a quinoxaline ring, and a quinoline ring. Many rings can be condensed to form a ring such as a phenanthrene ring or a triphenylene ring. The number of the rings contained in the group represented by the general formulae (6) can be selected from a range of 3 to 5, or can be selected from a range of 5 to 7. The number of the rings contained in the group represented by the general formulae (7) to (12) can be selected from a range of 5 to 7, or can be 5.

The substituent that R⁴¹ to R¹¹⁰ can take include the groups of the above-mentioned Substituent Group G, and is preferably an unsubstituted alkyl group having 1 to 10 carbon atoms, or an aryl group having 6 to 10 carbon atoms and optionally substituted with an unsubstituted alkyl group having 1 to 10 carbon atoms. In one preferred embodiment of the present invention, R⁴¹ to R¹¹⁰ each are a hydrogen atom or an unsubstituted alkyl group having 1 to 10 carbon atoms. In one preferred embodiment of the present invention, R⁴¹ to R¹¹⁰ each are a hydrogen atom or an unsubstituted aryl group having 6 to 10 carbon atoms. In one preferred embodiment of the present invention, R⁴¹ to R¹¹⁰ are all hydrogen atoms.

The carbon atoms (the ring skeleton-constituting carbon atoms) to which R⁴¹ to R¹¹⁰ bond in the general formulae (6) to (12) can be each independently substituted with a nitrogen atom. Namely, C—R⁴¹ to C—R¹¹⁰ in the general formulae (6) to (12) can be each independently substituted with N. The number substituted with a nitrogen atom is preferably 0 to 4 in the general formulae (6) to (12), more preferably 1 to 2. In one embodiment of the present invention, the number substituted with a nitrogen atom is 0. In the case where two or more each are substituted with a nitrogen atom, it is preferable that the number of the nitrogen atoms substituted in one ring is one.

In the general formulae (6) to (12), X¹ to X⁶ each represent an oxygen atom, a sulfur atom or N—R. In one embodiment of the present invention, X¹ to X⁶ are oxygen atoms. In one embodiment of the present invention, X¹ to X⁶ are sulfur atoms. In one embodiment of the present invention, X¹ to X⁶ each are N—R. R represents a hydrogen atom or a substituent, and is preferably a substituent. For examples of the substituent, reference can be made to the substituents selected from the above-mentioned Substituent Group A. For example, the substituent is preferably an unsubstituted phenyl group, or a phenyl group substituted with one group or a combination of two or more groups selected from an alkyl group and an aryl group.

In the general formulae (6) to (12), * indicates a bonding position.

Preferred compounds for use as the second organic compound are shown below. In the structural formulae of the following exemplary compounds, t-Bu represents a tertiary butyl group.

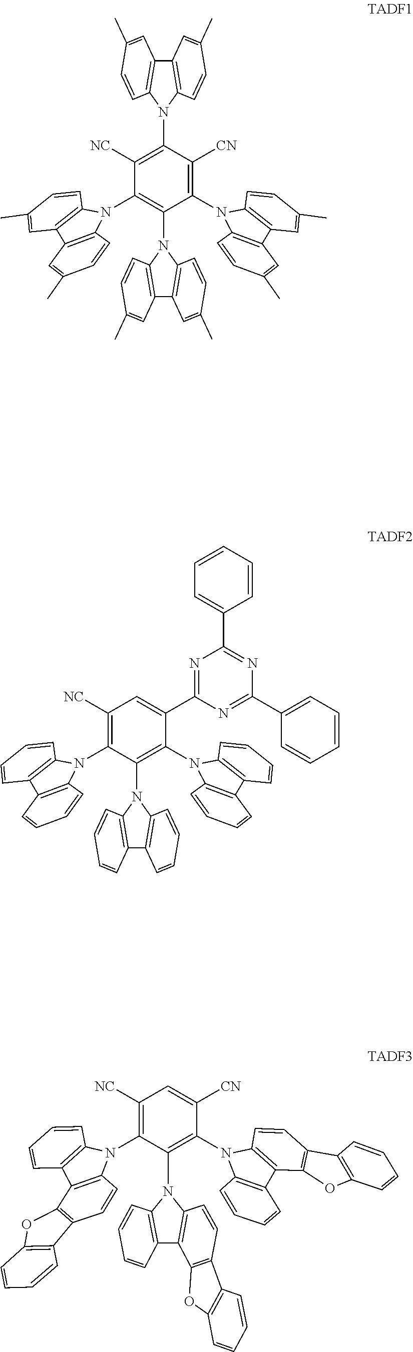

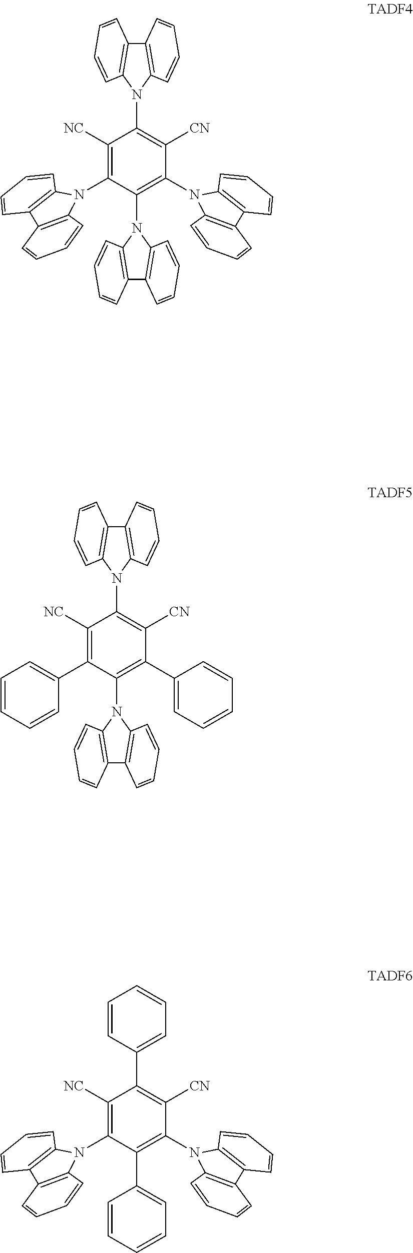

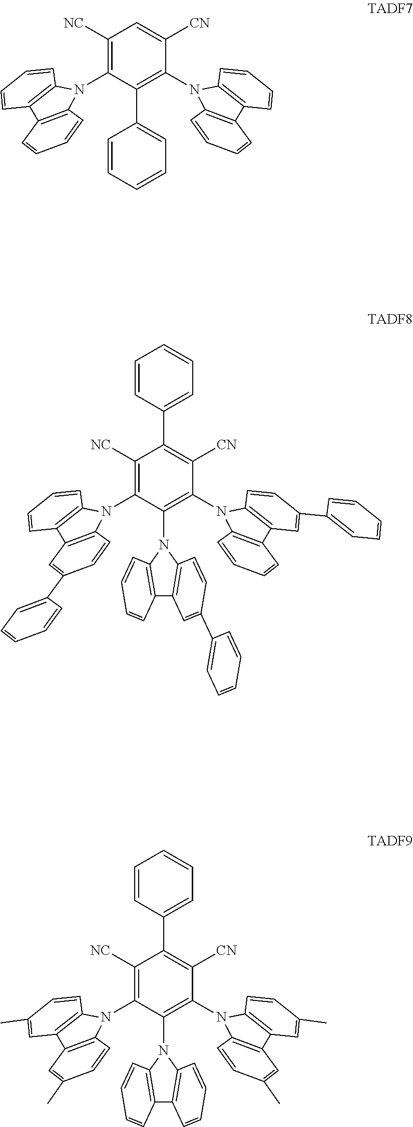

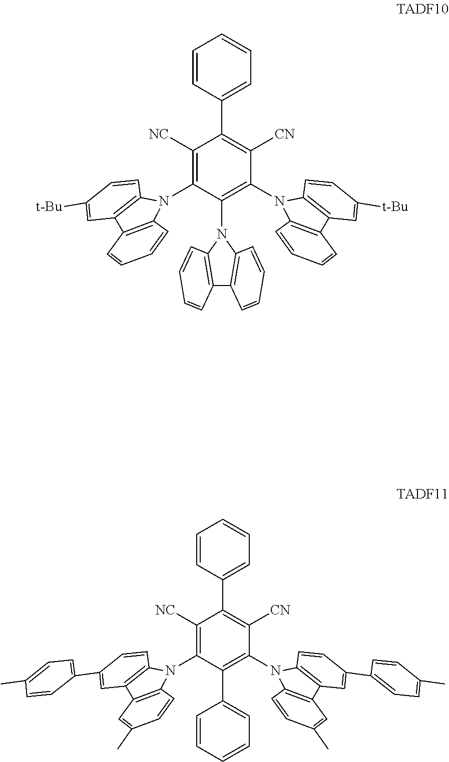

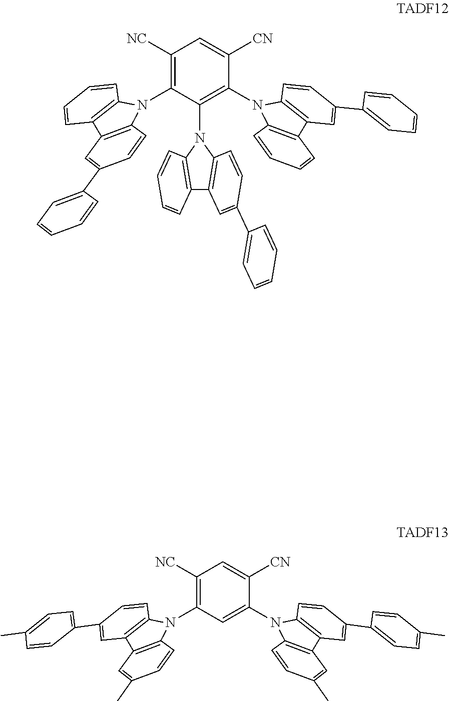

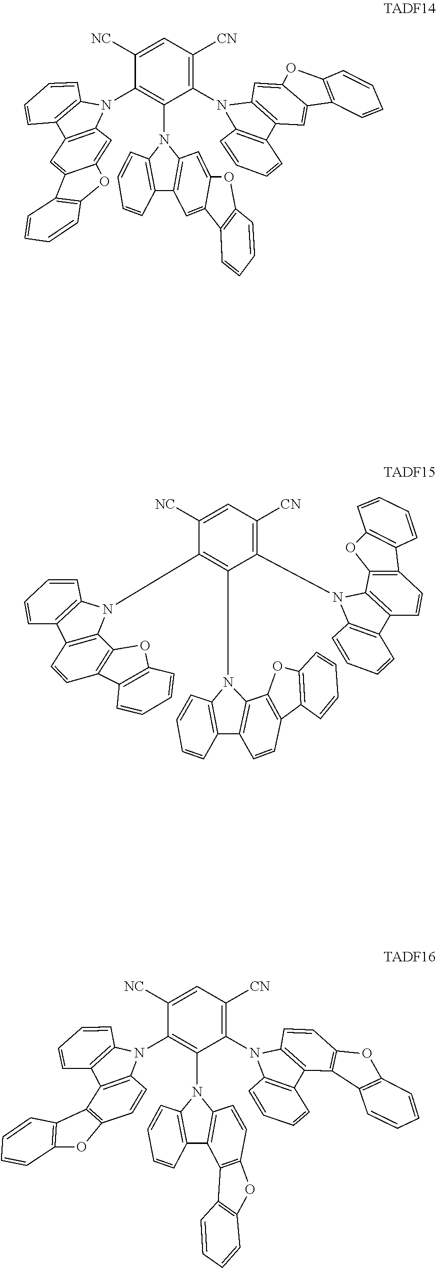 [SMILES: N#Cc1cc(C#N)c(-n2c3ccccc3c3cc4c(cc32)oc2ccccc24)c(-n2c3ccccc3c3cc4c(cc32)oc2ccccc24)c1-n1c2ccccc2c2cc3c(cc21)oc1ccccc13 ; N#Cc1cc(C#N)c(-n2c3ccccc3c3ccc4c5ccccc5oc4c32)c(-n2c3ccccc3c3ccc4c5ccccc5oc4c32)c1-n1c2ccccc2c2ccc3c4ccccc4oc3c21 ; N#Cc1cc(C#N)c(-n2c3ccccc3c3c4c(ccc32)oc2ccccc24)c(-n2c3ccccc3c3c4c(ccc32)oc2ccccc24)c1-n1c2ccccc2c2c3c(ccc21)oc1ccccc13]

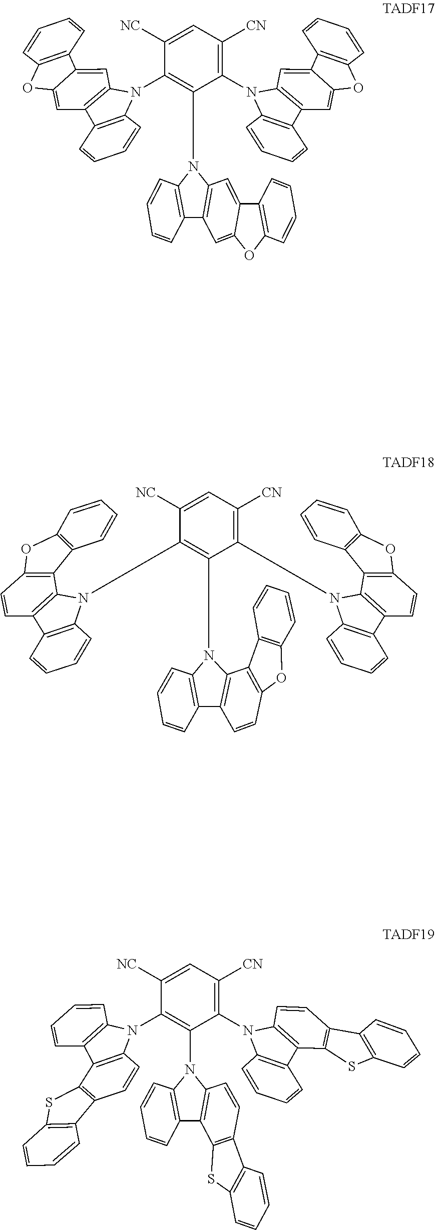 [SMILES: N#Cc1cc(C#N)c(-n2c3ccccc3c3cc4oc5ccccc5c4cc32)c(-n2c3ccccc3c3cc4oc5ccccc5c4cc32)c1-n1c2ccccc2c2cc3oc4ccccc4c3cc21 ; N#Cc1cc(C#N)c(-n2c3ccccc3c3ccc4oc5ccccc5c4c32)c(-n2c3ccccc3c3ccc4oc5ccccc5c4c32)c1-n1c2ccccc2c2ccc3oc4ccccc4c3c21 ; N#Cc1cc(C#N)c(-n2c3ccccc3c3c4sc5ccccc5c4ccc32)c(-n2c3ccccc3c3c4sc5ccccc5c4ccc32)c1-n1c2ccccc2c2c3sc4ccccc4c3ccc21]

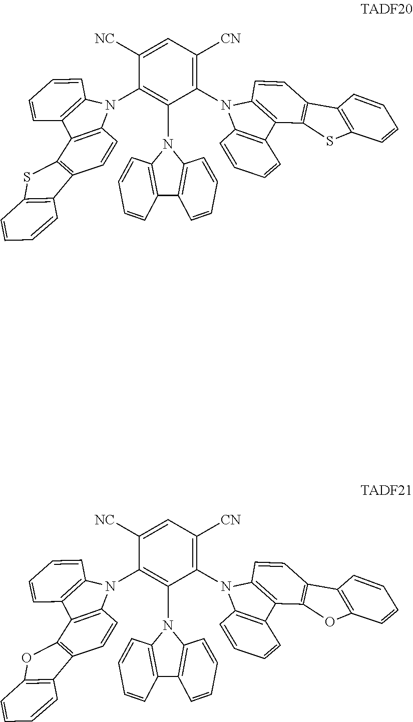 [SMILES: N#Cc1cc(C#N)c(-n2c3ccccc3c3c4sc5ccccc5c4ccc32)c(-n2c3ccccc3c3ccccc32)c1-n1c2ccccc2c2c3sc4ccccc4c3ccc21 ; N#Cc1cc(C#N)c(-n2c3ccccc3c3c4oc5ccccc5c4ccc32)c(-n2c3ccccc3c3ccccc32)c1-n1c2ccccc2c2c3oc4ccccc4c3ccc21]

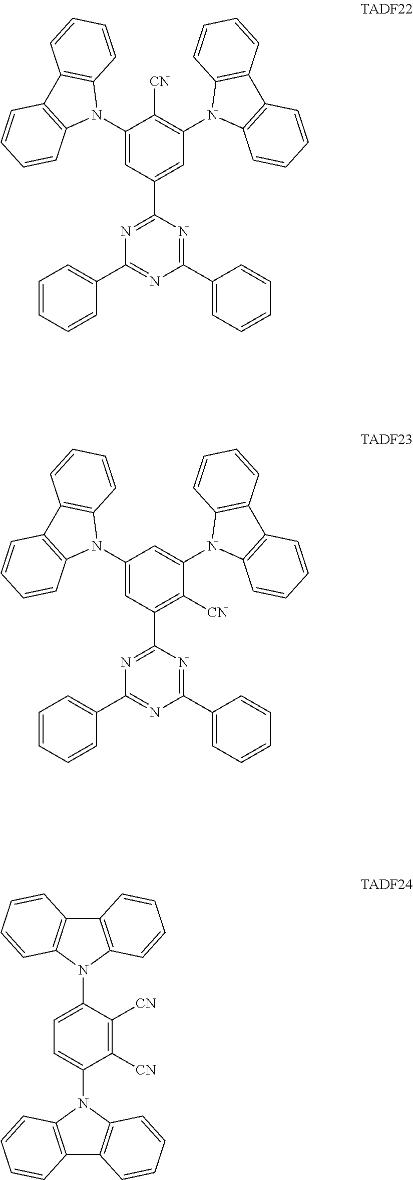 [SMILES: N#Cc1c(-n2c3ccccc3c3ccccc32)cc(-c2nc(-c3ccccc3)nc(-c3ccccc3)n2)cc1-n1c2ccccc2c2ccccc21 ; N#Cc1c(-c2nc(-c3ccccc3)nc(-c3ccccc3)n2)cc(-n2c3ccccc3c3ccccc32)cc1-n1c2ccccc2c2ccccc21 ; N#Cc1c(-n2c3ccccc3c3ccccc32)ccc(-n2c3ccccc3c3ccccc32)c1C#N]

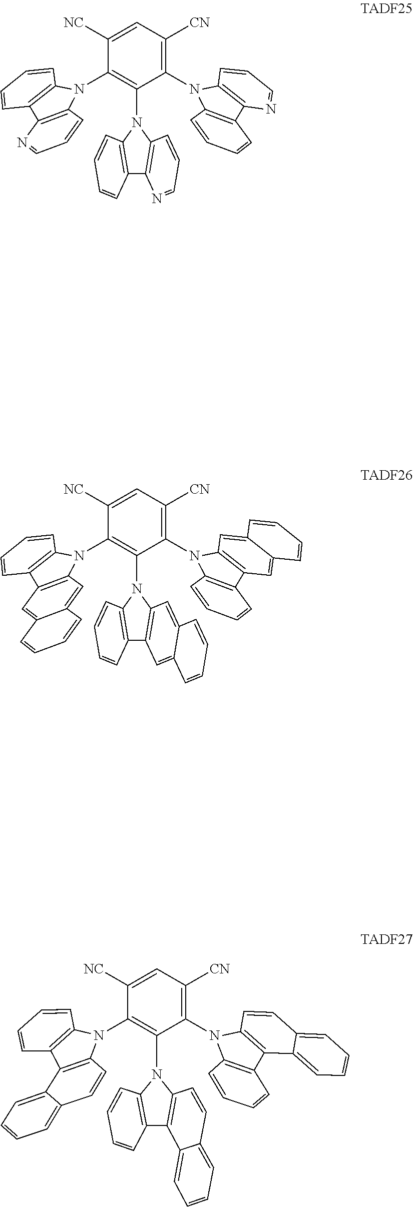 [SMILES: N#Cc1cc(C#N)c(-n2c3ccccc3c3ncccc32)c(-n2c3ccccc3c3ncccc32)c1-n1c2ccccc2c2ncccc21 ; N#Cc1cc(C#N)c(-n2c3ccccc3c3cc4ccccc4cc32)c(-n2c3ccccc3c3cc4ccccc4cc32)c1-n1c2ccccc2c2cc3ccccc3cc21 ; N#Cc1cc(C#N)c(-n2c3ccccc3c3c4ccccc4ccc32)c(-n2c3ccccc3c3c4ccccc4ccc32)c1-n1c2ccccc2c2c3ccccc3ccc21]

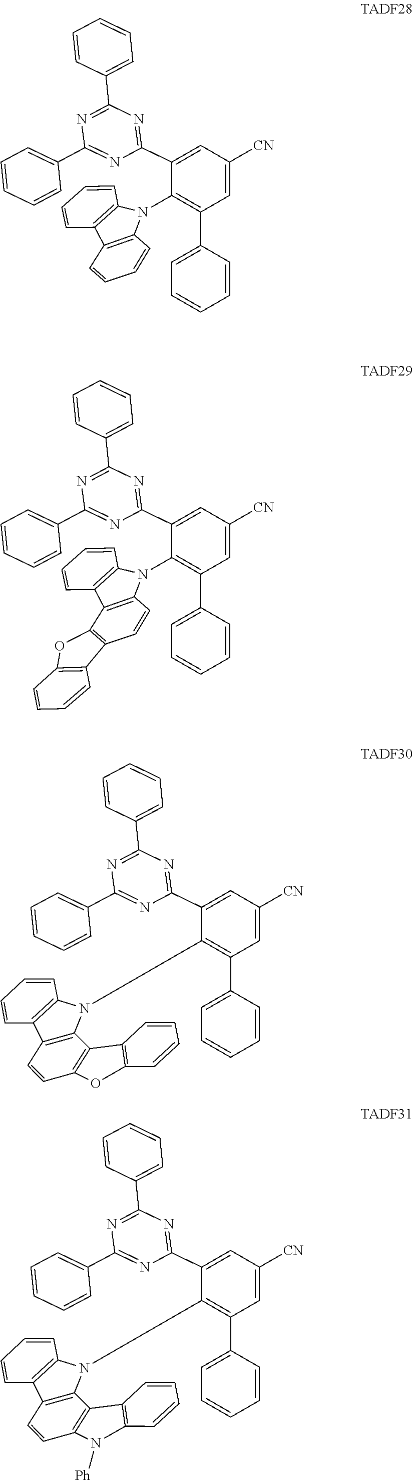 [SMILES: N#Cc1cc(-c2ccccc2)c(-n2c3ccccc3c3ccccc32)c(-c2nc(-c3ccccc3)nc(-c3ccccc3)n2)c1 ; N#Cc1cc(-c2ccccc2)c(-n2c3ccccc3c3c4oc5ccccc5c4ccc32)c(-c2nc(-c3ccccc3)nc(-c3ccccc3)n2)c1 ; N#Cc1cc(-c2ccccc2)c(-n2c3ccccc3c3ccc4oc5ccccc5c4c32)c(-c2nc(-c3ccccc3)nc(-c3ccccc3)n2)c1 ; N#Cc1cc(-c2ccccc2)c(-n2c3ccccc3c3ccc4c(c5ccccc5n4-c4ccccc4)c32)c(-c2nc(-c3ccccc3)nc(-c3ccccc3)n2)c1]

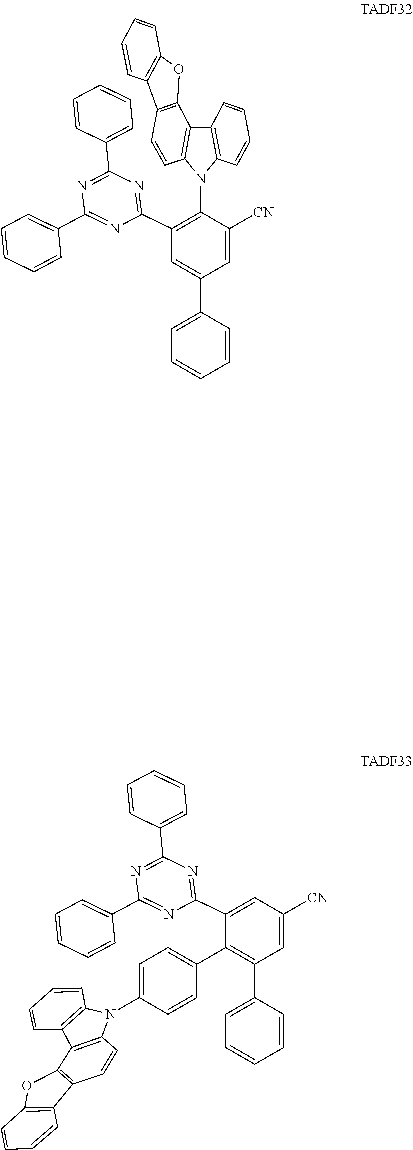 [SMILES: N#Cc1cc(-c2ccccc2)cc(-c2nc(-c3ccccc3)nc(-c3ccccc3)n2)c1-n1c2ccccc2c2c3oc4ccccc4c3ccc21 ; N#Cc1cc(-c2ccccc2)c(-c2ccc(-n3c4ccccc4c4c5oc6ccccc6c5ccc43)cc2)c(-c2nc(-c3ccccc3)nc(-c3ccccc3)n2)c1]

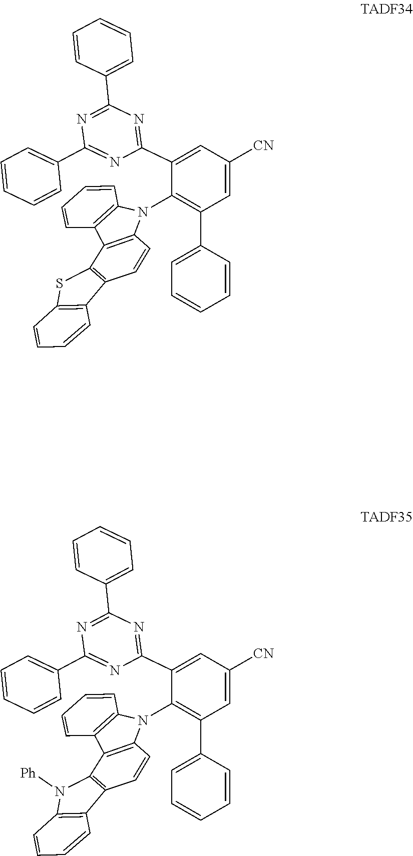 [SMILES: N#Cc1cc(-c2ccccc2)c(-n2c3ccccc3c3c4sc5ccccc5c4ccc32)c(-c2nc(-c3ccccc3)nc(-c3ccccc3)n2)c1 ; N#Cc1cc(-c2ccccc2)c(-n2c3ccccc3c3c2ccc2c4ccccc4n(-c4ccccc4)c23)c(-c2nc(-c3ccccc3)nc(-c3ccccc3)n2)c1]

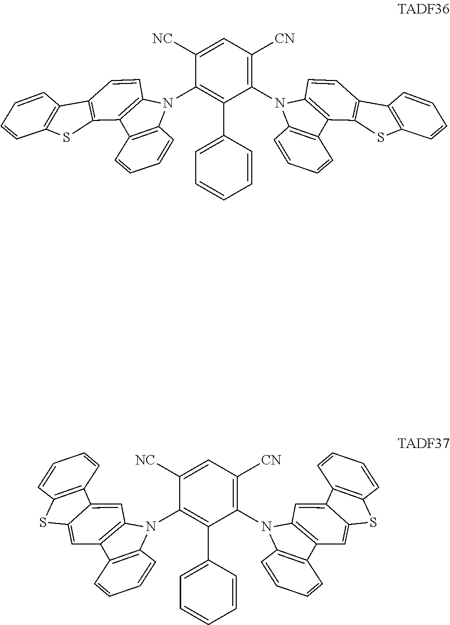 [SMILES: N#Cc1cc(C#N)c(-n2c3ccccc3c3c4sc5ccccc5c4ccc32)c(-c2ccccc2)c1-n1c2ccccc2c2c3sc4ccccc4c3ccc21 ; N#Cc1cc(C#N)c(-n2c3ccccc3c3cc4sc5ccccc5c4cc32)c(-c2ccccc2)c1-n1c2ccccc2c2cc3sc4ccccc4c3cc21]

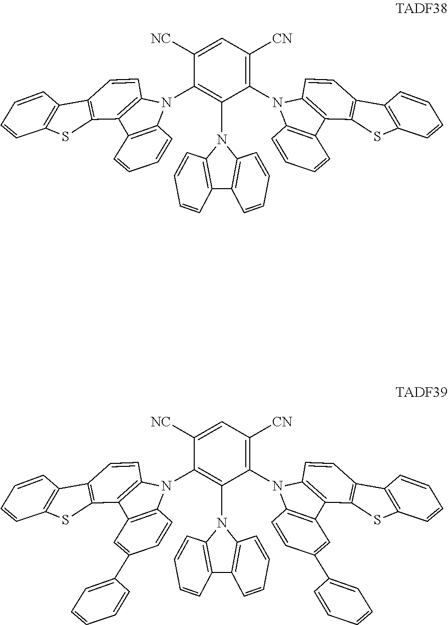 [SMILES: N#Cc1cc(C#N)c(-n2c3ccccc3c3c4sc5ccccc5c4ccc32)c(-n2c3ccccc3c3ccccc32)c1-n1c2ccccc2c2c3sc4ccccc4c3ccc21 ; N#Cc1cc(C#N)c(-n2c3ccc(-c4ccccc4)cc3c3c4sc5ccccc5c4ccc32)c(-n2c3ccccc3c3ccccc32)c1-n1c2ccc(-c3ccccc3)cc2c2c3sc4ccccc4c3ccc21]

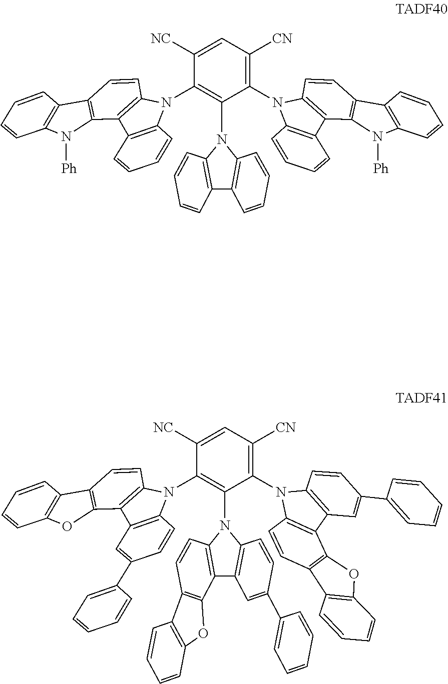 [SMILES: N#Cc1cc(C#N)c(-n2c3ccccc3c3c2ccc2c4ccccc4n(-c4ccccc4)c23)c(-n2c3ccccc3c3ccccc32)c1-n1c2ccccc2c2c1ccc1c3ccccc3n(-c3ccccc3)c12 ; N#Cc1cc(C#N)c(-n2c3ccc(-c4ccccc4)cc3c3c4oc5ccccc5c4ccc32)c(-n2c3ccc(-c4ccccc4)cc3c3c4oc5ccccc5c4ccc32)c1-n1c2ccc(-c3ccccc3)cc2c2c3oc4ccccc4c3ccc21]

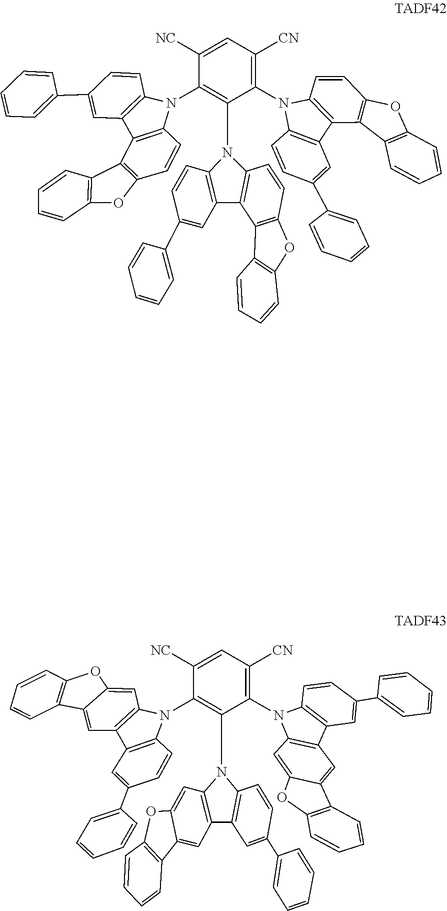 [SMILES: N#Cc1cc(C#N)c(-n2c3ccc(-c4ccccc4)cc3c3c4c(ccc32)oc2ccccc24)c(-n2c3ccc(-c4ccccc4)cc3c3c4c(ccc32)oc2ccccc24)c1-n1c2ccc(-c3ccccc3)cc2c2c3c(ccc21)oc1ccccc13 ; N#Cc1cc(C#N)c(-n2c3ccc(-c4ccccc4)cc3c3cc4c(cc32)oc2ccccc24)c(-n2c3ccc(-c4ccccc4)cc3c3cc4c(cc32)oc2ccccc24)c1-n1c2ccc(-c3ccccc3)cc2c2cc3c(cc21)oc1ccccc13]

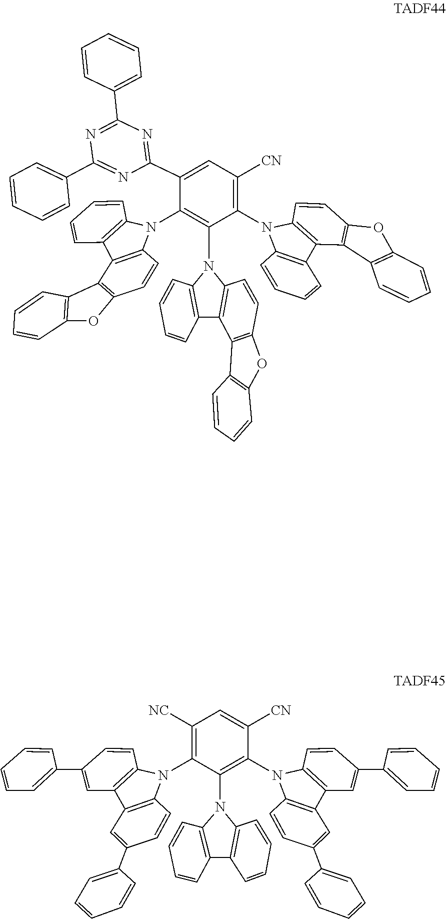 [SMILES: N#Cc1cc(-c2nc(-c3ccccc3)nc(-c3ccccc3)n2)c(-n2c3ccccc3c3c4c(ccc32)oc2ccccc24)c(-n2c3ccccc3c3c4c(ccc32)oc2ccccc24)c1-n1c2ccccc2c2c3c(ccc21)oc1ccccc13 ; N#Cc1cc(C#N)c(-n2c3ccc(-c4ccccc4)cc3c3cc(-c4ccccc4)ccc32)c(-n2c3ccccc3c3ccccc32)c1-n1c2ccc(-c3ccccc3)cc2c2cc(-c3ccccc3)ccc21]

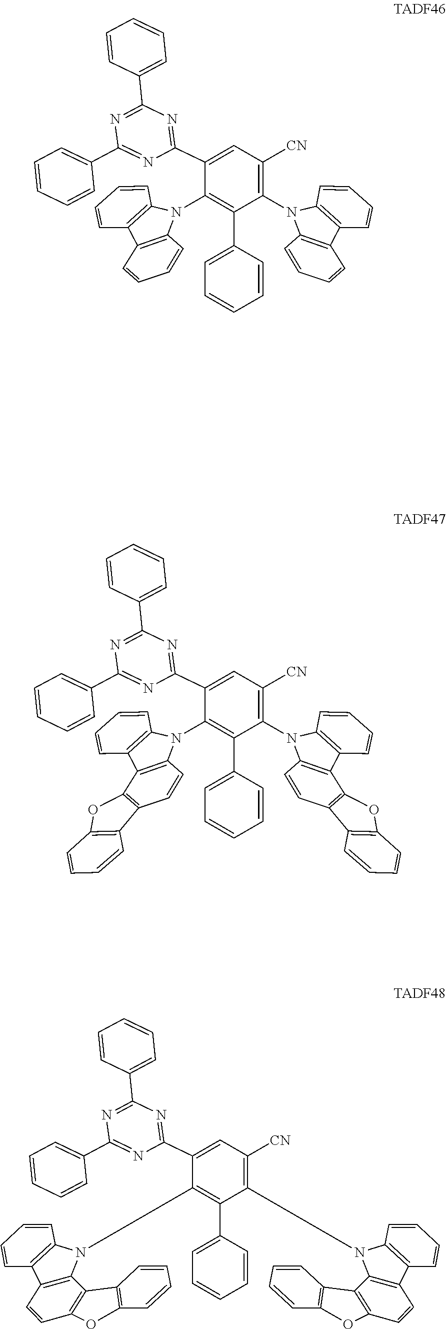 [SMILES: N#Cc1cc(-c2nc(-c3ccccc3)nc(-c3ccccc3)n2)c(-n2c3ccccc3c3ccccc32)c(-c2ccccc2)c1-n1c2ccccc2c2ccccc21 ; N#Cc1cc(-c2nc(-c3ccccc3)nc(-c3ccccc3)n2)c(-n2c3ccccc3c3c4oc5ccccc5c4ccc32)c(-c2ccccc2)c1-n1c2ccccc2c2c3oc4ccccc4c3ccc21 ; N#Cc1cc(-c2nc(-c3ccccc3)nc(-c3ccccc3)n2)c(-n2c3ccccc3c3ccc4oc5ccccc5c4c32)c(-c2ccccc2)c1-n1c2ccccc2c2ccc3oc4ccccc4c3c21]

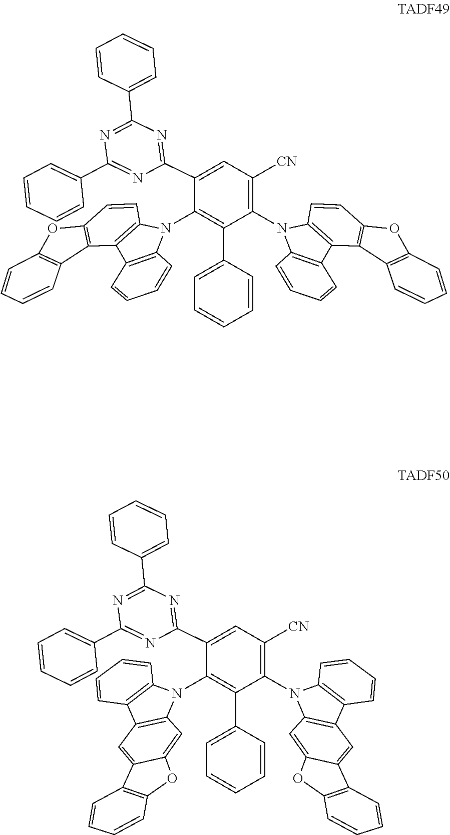 [SMILES: N#Cc1cc(-c2nc(-c3ccccc3)nc(-c3ccccc3)n2)c(-n2c3ccccc3c3c4c(ccc32)oc2ccccc24)c(-c2ccccc2)c1-n1c2ccccc2c2c3c(ccc21)oc1ccccc13 ; N#Cc1cc(-c2nc(-c3ccccc3)nc(-c3ccccc3)n2)c(-n2c3ccccc3c3cc4c(cc32)oc2ccccc24)c(-c2ccccc2)c1-n1c2ccccc2c2cc3c(cc21)oc1ccccc13]

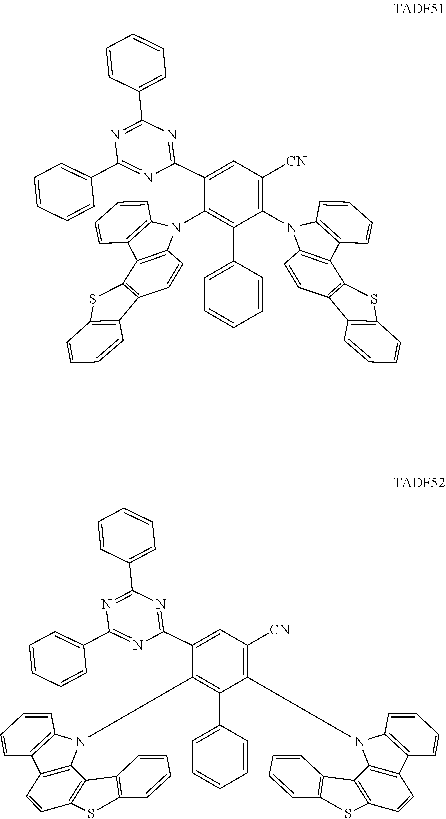 [SMILES: N#Cc1cc(-c2nc(-c3ccccc3)nc(-c3ccccc3)n2)c(-n2c3ccccc3c3c4sc5ccccc5c4ccc32)c(-c2ccccc2)c1-n1c2ccccc2c2c3sc4ccccc4c3ccc21 ; N#Cc1cc(-c2nc(-c3ccccc3)nc(-c3ccccc3)n2)c(-n2c3ccccc3c3ccc4sc5ccccc5c4c32)c(-c2ccccc2)c1-n1c2ccccc2c2ccc3sc4ccccc4c3c21]

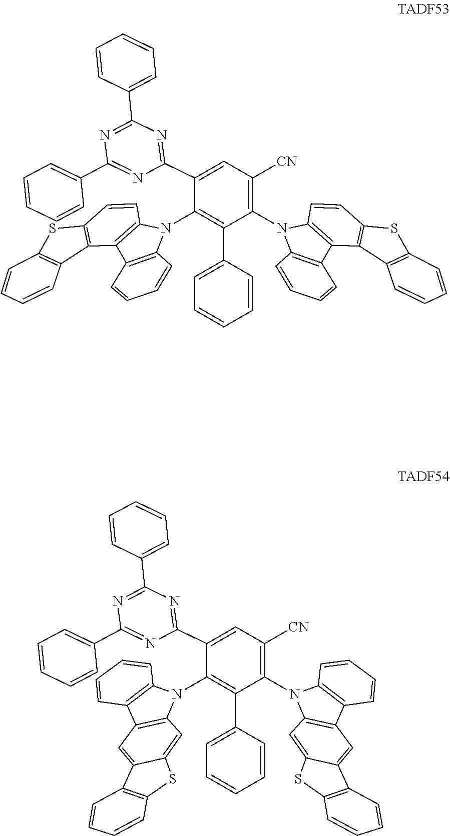 [SMILES: N#Cc1cc(-c2nc(-c3ccccc3)nc(-c3ccccc3)n2)c(-n2c3ccccc3c3c4c(ccc32)sc2ccccc24)c(-c2ccccc2)c1-n1c2ccccc2c2c3c(ccc21)sc1ccccc13 ; N#Cc1cc(-c2nc(-c3ccccc3)nc(-c3ccccc3)n2)c(-n2c3ccccc3c3cc4c(cc32)sc2ccccc24)c(-c2ccccc2)c1-n1c2ccccc2c2cc3c(cc21)sc1ccccc13]

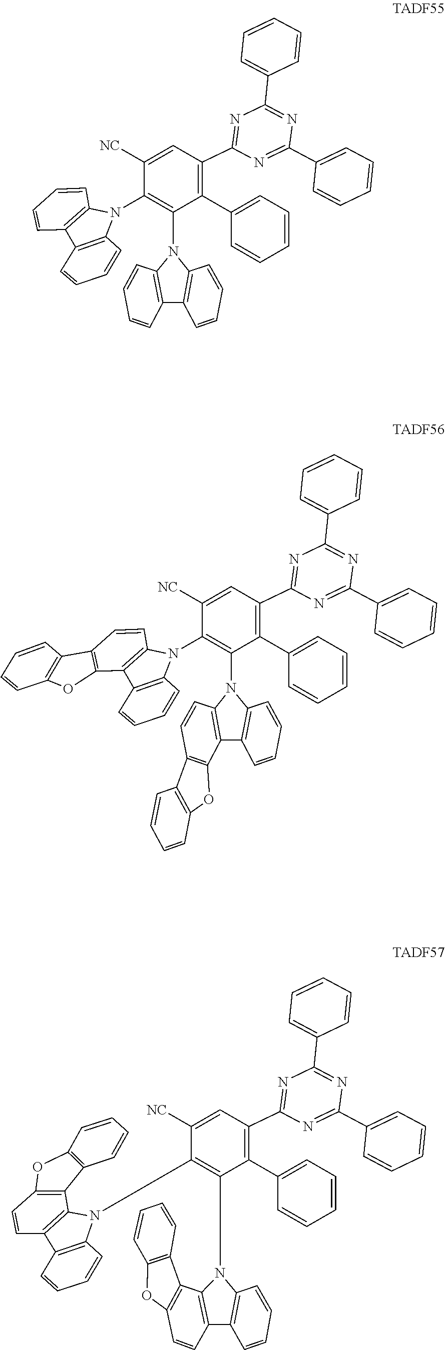 [SMILES: N#Cc1cc(-c2nc(-c3ccccc3)nc(-c3ccccc3)n2)c(-c2ccccc2)c(-n2c3ccccc3c3ccccc32)c1-n1c2ccccc2c2ccccc21 ; N#Cc1cc(-c2nc(-c3ccccc3)nc(-c3ccccc3)n2)c(-c2ccccc2)c(-n2c3ccccc3c3c4oc5ccccc5c4ccc32)c1-n1c2ccccc2c2c3oc4ccccc4c3ccc21 ; N#Cc1cc(-c2nc(-c3ccccc3)nc(-c3ccccc3)n2)c(-c2ccccc2)c(-n2c3ccccc3c3ccc4oc5ccccc5c4c32)c1-n1c2ccccc2c2ccc3oc4ccccc4c3c21]

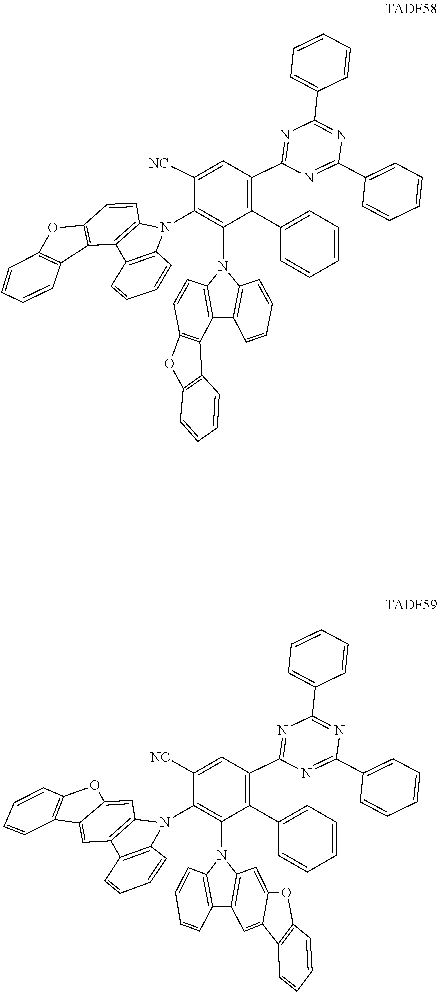 [SMILES: N#Cc1cc(-c2nc(-c3ccccc3)nc(-c3ccccc3)n2)c(-c2ccccc2)c(-n2c3ccccc3c3c4c(ccc32)oc2ccccc24)c1-n1c2ccccc2c2c3c(ccc21)oc1ccccc13 ; N#Cc1cc(-c2nc(-c3ccccc3)nc(-c3ccccc3)n2)c(-c2ccccc2)c(-n2c3ccccc3c3cc4c(cc32)oc2ccccc24)c1-n1c2ccccc2c2cc3c(cc21)oc1ccccc13]

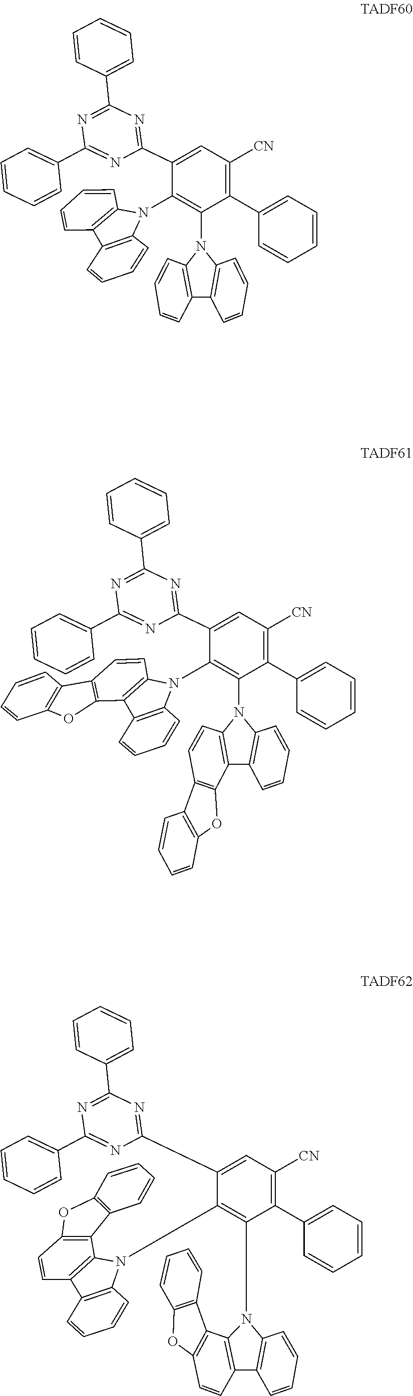 [SMILES: N#Cc1cc(-c2nc(-c3ccccc3)nc(-c3ccccc3)n2)c(-n2c3ccccc3c3ccccc32)c(-n2c3ccccc3c3ccccc32)c1-c1ccccc1 ; N#Cc1cc(-c2nc(-c3ccccc3)nc(-c3ccccc3)n2)c(-n2c3ccccc3c3c4oc5ccccc5c4ccc32)c(-n2c3ccccc3c3c4oc5ccccc5c4ccc32)c1-c1ccccc1 ; N#Cc1cc(-c2nc(-c3ccccc3)nc(-c3ccccc3)n2)c(-n2c3ccccc3c3ccc4oc5ccccc5c4c32)c(-n2c3ccccc3c3ccc4oc5ccccc5c4c32)c1-c1ccccc1]

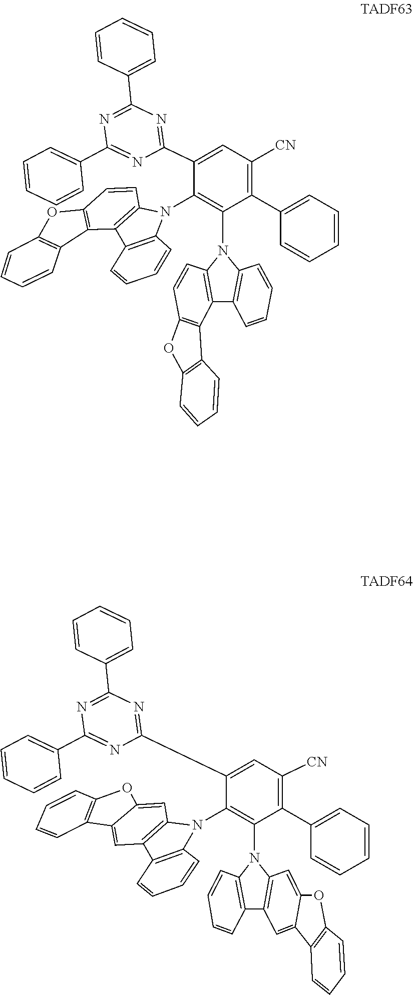 [SMILES: N#Cc1cc(-c2nc(-c3ccccc3)nc(-c3ccccc3)n2)c(-n2c3ccccc3c3c4c(ccc32)oc2ccccc24)c(-n2c3ccccc3c3c4c(ccc32)oc2ccccc24)c1-c1ccccc1 ; N#Cc1cc(-c2nc(-c3ccccc3)nc(-c3ccccc3)n2)c(-n2c3ccccc3c3cc4c(cc32)oc2ccccc24)c(-n2c3ccccc3c3cc4c(cc32)oc2ccccc24)c1-c1ccccc1]

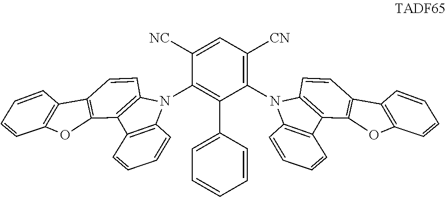 [SMILES: N#Cc1cc(C#N)c(-n2c3ccccc3c3c4oc5ccccc5c4ccc32)c(-c2ccccc2)c1-n1c2ccccc2c2c3oc4ccccc4c3ccc21]

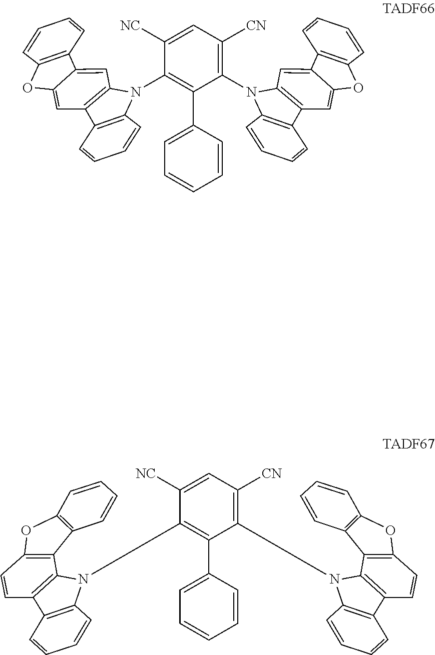 [SMILES: N#Cc1cc(C#N)c(-n2c3ccccc3c3cc4oc5ccccc5c4cc32)c(-c2ccccc2)c1-n1c2ccccc2c2cc3oc4ccccc4c3cc21 ; N#Cc1cc(C#N)c(-n2c3ccccc3c3ccc4oc5ccccc5c4c32)c(-c2ccccc2)c1-n1c2ccccc2c2ccc3oc4ccccc4c3c21]

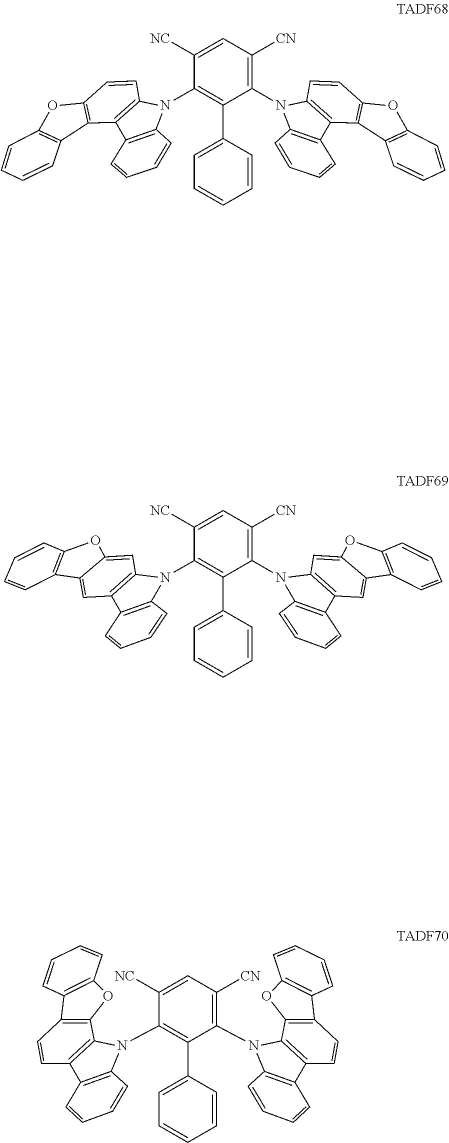 [SMILES: N#Cc1cc(C#N)c(-n2c3ccccc3c3c4c(ccc32)oc2ccccc24)c(-c2ccccc2)c1-n1c2ccccc2c2c3c(ccc21)oc1ccccc13 ; N#Cc1cc(C#N)c(-n2c3ccccc3c3cc4c(cc32)oc2ccccc24)c(-c2ccccc2)c1-n1c2ccccc2c2cc3c(cc21)oc1ccccc13 ; N#Cc1cc(C#N)c(-n2c3ccccc3c3ccc4c5ccccc5oc4c32)c(-c2ccccc2)c1-n1c2ccccc2c2ccc3c4ccccc4oc3c21]

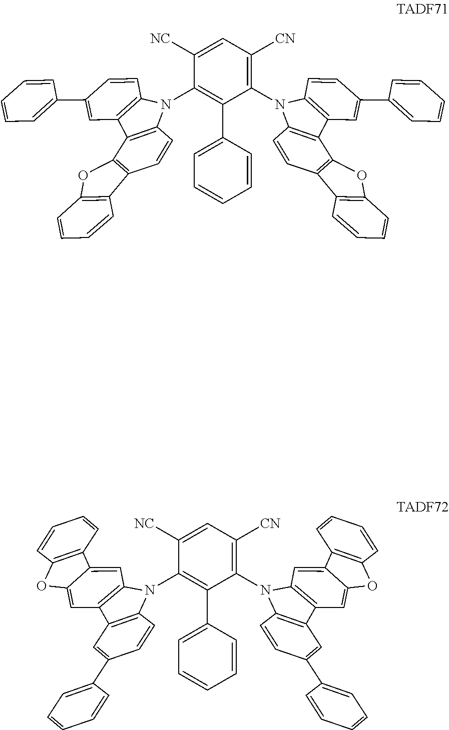 [SMILES: N#Cc1cc(C#N)c(-n2c3ccc(-c4ccccc4)cc3c3c4oc5ccccc5c4ccc32)c(-c2ccccc2)c1-n1c2ccc(-c3ccccc3)cc2c2c3oc4ccccc4c3ccc21 ; N#Cc1cc(C#N)c(-n2c3ccc(-c4ccccc4)cc3c3cc4oc5ccccc5c4cc32)c(-c2ccccc2)c1-n1c2ccc(-c3ccccc3)cc2c2cc3oc4ccccc4c3cc21]

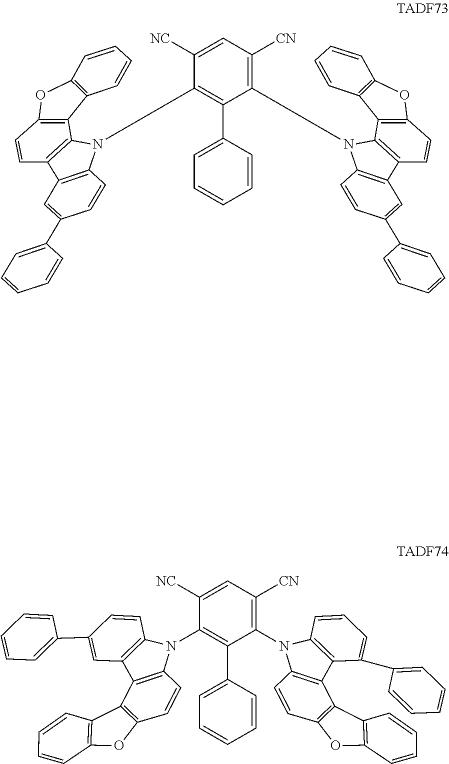 [SMILES: N#Cc1cc(C#N)c(-n2c3ccc(-c4ccccc4)cc3c3ccc4oc5ccccc5c4c32)c(-c2ccccc2)c1-n1c2ccc(-c3ccccc3)cc2c2ccc3oc4ccccc4c3c21 ; N#Cc1cc(C#N)c(-n2c3cccc(-c4ccccc4)c3c3c4c(ccc32)oc2ccccc24)c(-c2ccccc2)c1-n1c2ccc(-c3ccccc3)cc2c2c3c(ccc21)oc1ccccc13]

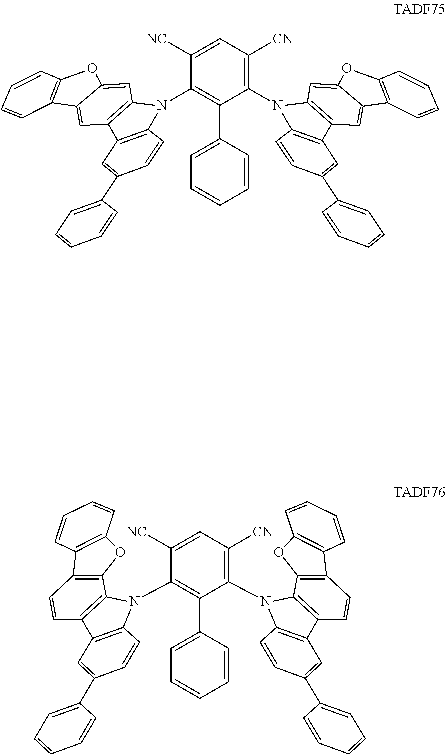 [SMILES: N#Cc1cc(C#N)c(-n2c3ccc(-c4ccccc4)cc3c3cc4c(cc32)oc2ccccc24)c(-c2ccccc2)c1-n1c2ccc(-c3ccccc3)cc2c2cc3c(cc21)oc1ccccc13 ; N#Cc1cc(C#N)c(-n2c3ccc(-c4ccccc4)cc3c3ccc4c5ccccc5oc4c32)c(-c2ccccc2)c1-n1c2ccc(-c3ccccc3)cc2c2ccc3c4ccccc4oc3c21]

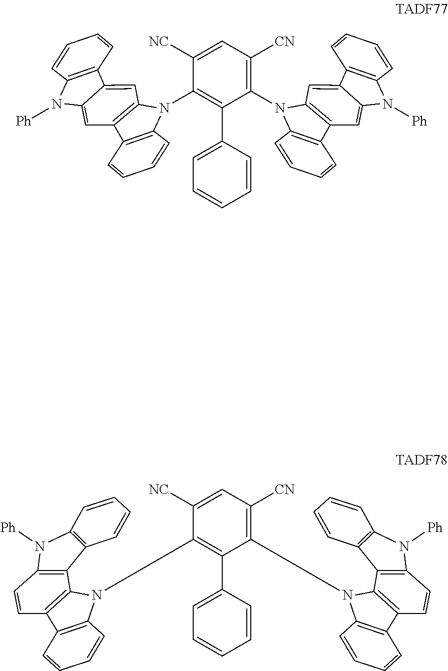 [SMILES: N#Cc1cc(C#N)c(-n2c3ccccc3c3cc4c(cc32)c2ccccc2n4-c2ccccc2)c(-c2ccccc2)c1-n1c2ccccc2c2cc3c(cc21)c1ccccc1n3-c1ccccc1 ; N#Cc1cc(C#N)c(-n2c3ccccc3c3ccc4c(c5ccccc5n4-c4ccccc4)c32)c(-c2ccccc2)c1-n1c2ccccc2c2ccc3c(c4ccccc4n3-c3ccccc3)c21]

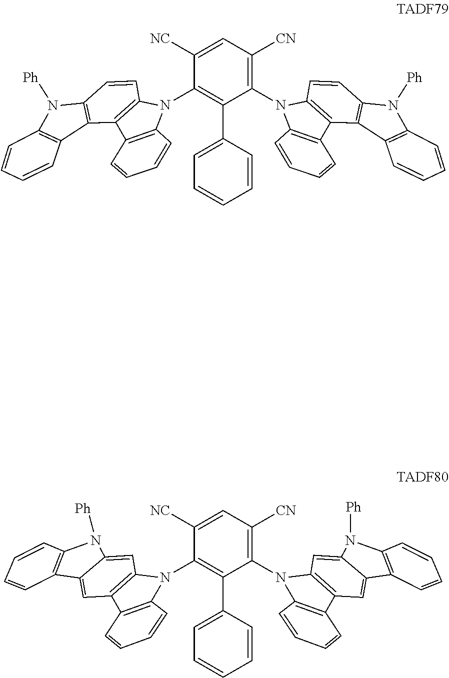 [SMILES: N#Cc1cc(C#N)c(-n2c3ccccc3c3c4c5ccccc5n(-c5ccccc5)c4ccc32)c(-c2ccccc2)c1-n1c2ccccc2c2c3c4ccccc4n(-c4ccccc4)c3ccc21 ; N#Cc1cc(C#N)c(-n2c3ccccc3c3cc4c5ccccc5n(-c5ccccc5)c4cc32)c(-c2ccccc2)c1-n1c2ccccc2c2cc3c4ccccc4n(-c4ccccc4)c3cc21]

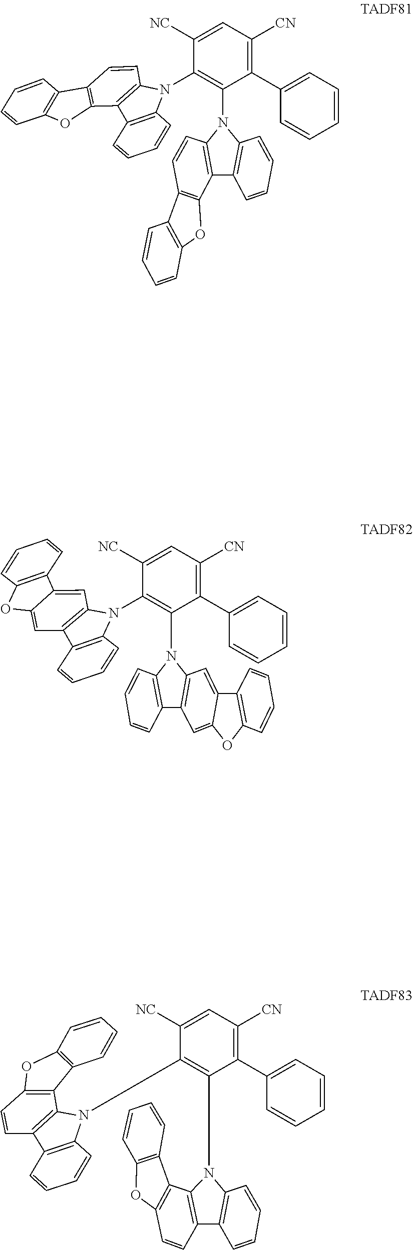 [SMILES: N#Cc1cc(C#N)c(-n2c3ccccc3c3c4oc5ccccc5c4ccc32)c(-n2c3ccccc3c3c4oc5ccccc5c4ccc32)c1-c1ccccc1 ; N#Cc1cc(C#N)c(-n2c3ccccc3c3cc4oc5ccccc5c4cc32)c(-n2c3ccccc3c3cc4oc5ccccc5c4cc32)c1-c1ccccc1 ; N#Cc1cc(C#N)c(-n2c3ccccc3c3ccc4oc5ccccc5c4c32)c(-n2c3ccccc3c3ccc4oc5ccccc5c4c32)c1-c1ccccc1]

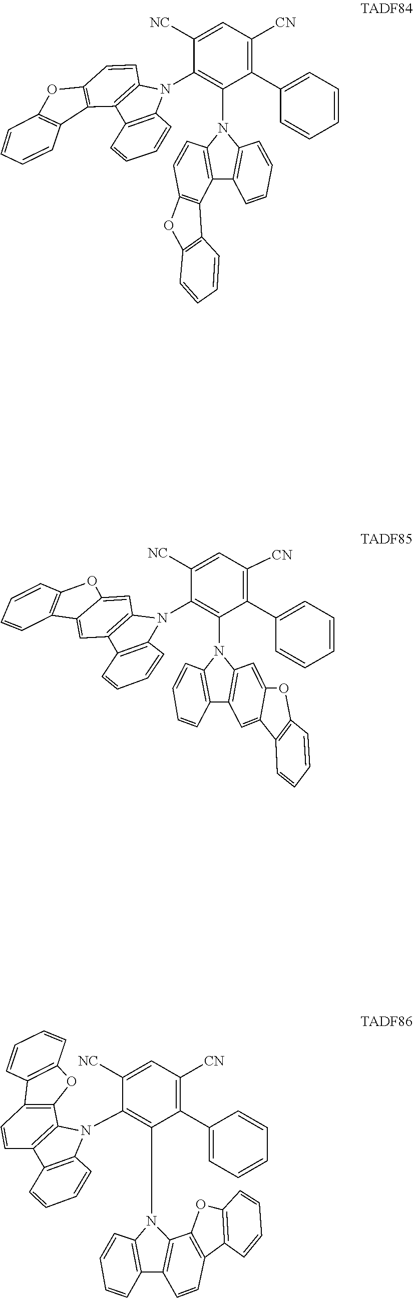 [SMILES: N#Cc1cc(C#N)c(-n2c3ccccc3c3c4c(ccc32)oc2ccccc24)c(-n2c3ccccc3c3c4c(ccc32)oc2ccccc24)c1-c1ccccc1 ; N#Cc1cc(C#N)c(-n2c3ccccc3c3cc4c(cc32)oc2ccccc24)c(-n2c3ccccc3c3cc4c(cc32)oc2ccccc24)c1-c1ccccc1 ; N#Cc1cc(C#N)c(-n2c3ccccc3c3ccc4c5ccccc5oc4c32)c(-n2c3ccccc3c3ccc4c5ccccc5oc4c32)c1-c1ccccc1]

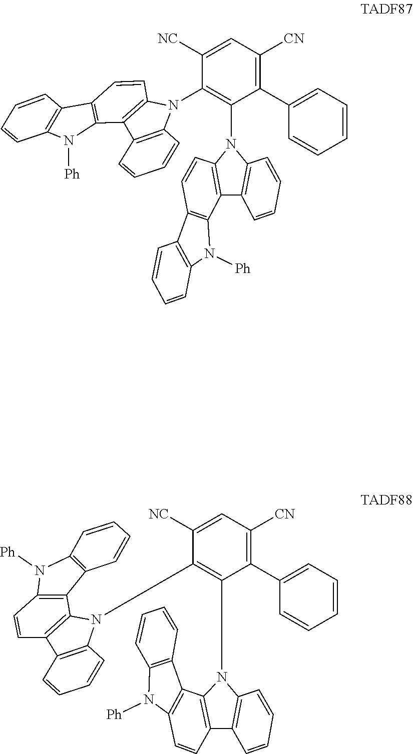 [SMILES: N#Cc1cc(C#N)c(-n2c3ccccc3c3c2ccc2c4ccccc4n(-c4ccccc4)c23)c(-n2c3ccccc3c3c2ccc2c4ccccc4n(-c4ccccc4)c23)c1-c1ccccc1 ; N#Cc1cc(C#N)c(-n2c3ccccc3c3ccc4c(c5ccccc5n4-c4ccccc4)c32)c(-n2c3ccccc3c3ccc4c(c5ccccc5n4-c4ccccc4)c32)c1-c1ccccc1]

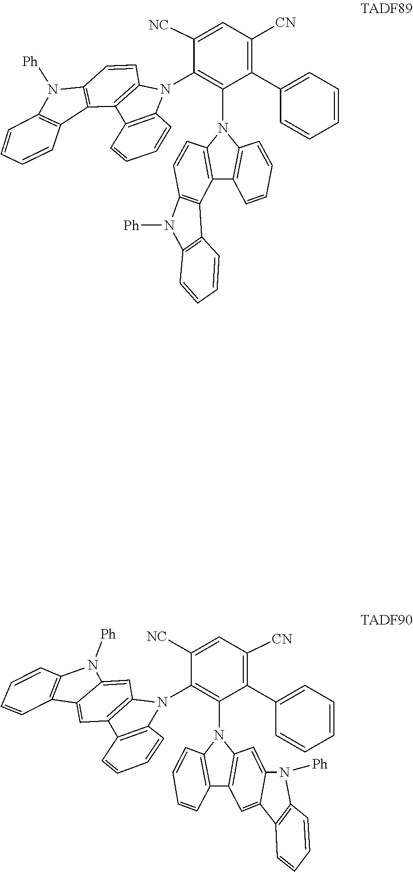 [SMILES: N#Cc1cc(C#N)c(-n2c3ccccc3c3c4c5ccccc5n(-c5ccccc5)c4ccc32)c(-n2c3ccccc3c3c4c5ccccc5n(-c5ccccc5)c4ccc32)c1-c1ccccc1 ; N#Cc1cc(C#N)c(-n2c3ccccc3c3cc4c5ccccc5n(-c5ccccc5)c4cc32)c(-n2c3ccccc3c3cc4c5ccccc5n(-c5ccccc5)c4cc32)c1-c1ccccc1]

Any other known delayed fluorescent materials than the above can be appropriately combined and used as the second organic compound. In addition, unknown delayed fluorescent materials can also be used.

As delayed fluorescent materials, there can be mentioned compounds included in the general formulae described in WO2013/154064, paragraphs 0008 to 0048 and 0095 to 0133; WO2013/011954, paragraphs 0007 to 0047 and 0073 to 0085; WO2013/011955, paragraphs 0007 to 0033 and 0059 to 0066; WO2013/081088, paragraphs 0008 to 0071 and 0118 to 0133; JP2013-256490A, paragraphs 0009 to 0046 and 0093 to 0134; JP2013-116975A, paragraphs 0008 to 0020 and 0038 to 0040; WO2013/133359, paragraphs 0007 to 0032 and 0079 to 0084; WO2013/161437, paragraphs 0008 to 0054 and 0101 to 0121; JP2014-9352A, paragraphs 0007 to 0041 and 0060 to 0069; and JP2014-9224A, paragraphs 0008 to 0048 and 0067 to 0076; JP2017-119663A, paragraphs 0013 to 0025; JP2017-119664A, paragraphs 0013 to 0026; JP2017-222623A, paragraphs 0012 to 0025; JP2017-226838A, paragraphs 0010 to 0050; JP2018-100411A, paragraphs 0012 to 0043; WO2018/047853, paragraphs 0016 to 0044; and especially, exemplary compounds therein capable of emitting delayed fluorescence. In addition, also preferably employable here are light emitting materials capable of emitting delayed fluorescence, as described in JP 2013-253121 A, WO2013/133359, WO2014/034535, WO2014/115743, WO2014/122895, WO2014/126200, WO2014/136758, WO2014/133121, WO2014/136860, WO2014/196585, WO2014/189122, WO2014/168101, WO2015/008580, WO2014/203840, WO2015/002213, WO2015/016200, WO2015/019725, WO2015/072470, WO2015/108049, WO2015/080182, WO2015/072537, WO2015/080183, JP2015-129240A, WO2015/129714, WO2015/129715, WO2015/133501, WO2015/136880, WO2015/137244, WO2015/137202, WO2015/137136, WO2015/146541 and WO2015/159541. These patent publications described in this paragraph are hereby incorporated as a part of this description by reference.

Preferably, the second organic compound does not contain a metal atom. For example, as the second organic compound, a compound composed of atoms selected from the group consisting of a carbon atom, a hydrogen atom, a nitrogen atom, an oxygen atom and a sulfur atom can be selected. For example, as the second organic compound, a compound composed of atoms selected from the group consisting of a carbon atom, a hydrogen atom, a nitrogen atom and an oxygen atom can be selected. For example, as the second organic compound, a compound composed of a carbon atom, a hydrogen atom and a nitrogen atom can be selected.

### (Third Organic Compound)

The third organic compound used in the light emitting layer of the organic electroluminescent device of the present invention is a fluorescent material having a smaller lowest excited singlet energy than the first organic compound and the second organic compound, and having a larger LUMO energy than the second organic compound. The organic electroluminescent device of the present indention emits fluorescence derived from the third organic compound. Light emission from the third organic compound generally includes delayed fluorescence. The maximum component of light emission from the organic electroluminescent device of the present invention is light emission from the third organic compound. Specifically, of the light emission from the organic electroluminescent device of the present invention, the amount of light emission from the third organic compound is the largest. 70% or more of light emission from the organic electroluminescent device can be light emission from the third organic compound, or 90% or more can be from the third organic compound, or 99% or more can be from the third organic compound. The third organic compound receives energy from the first organic compound in an excited singlet state, from the second organic compound in an excited singlet state, and from the second organic compound that has been in an excited singlet state through reverse intersystem crossing from an excited triplet state, and thus transitions into an excited singlet state. In a preferred embodiment of the present invention, the third organic compound receives energy from the second organic compound in an excited singlet state and from the second organic state that has been in an excited singlet state through reverse intersystem crossing from an excited triplet state, and thus transitions into an excited singlet state. The resultant third organic compound thus in an excited singlet state emits fluorescence when thereafter returning back to a ground state.

The fluorescent material to be used as the third organic compound is not specifically limited so far as it can receive energy from the first organic compound and the second organic compound in the manner as above to emit light, and the light emission can include any of fluorescence, delayed fluorescence and phosphorescence. Preferably, the light emission includes fluorescence and delayed fluorescence, and more preferred is a case where the maximum component of light emission from the third organic compound is fluorescence. In one embodiment of the present invention, the organic electroluminescent device does not emit phosphorescence, or the radiation amount of phosphorescence from the device is not more than 1% of fluorescence therefrom.

Two or more kinds of third organic compounds can be used as combined so far as they satisfy the requirements in the present invention. For example, by using two or more kinds of the third organic compounds that differ in the emission color, light of a desired color can be emitted. Also, by using one kind of the third organic compound, monochromatic emission can be made by the third organic compound.

In the present invention, the maximum emission wavelength of the compound usable as the third organic compound is not specifically limited. Therefore, a light emitting material having a maximum emission wavelength in a visible range (380 to 780 nm) or having a maximum emission wavelength in an IR range (780 nm to 1 mm), or a compound having a maximum emission wavelength in a UV range (for example, 280 to 380 nm) can be appropriately selected and used here. Preferred is a fluorescent material having a maximum emission wavelength in a visible range. For example, a light emitting material of which the maximum emission wavelength in a range of 380 to 780 nm falls within a range of 380 to 570 nm can be selected and used, a light emitting material of which the maximum emission wavelength falls within a range of 570 to 650 nm can be selected and used, a light emitting material of which the maximum emission wavelength falls within a range of 650 to 700 nm can be selected and used, or a light emitting material of which the maximum emission wavelength falls within a range of 700 to 780 nm can be selected and used. In one preferred embodiment of the present invention, the maximum emission wavelength of the third organic compound is longer than 570 nm.

In a preferred embodiment of the present invention, the second organic compound and the third organic compound are so selected and combined that the emission wavelength range of the former and the emission wavelength range of the latter can overlap with each other. Especially preferably, the edge in the short wavelength side of the emission spectrum of the second organic compound overlaps with the edge on the long wavelength side of the absorption spectrum of the third organic compound.

Preferably, the third organic compound does not contain a metal atom other than a boron atom. For example, as the third organic compound a compound composed of atoms selected from the group consisting of a carbon atom, a hydrogen atom, a nitrogen atom, an oxygen atom, a sulfur atom, a fluorine atom and a boron atom can be selected. For example, as the third organic compound, a compound composed of atoms selected from the group consisting of a carbon atom, a hydrogen atom, a nitrogen atom, an oxygen atom, a fluorine atom and a boron atom can be selected.

Examples of the third organic compound include a compound having a BODIPY (4,4-difluoro-4-bora-3a,4a-diaza-s-indacene) structure, and a compound containing a condensed aromatic ring structure such as anthracene, pyrene and perylene.

In one preferred embodiment of the present invention, a compound represented by the following general formula (1) is used as the third organic compound.

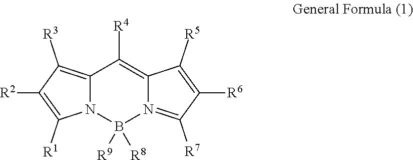

In the general formula (1), R¹ to R⁷ each independently represent a hydrogen atom or a substituent. At least one of R¹ to R⁷ is preferably a group represented by the following general formula (2).

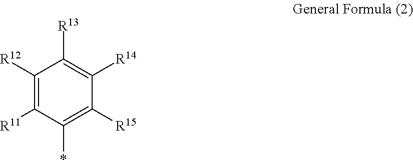

In the general formula (2), R¹¹ to R¹⁵ each independently represent a hydrogen atom or a substituent, and * indicates a bonding position.

Preferably, at least four, for example, four or five of R¹ to R⁷ in the general formula (1) each are a group represented by the general formula (2). In one preferred embodiment of the present invention, five of R¹ to R⁷ each are a group represented by the general formula (2). In one preferred embodiment of the present invention, at least R¹, R³, R⁵, and R⁷ each are a group represented by the general formula (2). In one preferred embodiment of the present invention, only, R¹, R³, R⁴, R⁵, and R⁷ are groups represented by the general formula (2). In one preferred embodiment of the present invention, R¹, R³, R⁴, R⁵, and R⁷ each are a group represented by the general formula (2) and R² and R⁴ each are a hydrogen atom, an unsubstituted alkyl group (for example, having 1 to 10 carbon atoms), or an unsubstituted aryl group (for example, having 6 to 14 carbon atoms). In one embodiment of the present invention, all R¹ to R⁷ are groups represented by the general formula (2).

In one preferred embodiment of the present invention, R¹ and R⁷ are the same. In one preferred embodiment of the present invention, R³ and R⁵ are the same. In one preferred embodiment of the present invention, R² and R⁶ are the same. In one preferred embodiment of the present invention, R¹ and R⁷ are the same, R³ and R⁵ are the same, and R¹ and R³ differ from each other. In one preferred embodiment of the present invention, R¹, R³, R⁵, and R⁷ are the same. In one preferred embodiment of the present invention, R¹, R⁴ and R⁷ are the same, and differ from R³ and R⁵. In one preferred embodiment of the present invention, R³, R⁴ and R⁵ are the same, and differ from R¹ and R⁷. In one preferred embodiment of the present invention, R¹, R³, R⁵, and R⁷ all differ from R⁴.

As the substituent that R¹¹ to R¹⁵ can take in the general formula (2), for example, groups of the above-mentioned Substituent Group A can be selected, or groups of the above-mentioned Substituent Group B can be selected. The substituent that R¹¹ to R¹⁵ can take is preferably a group or a combination of two or more groups selected from the group consisting of a substituted or unsubstituted alkyl group (for example, having 1 to 40 carbon atoms), a substituted or unsubstituted alkoxy group (for example, having 1 to 40 carbon atoms), a substituted or unsubstituted aryl group (for example, having 6 to 30 carbon atoms), a substituted or unsubstituted aryloxy group (for example, having 6 to 30 carbon atoms), and a substituted or unsubstituted amino group (for example, having 0 to 20 carbon atoms). Hereinunder these groups are referred to as “groups of Substituent Group C”. Among the Substituent Group C, preferably, an unsubstituted alkyl group having 1 to 20 carbon atoms, an unsubstituted alkoxy group having 1 to 20 carbon atoms, an unsubstituted aryl group having 6 to 14 carbon atoms, an aryloxy group having 6 to 14 carbon atoms, or an unsubstituted diarylamino group having 5 to 20 ring skeleton-constituting atoms is selected. Hereinunder these groups are referred to as “groups of Substituent Group D”. Here the substituted amino group is preferably a di-substituted amino group, in which the two substituents of the amino group are preferably each independently a substituted or unsubstituted aryl group, a substituted or unsubstituted heteroaryl group, or a substituted or unsubstituted alkyl group, especially preferably a substituted or unsubstituted aryl group (that is, the amino group is a diarylamino group). As the substituent that the two aryl groups of the diarylamino group can take, the groups of the above-mentioned Substituent Group B can be selected, or the groups of the above-mentioned Substituent Group C can be selected. The two aryl groups of the diarylamino group can bond to each other via a single bond or a linking group, and for the linking group, reference can be made to the description of the linking group in R³³ and R³⁴. Specific examples of the diarylamino group employable herein include a substituted or unsubstituted carbazol-9-yl group. Examples of the substituted or unsubstituted carbazol-9-yl group include groups of the general formula (6) where L¹¹ is a single bond.

In one preferred embodiment of the present invention, only R¹³ in the general formula (2) is a substituent and R¹¹, R¹², R¹⁴, and R¹⁵ are hydrogen atoms. In one preferred embodiment of the present invention, only R¹¹ in the general formula (2) is a substituent and R¹², R¹³, R¹⁴, and R¹⁵ are hydrogen atoms. In one preferred embodiment of the present invention, R¹¹ and R¹³ alone in the general formula (2) are substituents, and R¹², R¹⁴, and R¹⁵ are hydrogen atoms.

R¹ to R⁷ in the general formula (1) can include a group where R¹¹ to R¹⁵ in the general formula (2) are all hydrogen atoms (that is, a phenyl group). For example, R², R⁴, and R⁶ can be phenyl groups.

In the general formula (1), R⁸ and R⁹ are preferably each independently represent a group or a combination of two or more groups selected from the group consisting of a hydrogen atom, a halogen atom, an alkyl group (for example, having 1 to 40 carbon atoms), an alkoxy group (for example, having 1 to 40 carbon atoms), an aryloxy group (for example, having 6 to 30 carbon atoms) and a cyano group. In a preferred embodiment of the present invention, R⁸ and R⁹ are the same. In a preferred embodiment of the present invention, R⁸ and R⁹ are halogen atoms, especially preferably fluorine atoms.

The total number of the substituted or unsubstituted alkoxy group, the substituted or unsubstituted aryloxy group and the substituted or unsubstituted amino group existing in R¹ to R⁹ in the general formula (1) is preferably 3 or more. For example, a compound having three such groups can be employed, or a compound having four such groups can be employed. More preferably, the total number of the substituted or unsubstituted alkoxy group, the substituted or unsubstituted aryloxy group and the substituted or unsubstituted amino group existing in R¹ to R⁷ in the general formula (1) is 3 or more. For example, a compound having three such groups can be employed, or a compound having four such groups can be employed. At that time, an alkoxy group, an aryloxy group and an amino group may not exist in R⁸ and R⁹. Even more preferably, the total number of the substituted or unsubstituted alkoxy group, the substituted or unsubstituted aryloxy group and the substituted or unsubstituted amino group existing in R¹, R³, R⁴, R⁵, and R⁷ in the general formula (1) is 3 or more. For example, a compound having three such groups can be employed, or a compound having four such groups can be employed. At that time, an alkoxy group, an aryloxy group and an amino group may not exist in R², R⁶, R⁸, and R⁹. In one preferred embodiment of the present invention, three or more substituted or unsubstituted alkoxy group exist in the compound. In a preferred embodiment of the present invention, four or more substituted or unsubstituted alkoxy group exist in the compound. In one preferred embodiment of the present invention, one or more substituted or unsubstituted alkoxy groups and two or more substituted or unsubstituted aryloxy groups exist in the compound. In one preferred embodiment of the present invention, two or more substituted or unsubstituted alkoxy groups and one or more substituted or unsubstituted amino groups exist in the compound. In one preferred embodiment of the present invention, a substituted or unsubstituted alkoxy group or a substituted or unsubstituted aryloxy group exists in each R¹, R⁴, and R⁷. In one preferred embodiment of the present invention, a substituted or unsubstituted alkoxy group exists in each R¹, R⁴, and R⁷.

The total number of the substituents having a Hammett's a p value of less than −0.2 existing in R¹ to R⁹ in the general formula (1) is preferably 3 or more. Here, “Hammett's σₚ value” is one propounded by L. P. Hammett, and is one to quantify the influence of a substituent on the reaction rate or the equilibrium of a para-substituted benzene derivative. Specifically, the value is a constant (σₚ) peculiar to the substituent in the following equation that is established between a substituent and a reaction rate constant or an equilibrium constant in a para-substituted benzene derivative:

log(k/k₀)=ρσₚ

or

log(K/K₀)=ρσₚ

In the above equations, k represents a rate constant of a benzene derivative not having a substituent; k₀ represents a rate constant of a benzene derivative substituted with a substituent; K represents an equilibrium constant of a benzene derivative not having a substituent; K₀ represents an equilibrium constant of a benzene derivative substituted with a substituent; p represents a reaction constant to be determined by the kind and the condition of reaction. Regarding the description relating to the “Hammett's σₚ value” and the numerical value of each substituent, reference may be made to the description relating to σₚ value in Hansch, C. et. al., Chem. Rev., 91, 165-195 (1991). A group having a negative Hammett's σₚ value tends to exhibit electron donating performance (donor performance), and a group having a positive Hammett's σₚ value tends to exhibit electron accepting performance (acceptor performance).

Examples of the substituent having a Hammett's σₚ value of less than −0.2 include a methoxy group (−0.27), an ethoxy group (−0.24), an n-propoxy group (−0.25), an isopropoxy group (−0.45), and an n-butoxy group (−0.32). On the other hand, a fluorine atom (0.06), a methyl group (−0.17), an ethyl group (−0.15), a tert-butyl group (−0.20), an n-hexyl group (−0.15) and a cyclohexyl group (−0.15) are not substituents having a Hammett's σₚ value of less than −0.2.

In one embodiment of the present invention, a compound of the general formula (1) in which the number of the substituents having a Hammett's σₚ value of less than −0.2 existing in R¹ to R⁹ is three can be employed, or a compound having four such substituents can be employed. More preferably, the number of the substituents having a Hammett's σₚ value of less than −0.2 existing in R¹ to R⁷ is three or more, and for example, a compound having three such substituents can be employed, or a compound having four such substituents can be employed. At that time, a substituent having a Hammett's σₚ value of less than −0.2 may not exist in R⁸ and R⁹. Even more preferably, the number of the substituents having a Hammett's σₚ value of less than −0.2 existing in R¹, R³, R⁴, R⁵, and R⁷ in the general formula (1) is three or more, and for example, a compound having three such substituents can be employed, or a compound having four such substituents can be employed. At that time, a substituent having a Hammett's σₚ value of less than −0.2 may not exist in R², R⁶, R⁸, and R⁹. In one preferred embodiment of the present invention, a substituent having a Hammett's σₚ value of less than −0.2 exists in each R¹, R⁴, and R⁷.

Preferred compounds for use as the third organic compound are shown below. In the structural formulae of the following exemplary compounds, t-Bu represents a tertiary butyl group.

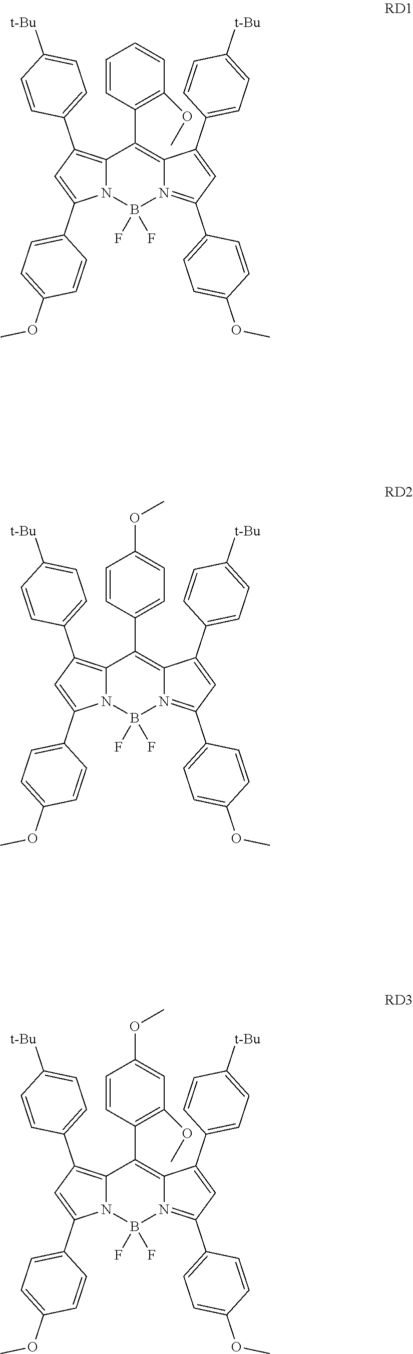

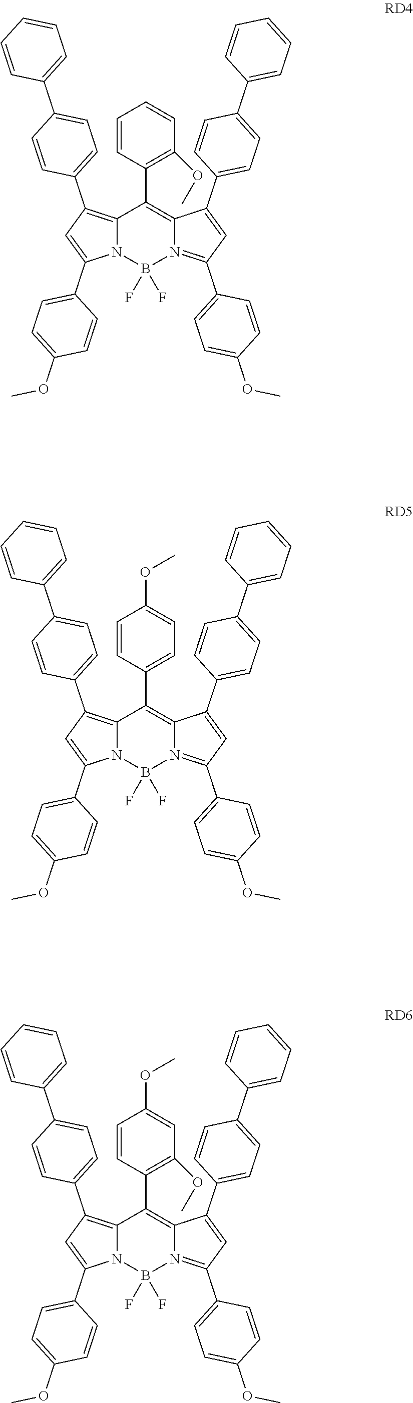

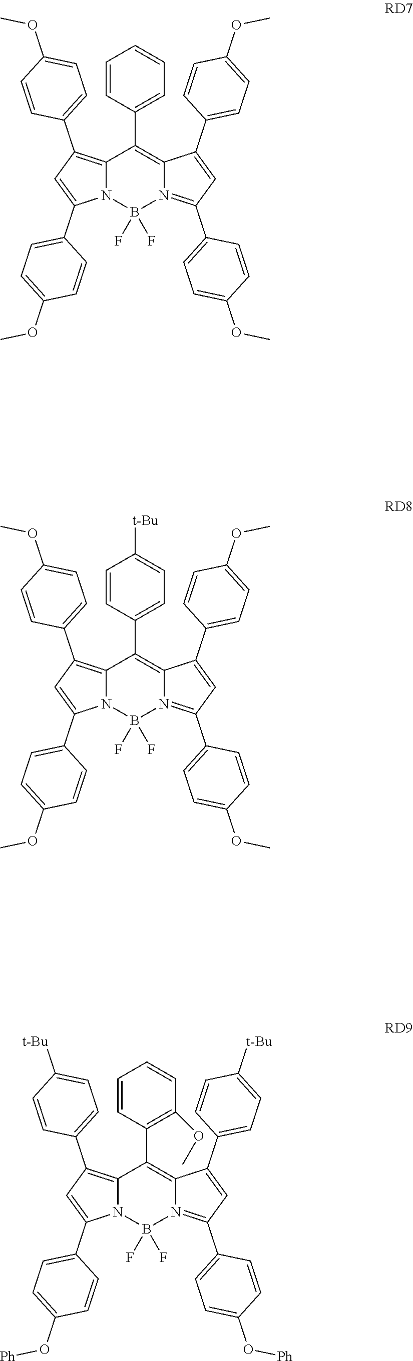

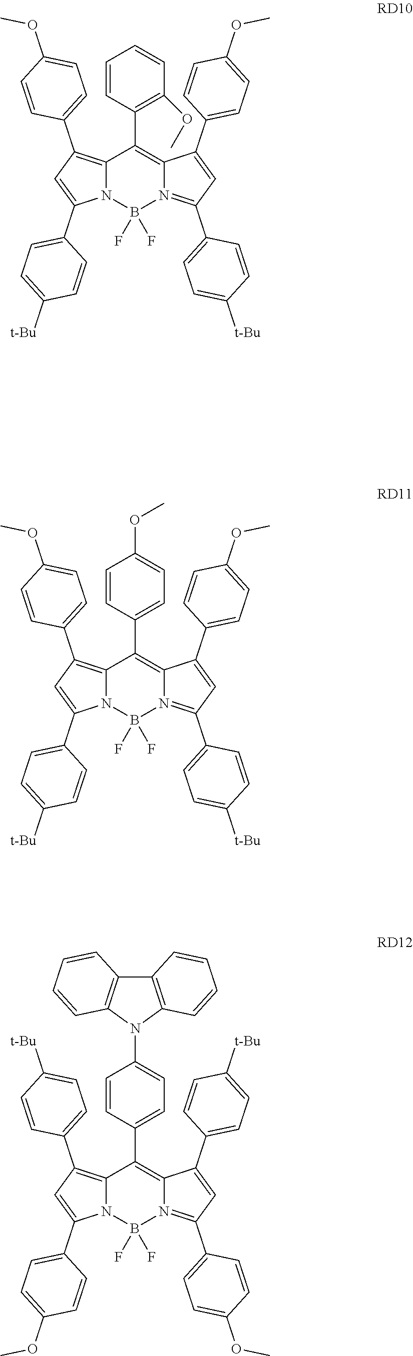

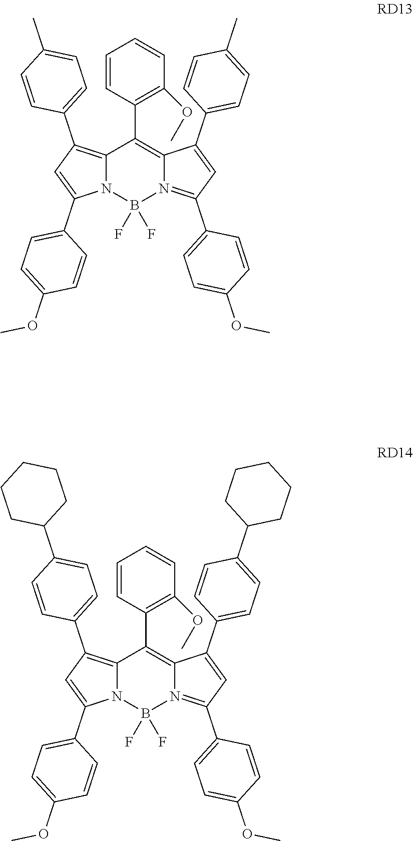

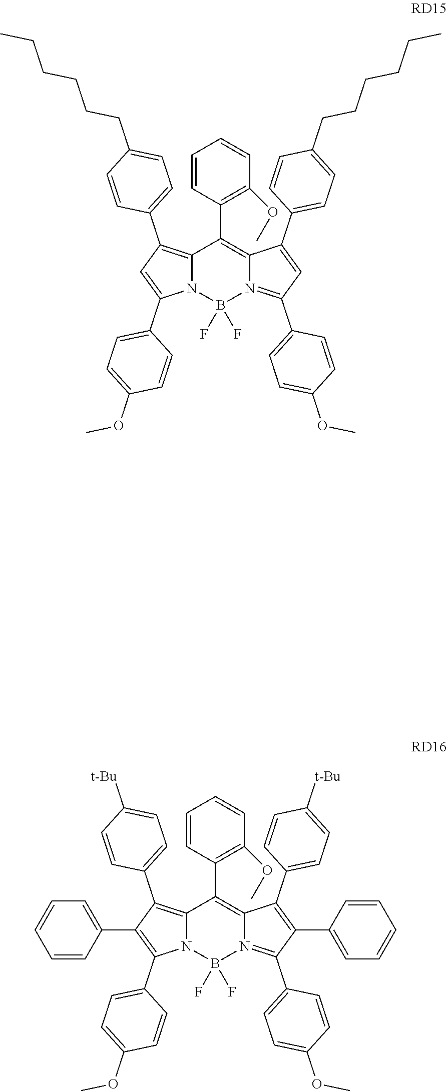

Unless otherwise specifically indicated, the alkyl group, the alkenyl group, the aryl group, the heteroaryl group, the arylene group and the heteroarylene group in this description are as mentioned below.

“Alkyl group” can be linear, branched or cyclic. Two or more of a linear moiety, a cyclic moiety and a branched moiety can be in the group as mixed. The carbon number of the alkyl group can be, for example, 1 or more, 2 or more, or 4 or more. The carbon number can also be 30 or less, 20 or less, 10 or less, 6 or less, or 4 or less. Specific examples of the alkyl group include a methyl group, an ethyl group, an n-propyl group, an isopropyl group, an n-butyl group, an isobutyl group, a tert-butyl group, an n-pentyl group, an isopentyl group, an n-hexyl group, an isohexyl group, a 2-ethylhexyl group, an n-heptyl group, an isoheptyl group, an n-octyl group, an isooctyl group, an n-nonyl group, an isononyl group, an n-decanyl group, an isodecanyl group, a cyclopentyl group, a cyclohexyl group, and a cycloheptyl group. The alkyl group of a substituent can be further substituted with an aryl group. For the alkyl moiety of “alkoxy group”, “alkylthio group”, “acyl group” and “alkoxycarbonyl group”, reference can be made to the description of “alkyl group” herein.

“Alkenyl group” can be linear, branched or cyclic. Two or more of a linear moiety, a cyclic moiety and a branched moiety can be in the group as mixed. The carbon number of the alkyl group can be, for example, 2 or more, or 4 or more. The carbon number can also be 30 or less, 20 or less, 10 or less, 6 or less, or 4 or less. Specific examples of the alkenyl group include an ethenyl group, an n-propenyl group, an isopropenyl group, an n-butenyl group, an isobutenyl group, an n-pentenyl group, an isopentenyl group, an n-hexenyl group, an isohexenyl group, and a 2-ethylhexenyl group. The alkenyl group to be a substituent can be further substituted with a substituent.

“Aryl group” and “Heteroaryl group” each can be a single ring or can be a condensed ring of two or more kinds of rings. In the case of a condensed ring, the number of the rings that are condensed is preferably 2 to 6, and, for example, can be selected from 2 to 4. Specific examples of the ring include a benzene ring, a pyridine ring, a pyrimidine ring, a triazine ring, a naphthalene ring, an anthracene ring, a phenanthrene ring, a triphenylene ring, a quinoline ring, a pyrazine ring, a quinoxaline ring, and a naphthyridine ring. Specific examples of the aryl ring or the heteroaryl ring include a phenyl group, a 1-naphthyl group, a 2-naphthyl group, a 1-anthracenyl group, a 2-anthracenyl group, a 9-anthracenyl group, a 2-pyridyl group, a 3-pyridyl group, and a 4-pyridyl group. For “arylene group” and “heteroarylene group”, the valence of the aryl group and the heteroaryl group is exchanged from 1 to 2, and the thus-exchanged description can be referred to. For the aryl moiety of “aryloxy group”, “arylthio group” and “aryloxycarbonyl group”, reference can be made to the description of “aryl group” herein. For the heteroaryl moiety of “heteroaryloxy group” “heteroarylthio group” and “heteroaryloxycarbonyl group”, reference can be made to the description of “heteroaryl group” herein.

### (Light Emitting Layer)

The light emitting layer in the organic electroluminescent device of the present invention is formed of a light emitting composition containing the first organic compound, the second organic compound of a delayed fluorescent material and the third organic compound satisfying the formula (a) and the formula (b). In a preferred embodiment of the present invention, the light emitting layer does not contain a compound and a metal element for transmitting and receiving charge or energy, in addition to the first organic compound, the second organic compound and the third organic compound. The light emitting layer can be composed of the first organic compound, the second organic compound and the third organic compound alone. The light emitting layer can be composed of a compound alone that consists of atoms selected from the group consisting of a carbon atom, a hydrogen atom, a nitrogen atom, a boron atom, an oxygen atom, a sulfur atom, and a fluorine atom. For example, the light emitting layer can be composed of a compound alone that consists of atoms selected from the group consisting of a carbon atom, a hydrogen atom, a nitrogen atom, a boron atom, an oxygen atom, and a fluorine atom. In a preferred embodiment of the present invention, the light emitting layer contains a carbon atom, a hydrogen atom, a nitrogen atom, a boron atom, an oxygen atom and a fluorine atom, and further preferably does not contain any other atom than these.

The light emitting layer can be formed in a wet process or in a dry process using a light emitting composition containing the first organic compound, the second organic compound of a delayed fluorescent material and the third organic compound satisfying the formula (a) and the formula (b).

In a wet process, a solution prepared by dissolving the light emitting composition is applied onto a surface, and the solvent used is removed to form a light emitting layer. The wet process includes a spin coating method, a slit coating method, an inkjet method (spray method), a gravure printing method, an offset printing method, and a flexographic printing method, but is not limited to these. In the wet process, a suitable organic solvent capable of dissolving the light emitting composition is selected and used. In some embodiments, a substituent (for example, an alkyl group) capable of increasing the solubility in an organic solvent can be introduced into the compound contained in the light emitting composition.

As a dry process, a vacuum evaporation method is preferably employed. In the case where a vacuum evaporation method is employed, the compounds constituting the light emitting layer can be co-evaporated from individual evaporation sources, or can be co-evaporated from a single evaporation source prepared by mixing all the compounds. In the case where a single evaporation source is used, a mixed powder prepared by mixing powders of all the compounds can be used, or a compressed-molded article prepared by compression-molding the mixed powder can be used, or a mixture prepared by heating, meting and mixing the compounds and then cooling the resultant mixture can be used. In some embodiments, plural compounds contained in a single evaporation source is co-evaporated under the condition that the evaporation speed (weight reducing speed) is the same or is nearly the same between the plural compounds to thereby form a light emitting layer having a compositional ratio corresponding to the compositional ratio of the plural compounds contained in the evaporation source. When plural compounds are mixed to prepare an evaporation source in the same compositional ratio as the compositional ratio of the light emitting layer to be formed, a light emitting layer having a desired compositional ratio can be formed in a simple manner. In some embodiments, a temperature at which the compounds to be co-evaporated could have the same weight reduction rate is specifically defined, and the temperature can be employed as the temperature for co-evaporation. In the case where a light emitting layer is formed in an evaporation method, the molecular weight of the first organic compound, the second organic compound and the third organic compound each is preferably 1500 or less, more preferably 1200 or less, even more preferably 1000 or less, further more preferably 900 or less. The lower limit of the molecular weight can be, for example, 200, can be 400, or can be 600.

### (Layer Configuration of Organic Electroluminescent Device)

By forming a light emitting layer of the light emitting composition containing the first organic compound, the second organic compound of a delayed fluorescent material and the third organic compound satisfying the formula (a) and the formula (b), there can be provided an excellent organic light emitting device such as an organic photoluminescent device (organic PL device) and an organic electroluminescent device (organic EL device).

The thickness of the light emitting layer can be 1 to 15 nm, or can be 2 to 10 nm or can be 3 to 7 nm.

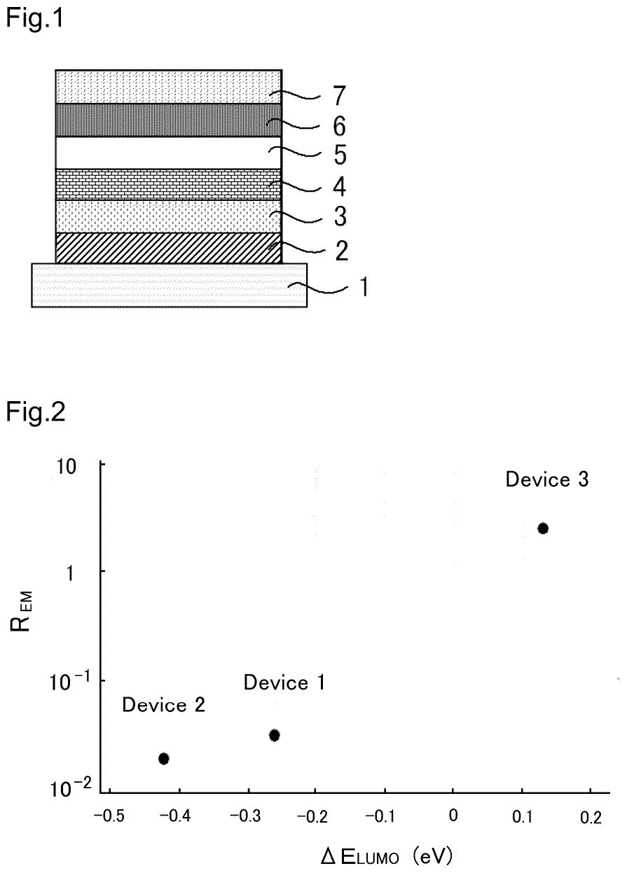

The organic photoluminescent device is so configured as to have at least a light emitting layer formed on a substrate. The organic electroluminescent device is so configured as to have at least an anode, a cathode and an organic layer formed between the anode and the cathode. The organic layer contains at least a light emitting layer, and can be composed of a light emitting layer, or can have at least one other organic layer in addition to the light emitting layer. Such other organic layers include hole transporting layer, a hole injection layer, an electron barrier layer, a hole barrier layer, an electron injection layer, an electron transporting layer and an exciton barrier layer. The hole transporting layer can also be a hole injection and transporting layer having a hole injection function, and the electron transporting layer can also be an electron injection transporting layer having an electron injection function. A specific configuration example of an organic electroluminescent device is shown in FIG. 1. In FIG. 1, 1 is a substrate, 2 is an anode, 3 is a hole injection layer, 4 is a hole transporting layer, 5 is a light emitting layer, 6 is an electron transporting layer, and 7 is a cathode.

In the case where the organic light emitting device of the invention is a multi-wavelength emission-type organic light emitting device, the device can be so designed that shortest wavelength emission contains delayed fluorescence. The device can be so designed that shortest wavelength emission does not contain delayed fluorescence.

The organic electroluminescent device formed of a light emitting composition, which contains the first organic compound, the second organic compound of a delayed fluorescent material and the third organic compound satisfying the formula (a) and the formula (b), is, when excited by a thermal or electronic means, able to emit light in a UV region, or light of blue, green, yellow, orange or red in a visible region (e.g., 420 to 500 nm, 500 to 600 nm or 600 to 700 nm) or light in a near IR region. For example, the organic electroluminescent device can emit light in a red or orange region (e.g., 620 to 780 nm). For example, the organic electroluminescent device can emit light in an orange or yellow region (e.g., 570 to 620 nm). For example, the organic electroluminescent device can emit light in a green region (e.g., 490 to 575 nm). For example, the organic electroluminescent device can emit light in a blue region (e.g., 400 to 490 nm). For example, the organic electroluminescent device can emit light in a UV spectral region (e.g., 280 to 400 nm). For example, the organic electroluminescent device can emit light in an IR spectral region (e.g., 780 nm to 2 um). In a preferred embodiment of the present invention, the maximum emission wavelength of the device is longer than 570 nm (for example, 570 to 780 nm).

In the following, the constituent members and the other layers than the light-emitting layer of the organic electroluminescent device are described.

### Substrate:

In some embodiments, the organic electroluminescent device of the invention is supported by a substrate, wherein the substrate is not particularly limited and may be any of those that have been commonly used in an organic electroluminescent device, for example those formed of glass, transparent plastics, quartz and silicon.

### Anode

In some embodiments, the anode of the organic electroluminescent device is made of a metal, an alloy, an electroconductive compound, or a combination thereof. In some embodiments, the metal, alloy, or electroconductive compound has a large work function (4 eV or more). In some embodiments, the metal is Au. In some embodiments, the electroconductive transparent material is selected from CuI, indium tin oxide (ITO), SnO₂, and ZnO. In some embodiments, an amorphous material capable of forming a transparent electroconductive film, such as IDIXO (In₂O₃—ZnO), is be used. In some embodiments, the anode is a thin film. In some embodiments the thin film is made by vapor deposition or sputtering. In some embodiments, the film is patterned by a photolithography method. In some embodiments, where the pattern may not require high accuracy (for example, approximately 100 μm or more), the pattern may be formed with a mask having a desired shape on vapor deposition or sputtering of the electrode material. In some embodiments, when a material can be applied as a coating, such as an organic electroconductive compound, a wet film forming method, such as a printing method and a coating method is used. In some embodiments, when the emitted light goes through the anode, the anode has a transmittance of more than 10%, and the anode has a sheet resistance of several hundred Ohm per square or less. In some embodiments, the thickness of the anode is from 10 to 1,000 nm. In some embodiments, the thickness of the anode is from 10 to 200 nm. In some embodiments, the thickness of the anode varies depending on the material used.

### Cathode

In some embodiments, the cathode is made of an electrode material a metal having a small work function (4 eV or less) (referred to as an electron injection metal), an alloy, an electroconductive compound, or a combination thereof In some embodiments, the electrode material is selected from sodium, a sodium-potassium alloy, magnesium, lithium, a magnesium-cupper mixture, a magnesium-silver mixture, a magnesium-aluminum mixture, a magnesium-indium mixture, an aluminum-aluminum oxide (Al₂O₃) mixture, indium, a lithium-aluminum mixture, and a rare earth metal. In some embodiments, a mixture of an electron injection metal and a second metal that is a stable metal having a larger work function than the electron injection metal is used. In some embodiments, the mixture is selected from a magnesium-silver mixture, a magnesium-aluminum mixture, a magnesium-indium mixture, an aluminum-aluminum oxide (Al₂O₃) mixture, a lithium-aluminum mixture, and aluminum. In some embodiments, the mixture increases the electron injection property and the durability against oxidation. In some embodiments, the cathode is produced by forming the electrode material into a thin film by vapor deposition or sputtering. In some embodiments, the cathode has a sheet resistance of several hundred Ohm per square or less. In some embodiments, the thickness of the cathode ranges from 10 nm to 5μm. In some embodiments, the thickness of the cathode ranges from 50 to 200 nm. In some embodiments, for transmitting the emitted light, any one of the anode and the cathode of the organic electroluminescent device is transparent or translucent. In some embodiments, the transparent or translucent electroluminescent devices enhances the light emission luminance.

In some embodiments, the cathode is formed with an electroconductive transparent material, as described for the anode, to form a transparent or translucent cathode. In some embodiments, a device comprises an anode and a cathode, both being transparent or translucent.

### Injection Layer

An injection layer is a layer between the electrode and the organic layer. In some embodiments, the injection layer decreases the driving voltage and enhances the light emission luminance. In some embodiments the injection layer includes a hole injection layer and an electron injection layer. The injection layer can be positioned between the anode and the light-emitting layer or the hole transporting layer, and between the cathode and the light-emitting layer or the electron transporting layer. In some embodiments, an injection layer is present. In some embodiments, no injection layer is present.

Preferred compound examples for use as a hole injection material are shown below. MoO₃,

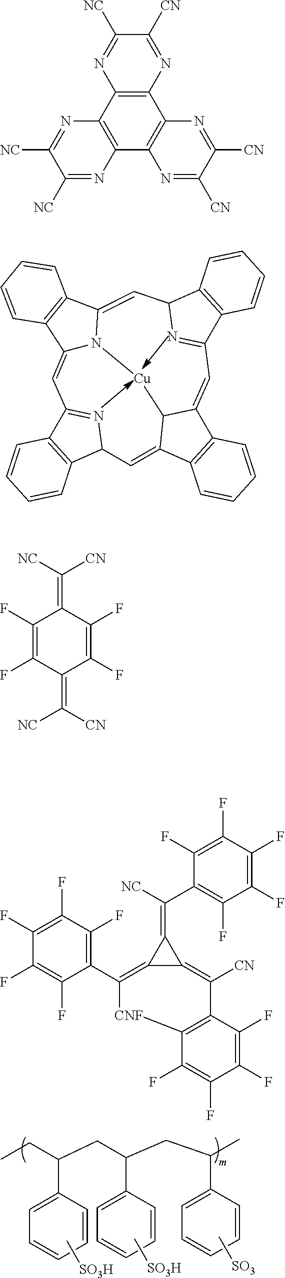

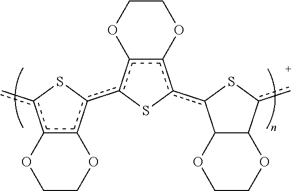

Next, preferred compound examples for use as an electron injection material are shown below.

LiF, CsF,

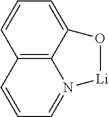

### Barrier Layer

A barrier layer is a layer capable of inhibiting charges (electrons or holes) and/or excitons present in the light-emitting layer from being diffused outside the light-emitting layer. In some embodiments, the electron barrier layer is between the light-emitting layer and the hole transporting layer, and inhibits electrons from passing through the light-emitting layer toward the hole transporting layer. In some embodiments, the hole barrier layer is between the light-emitting layer and the electron transporting layer, and inhibits holes from passing through the light-emitting layer toward the electron transporting layer. In some embodiments, the barrier layer inhibits excitons from being diffused outside the light-emitting layer. In some embodiments, the electron barrier layer and the hole barrier layer are exciton barrier layers. As used herein, the term “electron barrier layer” or “exciton barrier layer” includes a layer that has the functions of both electron barrier layer and of an exciton barrier layer.

### Hole Barrier Layer

A hole barrier layer acts as an electron transporting layer. In some embodiments, the hole barrier layer inhibits holes from reaching the electron transporting layer while transporting electrons. In some embodiments, the hole barrier layer enhances the recombination probability of electrons and holes in the light-emitting layer. The material for the hole barrier layer may be the same materials as the ones described for the electron transporting layer.

Preferred compound examples for use for the hole barrier layer are shown below.

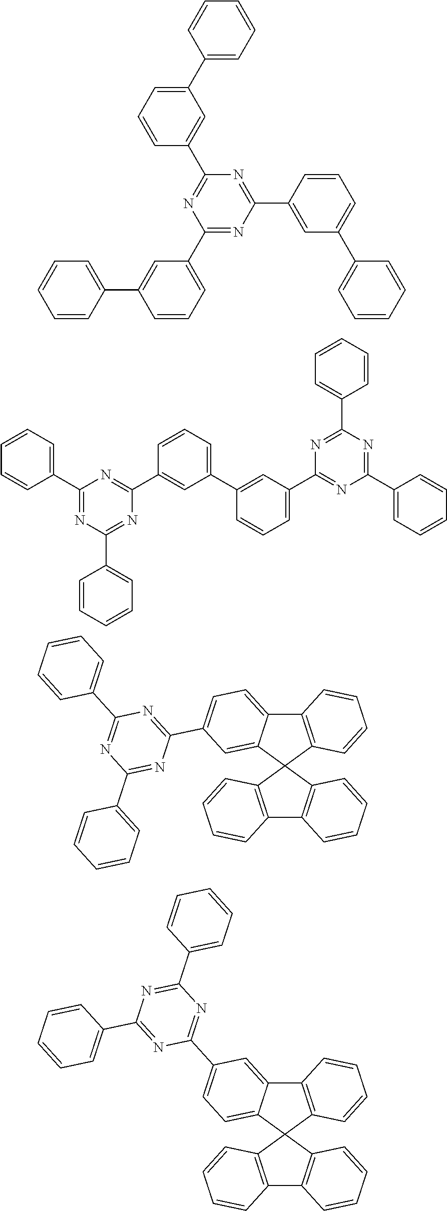

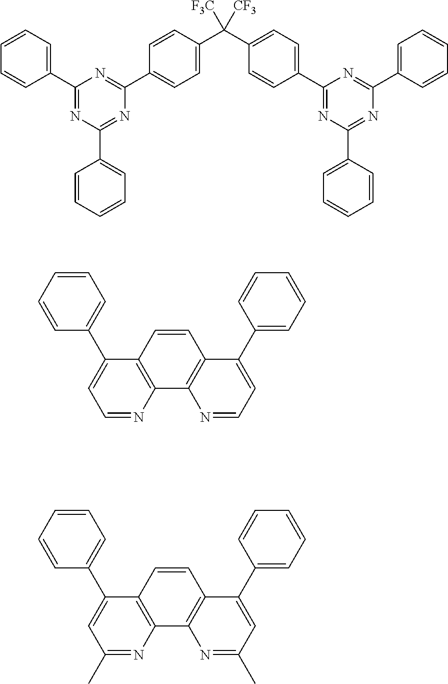 [SMILES: FC(F)(F)C(c1ccc(-c2nc(-c3ccccc3)nc(-c3ccccc3)n2)cc1)(c1ccc(-c2nc(-c3ccccc3)nc(-c3ccccc3)n2)cc1)C(F)(F)F ; c1ccc(-c2ccnc3c2ccc2c(-c4ccccc4)ccnc23)cc1 ; Cc1cc(-c2ccccc2)c2ccc3c(-c4ccccc4)cc(C)nc3c2n1]

### Electron Barrier Layer

As electron barrier layer transports holes. In some embodiments, the electron barrier layer inhibits electrons from reaching the hole transporting layer while transporting holes. In some embodiments, the electron barrier layer enhances the recombination probability of electrons and holes in the light-emitting layer.

Preferred compound examples for use as the electron barrier material are shown below.

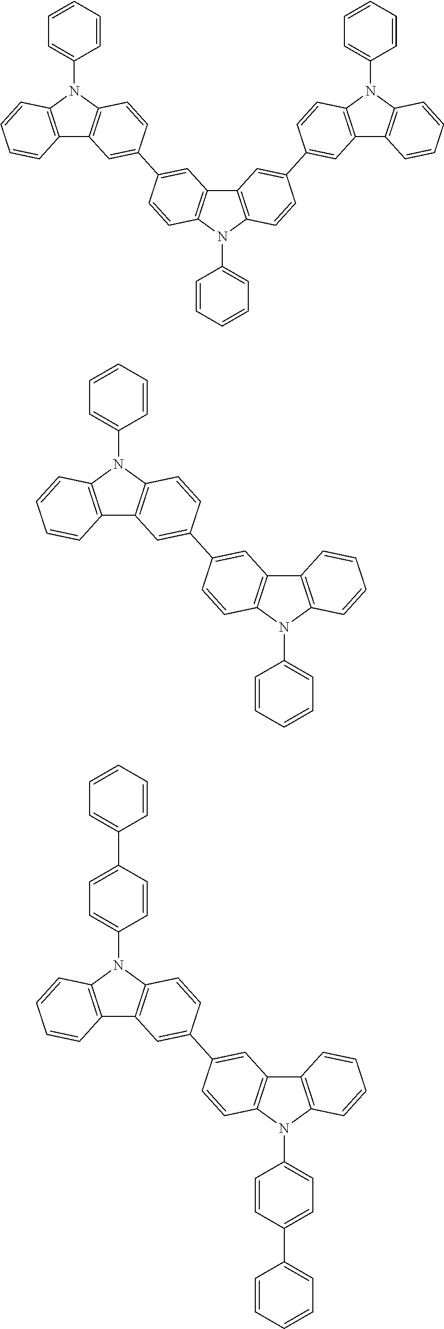 [SMILES: c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1 ; c1ccc(-n2c3ccccc3c3cc(-c4ccc5c(c4)c4ccccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

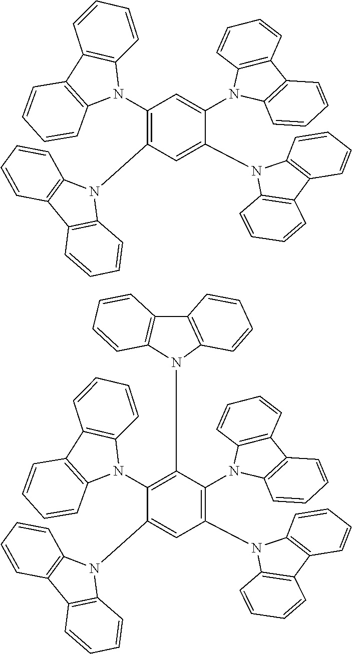

### Exciton Barrier Layer

An exciton barrier layer inhibits excitons generated through recombination of holes and electrons in the light-emitting layer from being diffused to the charge transporting layer. In some embodiments, the exciton barrier layer enables effective confinement of excitons in the light-emitting layer. In some embodiments, the light emission efficiency of the device is enhanced. In some embodiments, the exciton barrier layer is adjacent to the light-emitting layer on any of the side of the anode and the side of the cathode, and on both the sides. In some embodiments, where the exciton barrier layer is on the side of the anode, the layer can be between the hole transporting layer and the light-emitting layer and adjacent to the light-emitting layer. In some embodiments, where the exciton barrier layer is on the side of the cathode, the layer can be between the light-emitting layer and the cathode and adjacent to the light-emitting layer. In some embodiments, a hole injection layer, an electron barrier layer, or a similar layer is between the anode and the exciton barrier layer that is adjacent to the light-emitting layer on the side of the anode. In some embodiments, a hole injection layer, an electron barrier layer, a hole barrier layer, or a similar layer is between the cathode and the exciton barrier layer that is adjacent to the light-emitting layer on the side of the cathode. In some embodiments, the exciton barrier layer comprises excited singlet energy and excited triplet energy, at least one of which is higher than the excited singlet energy and the excited triplet energy of the light-emitting material, respectively.

### Hole Transporting Layer

The hole transporting layer comprises a hole transporting material. In some embodiments, the hole transporting layer is a single layer. In some embodiments, the hole transporting layer comprises a plurality layers.

In some embodiments, the hole transporting material has one of injection or transporting property of holes and barrier property of electrons. In some embodiments, the hole transporting material is an organic material. In some embodiments, the hole transporting material is an inorganic material. Examples of known hole transporting materials that may be used herein include but are not limited to a triazole derivative, an oxadiazole derivative, an imidazole derivative, a carbazole derivative, an indolocarbazole derivative, a polyarylalkane derivative, a pyrazoline derivative, a pyrazolone derivative, a phenylenediamine derivative, an arylamine derivative, an amino-substituted chalcone derivative, an oxazole derivative, a styrylanthracene derivative, a fluorenone derivative, a hydrazone derivative, a stilbene derivative, a silazane derivative, an aniline copolymer and an electroconductive polymer oligomer, particularly a thiophene oligomer, or a combination thereof In some embodiments, the hole transporting material is selected from a porphyrin compound, an aromatic tertiary amine compound, and a styrylamine compound. In some embodiments, the hole transporting material is an aromatic tertiary amine compound. Preferred compound examples for use as the hole transporting material are shown below.

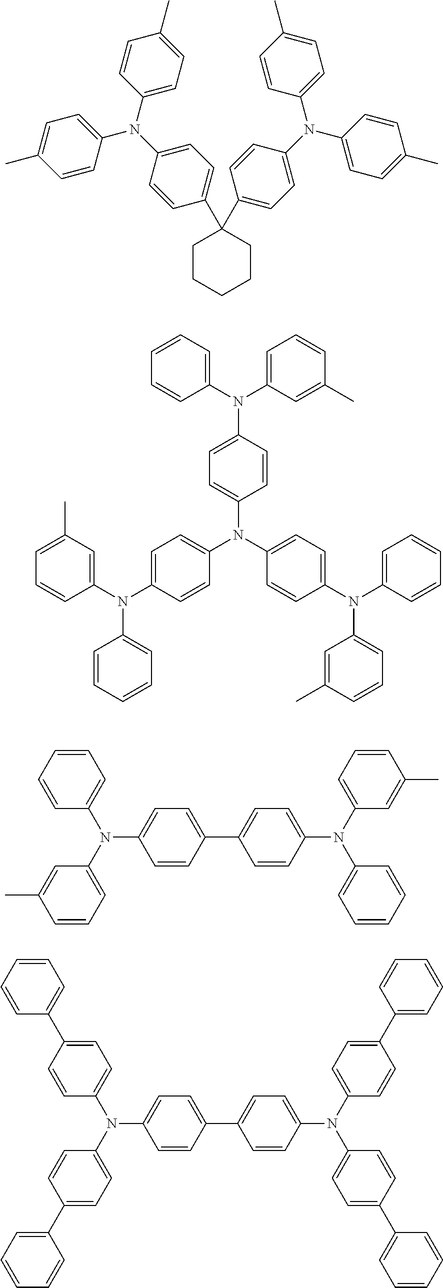

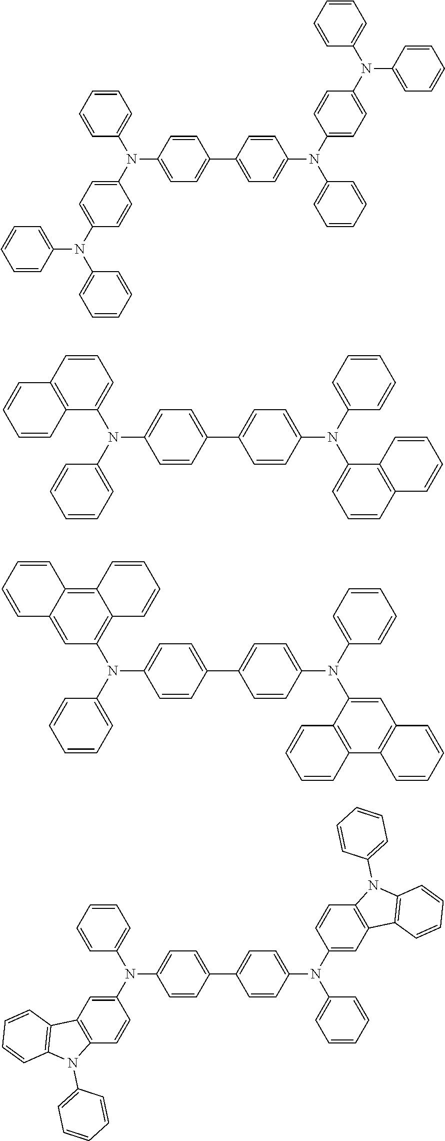

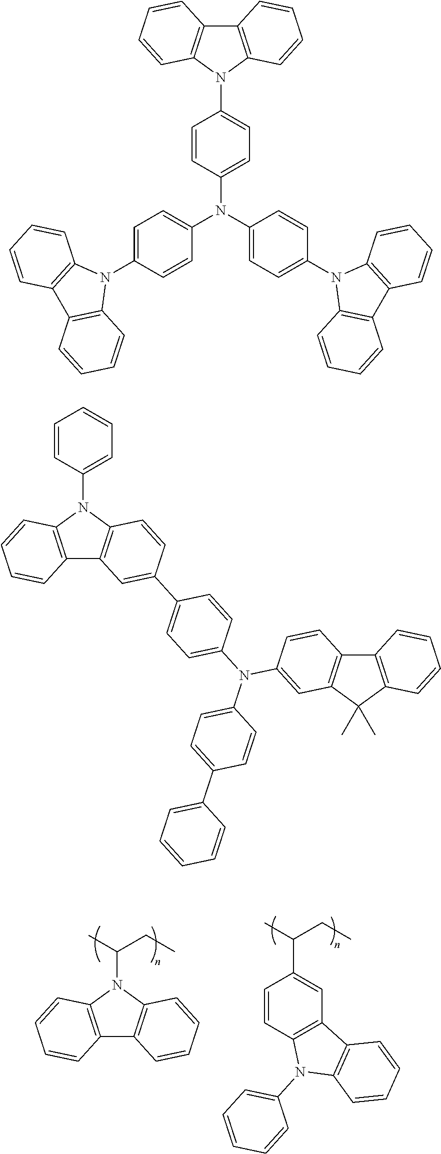

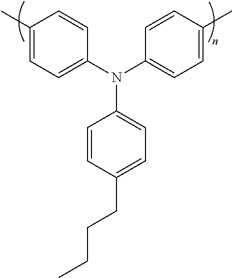

### Electron Transporting Layer

The electron transporting layer comprises an electron transporting material. In some embodiments, the electron transporting layer is a single layer. In some embodiments, the electron transporting layer comprises a plurality of layer.

In some embodiments, the electron transporting material needs only to have a function of transporting electrons, which are injected from the cathode, to the light-emitting layer. In some embodiments, the electron transporting material also function as a hole barrier material. Examples of the electron transporting layer that may be used herein include but are not limited to a nitro-substituted fluorene derivative, a diphenylquinone derivative, a thiopyran dioxide derivative, carbodiimide, a fluorenylidene methane derivative, anthraquinodimethane, an anthrone derivatives, an azole derivative, an azine derivative, an oxadiazole derivative, or a combination thereof, or a polymer thereof In some embodiments, the electron transporting material is a thiadiazole derivative, or a quinoxaline derivative. In some embodiments, the electron transporting material is a polymer material. Preferred compound examples for use as the electron transporting material are shown below.

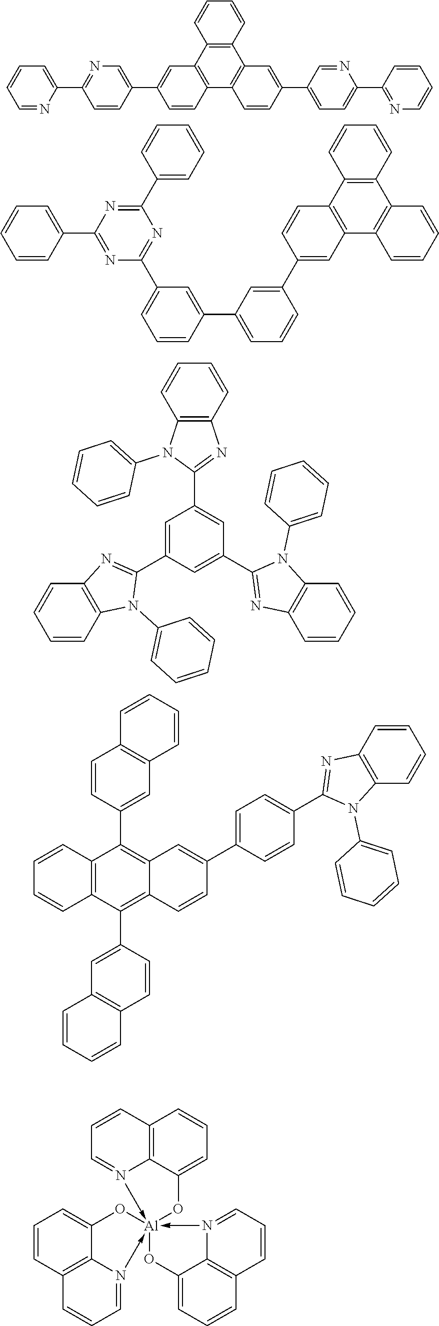

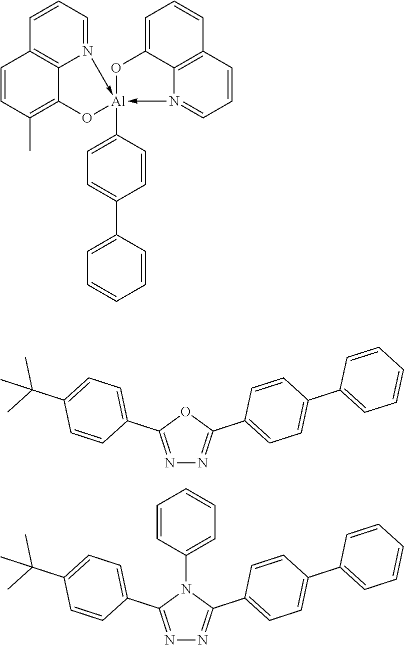

Hereinunder compound examples preferred as a material that can be added to the organic layers are shown. For example, these can be added as a stabilization material.

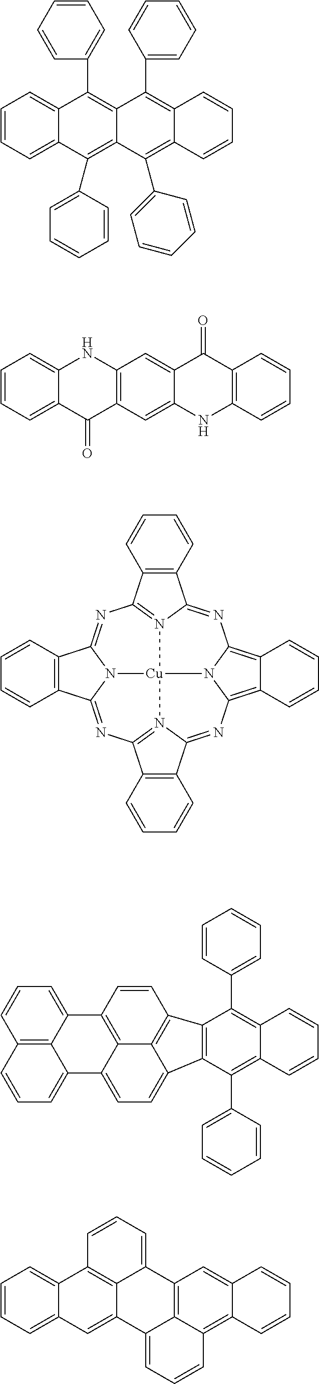

Preferred materials for use in the organic electroluminescent device are specifically shown. However, the materials usable in the invention should not be limitatively interpreted by the following exemplary compounds. Compounds that are exemplified as materials having a specific function can also be used as materials having any other function.

### Devices

In some embodiments, a light emitting layer is incorporated into a device. For example, the device includes, but is not limited to an OLED bulb, an OLED lamp, a television screen, a computer monitor, a mobile phone, and a tablet.

In some embodiments, an electronic device comprises an OLED comprising an anode, a cathode, and at least one organic layer comprising a light emitting layer between the anode and the cathode.

In some embodiments, compositions described herein may be incorporated into various light-sensitive or light-activated devices, such as a OLEDs or photovoltaic devices. In some embodiments, the composition may be useful in facilitating charge transfer or energy transfer within a device and/or as a hole-transport material. The device may be, for example, an organic light-emitting diode (OLED), an organic integrated circuit (O-IC), an organic field-effect transistor (O-FET), an organic thin-film transistor (O-TFT), an organic light-emitting transistor (O-LET), an organic solar cell (O-SC), an organic optical detector, an organic photoreceptor, an organic field-quench device (O-FQD), a light-emitting electrochemical cell (LEC) or an organic laser diode (O-laser).

### Bulbs or Lamps

In some embodiments, an electronic device comprises an OLED comprising an anode, a cathode, and at least one organic layer comprising a light emitting layer between the anode and the cathode.

In some embodiments, a device comprises OLEDs that differ in color. In some embodiments, a device comprises an array comprising a combination of OLEDs. In some embodiments, the combination of OLEDs is a combination of three colors (e.g., RGB). In some embodiments, the combination of OLEDs is a combination of colors that are not red, green, or blue (for example, orange and yellow green). In some embodiments, the combination of OLEDs is a combination of two, four, or more colors.

In some embodiments, a device is an OLED light comprising:
a circuit board having a first side with a mounting surface and an opposing second side, and defining at least one aperture;
at least one OLED on the mounting surface, the at least one OLED configured to emanate light, comprising:
   an anode, a cathode, and at least one organic layer comprising a light emitting layer between the anode and the cathode;
a housing for the circuit board; and
at least one connector arranged at an end of the housing, the housing and the connector defining a package adapted for installation in a light fixture.

In some embodiments, the OLED light comprises a plurality of OLEDs mounted on a circuit board such that light emanates in a plurality of directions. In some embodiments, a portion of the light emanated in a first direction is deflected to emanate in a second direction. In some embodiments, a reflector is used to deflect the light emanated in a first direction.

### Displays or Screens

In some embodiments, the compounds of the invention can be used in a screen or a display. In some embodiments, the compounds of the invention are deposited onto a substrate using a process including, but not limited to, vacuum evaporation, deposition, vapor deposition, or chemical vapor deposition (CVD). In some embodiments, the substrate is a photoplate structure useful in a two-sided etch provides a unique aspect ratio pixel. The screen (which may also be referred to as a mask) is used in a process in the manufacturing of OLED displays. The corresponding artwork pattern design facilitates a very steep and narrow tie-bar between the pixels in the vertical direction and a large, sweeping bevel opening in the horizontal direction. This allows the close patterning of pixels needed for high definition displays while optimizing the chemical deposition onto a TFT backplane.

The internal patterning of the pixel allows the construction of a 3-dimensional pixel opening with varying aspect ratios in the horizontal and vertical directions. Additionally, the use of imaged “stripes” or halftone circles within the pixel area inhibits etching in specific areas until these specific patterns are undercut and fall off the substrate. At that point the entire pixel area is subjected to a similar etch rate but the depths are varying depending on the halftone pattern. Varying the size and spacing of the halftone pattern allows etching to be inhibited at different rates within the pixel allowing for a localized deeper etch needed to create steep vertical bevels.

A preferred material for the deposition mask is invar. Invar is a metal alloy that is cold rolled into long thin sheet in a steel mill. Invar cannot be electrodeposited onto a rotating mandrel as the nickel mask. A preferred and more cost feasible method for forming the open areas in the mask used for deposition is through a wet chemical etching.

In some embodiments, a screen or display pattern is a pixel matrix on a substrate. In some embodiments, a screen or display pattern is fabricated using lithography (e.g., photolithography and e-beam lithography). In some embodiments, a screen or display pattern is fabricated using a wet chemical etch. In further embodiments, a screen or display pattern is fabricated using plasma etching.

### Methods of Manufacturing Devices

An OLED display is generally manufactured by forming a large mother panel and then cutting the mother panel in units of cell panels. In general, each of the cell panels on the mother panel is formed by forming a thin film transistor (TFT) including an active layer and a source/drain electrode on a base substrate, applying a planarization film to the TFT, and sequentially forming a pixel electrode, a light-emitting layer, a counter electrode, and an encapsulation layer, and then is cut from the mother panel.

An OLED display is generally manufactured by forming a large mother panel and then cutting the mother panel in units of cell panels. In general, each of the cell panels on the mother panel is formed by forming a thin film transistor (TFT) including an active layer and a source/drain electrode on a base substrate, applying a planarization film to the TFT, and sequentially forming a pixel electrode, a light-emitting layer, a counter electrode, and an encapsulation layer, and then is cut from the mother panel.

In another aspect, provided herein is a method of manufacturing an organic light-emitting diode (OLED) display, the method comprising:
forming a barrier layer on a base substrate of a mother panel;
forming a plurality of display units in units of cell panels on the barrier layer;
forming an encapsulation layer on each of the display units of the cell panels;
applying an organic film to an interface portion between the cell panels.

In some embodiments, the barrier layer is an inorganic film formed of, for example, SiNx, and an edge portion of the barrier layer is covered with an organic film formed of polyimide or acryl. In some embodiments, the organic film helps the mother panel to be softly cut in units of the cell panel.

In some embodiments, the thin film transistor (TFT) layer includes a light-emitting layer, a gate electrode, and a source/drain electrode. Each of the plurality of display units may include a thin film transistor (TFT) layer, a planarization film formed on the TFT layer, and a light-emitting unit formed on the planarization film, wherein the organic film applied to the interface portion is formed of a same material as a material of the planarization film and is formed at a same time as the planarization film is formed. In some embodiments, a light-emitting unit is connected to the TFT layer with a passivation layer and a planarization film therebetween and an encapsulation layer that covers and protects the light-emitting unit. In some embodiments of the method of manufacturing, the organic film contacts neither the display units nor the encapsulation layer.

Each of the organic film and the planarization film may include any one of polyimide and acryl. In some embodiments, the bather layer may be an inorganic film. In some embodiments, the base substrate may be formed of polyimide. The method may further include, before the forming of the barrier layer on one surface of the base substrate formed of polyimide, attaching a carrier substrate formed of a glass material to another surface of the base substrate, and before the cutting along the interface portion, separating the carrier substrate from the base substrate. In some embodiments, the OLED display is a flexible display.

In some embodiments, the passivation layer is an organic film disposed on the TFT layer to cover the TFT layer. In some embodiments, the planarization film is an organic film formed on the passivation layer. In some embodiments, the planarization film is formed of polyimide or acryl, like the organic film formed on the edge portion of the barrier layer. In some embodiments, the planarization film and the organic film are simultaneously formed when the OLED display is manufactured. In some embodiments, the organic film may be formed on the edge portion of the barrier layer such that a portion of the organic film directly contacts the base substrate and a remaining portion of the organic film contacts the barrier layer while surrounding the edge portion of the barrier layer.

In some embodiments, the light-emitting layer includes a pixel electrode, a counter electrode, and an organic light-emitting layer disposed between the pixel electrode and the counter electrode. In some embodiments, the pixel electrode is connected to the source/drain electrode of the TFT layer.

In some embodiments, when a voltage is applied to the pixel electrode through the TFT layer, an appropriate voltage is formed between the pixel electrode and the counter electrode, and thus the organic light-emitting layer emits light, thereby forming an image. Hereinafter, an image forming unit including the TFT layer and the light-emitting unit is referred to as a display unit.

In some embodiments, the encapsulation layer that covers the display unit and prevents penetration of external moisture may be formed to have a thin film encapsulation structure in which an organic film and an inorganic film are alternately stacked. In some embodiments, the encapsulation layer has a thin film encapsulation structure in which a plurality of thin films are stacked. In some embodiments, the organic film applied to the interface portion is spaced apart from each of the plurality of display units. In some embodiments, the organic film is formed such that a portion of the organic film directly contacts the base substrate and a remaining portion of the organic film contacts the barrier layer while surrounding an edge portion of the barrier layer.

In one embodiment, the OLED display is flexible and uses the soft base substrate formed of polyimide. In some embodiments, the base substrate is formed on a carrier substrate formed of a glass material, and then the carrier substrate is separated.

In some embodiments, the barrier layer is formed on a surface of the base substrate opposite to the carrier substrate. In one embodiment, the barrier layer is patterned according to a size of each of the cell panels. For example, while the base substrate is formed over the entire surface of a mother panel, the barrier layer is formed according to a size of each of the cell panels, and thus a groove is formed at an interface portion between the barrier layers of the cell panels. Each of the cell panels can be cut along the groove.

In some embodiments, the method of manufacture further comprises cutting along the interface portion, wherein a groove is formed in the barrier layer, wherein at least a portion of the organic film is formed in the groove, and wherein the groove does not penetrate into the base substrate. In some embodiments, the TFT layer of each of the cell panels is formed, and the passivation layer which is an inorganic film and the planarization film which is an organic film are disposed on the TFT layer to cover the TFT layer. At the same time as the planarization film formed of, for example, polyimide or acryl is formed, the groove at the interface portion is covered with the organic film formed of, for example, polyimide or acryl. This is to prevent cracks from occurring by allowing the organic film to absorb an impact generated when each of the cell panels is cut along the groove at the interface portion. That is, if the entire barrier layer is entirely exposed without the organic film, an impact generated when each of the cell panels is cut along the groove at the interface portion is transferred to the barrier layer, thereby increasing the risk of cracks. However, in one embodiment, since the groove at the interface portion between the barrier layers is covered with the organic film and the organic film absorbs an impact that would otherwise be transferred to the barrier layer, each of the cell panels may be softly cut and cracks may be prevented from occurring in the barrier layer. In one embodiment, the organic film covering the groove at the interface portion and the planarization film are spaced apart from each other. For example, if the organic film and the planarization film are connected to each other as one layer, since external moisture may penetrate into the display unit through the planarization film and a portion where the organic film remains, the organic film and the planarization film are spaced apart from each other such that the organic film is spaced apart from the display unit.

In some embodiments, the display unit is formed by forming the light-emitting unit, and the encapsulation layer is disposed on the display unit to cover the display unit. As such, once the mother panel is completely manufactured, the carrier substrate that supports the base substrate is separated from the base substrate. In some embodiments, when a laser beam is emitted toward the carrier substrate, the carrier substrate is separated from the base substrate due to a difference in a thermal expansion coefficient between the carrier substrate and the base substrate.

In some embodiments, the mother panel is cut in units of the cell panels. In some embodiments, the mother panel is cut along an interface portion between the cell panels by using a cutter. In some embodiments, since the groove at the interface portion along which the mother panel is cut is covered with the organic film, the organic film absorbs an impact during the cutting. In some embodiments, cracks may be prevented from occurring in the barrier layer during the cutting.

In some embodiments, the methods reduce a defect rate of a product and stabilize its quality.

Another aspect is an OLED display including: a barrier layer that is formed on a base substrate; a display unit that is formed on the barrier layer; an encapsulation layer that is formed on the display unit; and an organic film that is applied to an edge portion of the barrier layer.

### (Method for Designing Light Emitting Composition)

The present invention also proposes a method for designing the light emitting composition that can be used in the light emitting layer of an organic light emitting device. By using the design method of the present invention, the light emitting composition used in the light emitting layer of a light emitting device that has a long emission lifetime and is excellent in stability can be easily designed.

The design method for the light emitting composition of the present invention includes the following steps 1 to 3.

[Step 1] evaluating at least one of a light emission efficiency and a drive voltage of a composition containing a first organic compound, a second organic compound of a delayed fluorescent material and a third organic compound, and satisfying the formula (a) and the formula (b),

[Step 2] carrying out at least once evaluating at least one of a light emission efficiency and a drive voltage of a composition in which at least one of the first organic compound, the second organic compound of a delayed fluorescent material and the third organic compound has been replaced within a range satisfying the formula (a) and the formula (b),

[Step 3] selecting a best combination of the results of the evaluated emission efficiency and drive voltage.

Evaluation of the emission efficiency and the drive voltage can be carried out by actually emitting a light emitting composition, or can be carried out by calculation. In addition, evaluation can also be carried out by actually emitting a light emitting composition combined with a calculation method. Preferably, evaluation is carried out from a comprehensive viewpoint using a level of practicality as an index. In the design method for the light emitting composition of the present invention, it is necessary to select and replace the first organic compound, the second organic compound, and the third organic compound within a range satisfying the formula (a) and the formula t (b). Also, it is necessary to select and replace the second organic compound from a delayed fluorescent material. For the compound replacement in the step 2, preferably, the compound is replaced to another one capable of attaining a more excellent evaluation. The step 2 can be carried out, for example, 10 times or more, 100 times or more, 1000 times or more, or 10000 times or more. In the present invention, only the light emission efficiency may be evaluated, or only the drive voltage may be evaluated, but preferably both are evaluated. The light emitting composition designed by the design method of the present invention can be used as the light emitting layer of an organic light emitting device (especially the organic electroluminescent device of the present invention).

The design method for the light emitting composition of the present invention can be stored as a program and can be used as such. The program can be stored on a recording medium and can be transmitted and received by an electronic means.

### EXAMPLES

The features of the present invention will be described more specifically with reference to Experimental Examples and Examples given below. The materials, processes, procedures and the like shown below may be appropriately modified unless they deviate from the substance of the invention. Accordingly, the scope of the invention is not construed as being limited to the specific examples shown below. Hereinunder the light emission characteristics were evaluated using a source meter (available from Keithley Instruments Corporation: 2400 series), a semiconductor parameter analyzer (available from Agilent Corporation, E5273A), an optical power meter device (available from Newport Corporation, 1930C), an optical spectroscope (available from Ocean Optics Corporation, USB2000), a spectroradiometer (available from Topcon Corporation, SR-3), and a streak camera (available from Hamamatsu Photonics K.K., Model C4334).

### (Experimental Example) Measurement of Electron Mobility

On a glass substrate having, as formed thereon, an anode of indium tin oxide (ITO) having a thickness of 50 nm, the following thin films were laminated according to a vacuum evaporation method at a vacuum degree of 5.0×10⁻⁵ Pa to produce a device for measurement of electron mobility.

First, on ITO, aluminum (Al) was deposited at a thickness of 50 nm. Next, the first organic compound, the second organic compound and the third organic compound were co-deposited from different evaporation sources to form a layer having a thickness of 100 nm. At that time, the compounds were so co-deposited that the first organic compound accounted for 64% by weight, the second organic compound for 35% by weight, and the third organic compound for 1% by weight. Next, Liq was deposited at a thickness of 2 nm and aluminum (Al) was at a thickness of 100 nm to form a cathode, thereby producing a device for measurement of electron mobility.

Using the compounds shown in the following table as the first organic compound, the second organic compound and the third organic compound, devices 1 to 3 were produced. All the compounds used for these devices satisfy the relationship of the lowest excited singlet energy of the formula (a). In the following table, the LUMO energy of the second organic compound E_{LUMO}(2) and the LUMO energy of the third organic compound E_{LUMO}(3) are also shown. Device 1 and Device 2 do not satisfy the LUMO energy relationship of the formula (b), and the Device 3 satisfies the LUMO energy relationship of the formula (b).

TABLE 1

| | First Organic | Second Organic Compound | | Third Organic Compound | |
|---|---|---|---|---|---|
| | Compound | | E_{LUMO}(2) | | E_{LUMO}(3) |
| | Compound | Compound | [eV] | Compound | [eV] |
| Device 1 | H1 | TDF2 | −3.53 | RD-X | −3.79 |
| Device 2 | H1 | TDF1 | −3.37 | RD-X | −3.79 |
| Device 3 | H1 | TDF2 | −3.53 | RD1 | −3.40 |

Comparative Devices 1 to 3 were produced like Devices 1 to 3, but in these, the third organic compound was not used and the co-evaporation layer was formed of only the first organic compound and the second organic compound.

The electron mobility of the thus-produced Devices 1 to 3 and Comparative Devices 1 to 3 were measured. The electron mobility of Device 1 was divided by the electron mobility of Comparative Device 1 to determine the electron mobility ratio REM of Device 1. Similarly, the electron mobility ratio R EM of Device 2 and Device 3 was determined. The LUMO energy difference ΔE_{LUMO} f the second organic compound and the third organic compound was calculated as E_{LUMO}(3)-E_{LUMO}(2). In FIG. 2, the electron mobility ratio R^{EM} of each Device was plotted on the vertical axis, and ΔE_{LUMO} was on the horizontal axis. The results in FIG. 2 indicate that, when the LUMO energy of the third organic compound is smaller than the LUMO energy of the second organic compound (that is, ΔLUMO is negative), the electron mobility reduces and the electron moves slowly, but when the LUMO energy of the third organic compound is larger than the LUMO energy of the second organic compound (that is ΔLUMO is positive), the electron mobility reduction is retarded and the electron movement is hardly lowered. In other words, in the case where the relationship of the formula (b) is satisfied, the electron trap by the third organic compound is retarded.

### Examples 1 to 2, Comparative Example 1

### Production and Evaluation of Organic Electroluminescent Devices

On a glass substrate having, as formed thereon, an anode of indium tin oxide (ITO) having a thickness of 50 nm, the following thin films were laminated at a vacuum degree of 5.0×10⁻⁵ Pa in a vacuum evaporation method to produce an organic electroluminescent device.

First, on the ITO, HAT-CN was deposited at a thickness of 10 nm, then NPD was deposited thereon at a thickness of 30 nm. Next, Tris-PCz was formed at a thickness of 10 nm, and H1 was formed thereon at a thickness of 5 nm. Next, the first organic compound, the second organic compound and the third organic compound were co-deposited from different evaporation sources to form a layer having a thickness of 30 nm to be a light emitting layer. At that time, the compounds were so co-deposited that the first organic compound accounted for 64% by mass, the second organic compound for 35% by mass and the third organic compound for 1% by mass. Next, SF3-TRZ was formed at a thickness of 10 nm, and then Liq and SF3-TRZ were co-deposited from different evaporation sources to form a layer having thickness of 30 nm. The content of Liq and SF3-TRZ in the layer was 30% by mass and 70% by mass, respectively. Further, Liq was formed at a thickness of 2 nm, and then aluminum (Al) was deposited at a thickness of 100 nm to form a cathode, thereby producing an organic electroluminescent device.

The compounds shown in the following table were used as the first organic compound, the second organic compound and the third organic compound to produce organic electroluminescent devices of Examples 1 to 2 and Comparative Example 1. The compounds used in every device satisfy the relationship of first excited singlet energy of the formula (a). In the following table, the LUMO energy of the second organic compound E_{LUMO}(2) and the LUMO energy of the third organic compound E_{LUMO}(3) are shown. The organic electroluminescent device of Comparative Example 1 does not satisfy the LUMO energy relationship of the formula (b), and the organic electroluminescent devices of Examples 1 and 2 satisfy the LUMO energy relationship of the formula (b).

Of the produced organic electroluminescent devices, the external quantum efficiency (EQE) and the drive voltage (V) at 15.4 mA/cm² were measured. The results are shown in the following table. The drive voltage is a relative value ΔV based on the drive voltage in Comparative Example 1. A smaller value of ΔV means that the device drove at a low voltage. From the results shown in the following table, it is confirmed that the organic electroluminescent devices of the present invention satisfying the formula (a) and the formula (b) exhibit a high emission efficiency at a low drive voltage.

TABLE 2

| | First Organic | Second Organic Compound | | Third Organic Compound | | Performance | | |
|---|---|---|---|---|---|---|---|---|
| | Compound | | E_{LUMO}(2) | | E_{LUMO}(3) | λmax | EQE | ΔV |
| | Compound | Compound | [eV] | Compound | [eV] | [nm] | [%] | [V] |
| Comparative | H1 | TADF2 | −3.53 | RD-X | −3.79 | 618 | 1.6 | 0 |
| Example 1 | | | | | | | | |
| Example 1 | H1 | TADF3 | −3.55 | RD1 | −3.40 | 634 | 10.5 | −0.23 |
| Example 2 | H1 | TADF2 | −3.53 | RD1 | −3.40 | 634 | 6.3 | −0.17 |

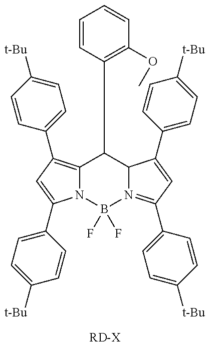

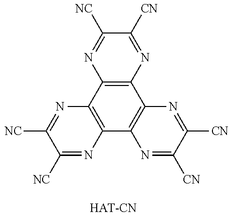 [SMILES: N#Cc1nc2c3nc(C#N)c(C#N)nc3c3nc(C#N)c(C#N)nc3c2nc1C#N]

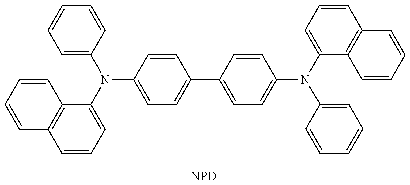 [SMILES: c1ccc(N(c2ccc(-c3ccc(N(c4ccccc4)c4cccc5ccccc45)cc3)cc2)c2cccc3ccccc23)cc1 ; "NPD"]

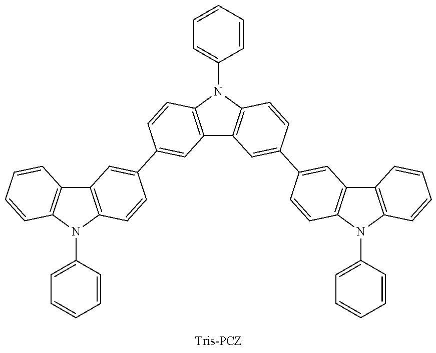 [SMILES: c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1]

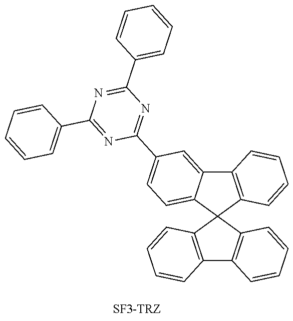 [SMILES: c1ccc(-c2nc(-c3ccccc3)nc(-c3ccc4c(c3)-c3ccccc3C43c4ccccc4-c4ccccc43)n2)cc1]

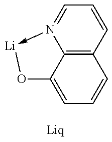

### REFERENCE SIGNS LIST

1 Substrate

2 Anode

3 Hole Injection Layer

4 Hole Transporting Layer

5 Light Emitting Layer

6 Electron Transporting Layer

7 Cathode

1. An organic electroluminescent device having an anode, a cathode, and at least one organic layer containing a light emitting layer between the anode and the cathode, wherein:
the light emitting layer contains a first organic compound, a second organic compound and a third organic compound,
the second organic compound is a delayed fluorescent material,
the maximum component of light emission from the device is light emission from the third organic compound,
the first organic compound, the second organic compound and the third organic compound satisfy the following formula (a) and the following formula (b):
E_{S1}(1)>E_{S1}(2)>E_{S1}(3) Formula (a)
E_{LUMO}(2)≤E_{LUMO}(3) Formula (b)
wherein:
E_{S1}(1) represents lowest excited singlet energy of the first organic compound,
E_{S2}(2) represents lowest excited singlet energy of the second organic compound,
E_{S1}(3) represents lowest excited singlet energy of the third organic compound,
E_{LUMO}(2) represents LUMO energy of the second organic compound,
E_{LUMO}(3) represents LUMO energy of the third organic compound.

2. The organic electroluminescent device according to claim 1, satisfying the following formula (c):
E_{LUMO}(2)≤E_{LUMO}(3)−0.13 eV Formula (c).

3. The organic electroluminescent device according to claim 1, wherein the maximum emission wavelength of the third compound is longer than 570 nm.

4. The organic electroluminescent device according to claim 1, wherein the third organic compound, E_{LUMO}(3) has a LUMO energy of larger than −3.5 eV.

5. The organic electroluminescent device according to claim 1, wherein the third organic compound is a compound represented by the following general formula (1): 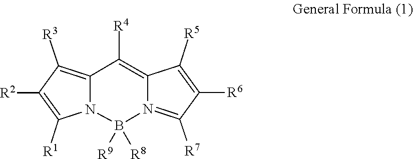
wherein R¹ to R⁷ each independently represent a hydrogen atom or a substituent; R⁸ and R⁹ each independently represent a hydrogen atom, a halogen atom, a substituted or unsubstituted alkyl group, a substituted or unsubstituted alkoxy group, a substituted or unsubstituted aryloxy group, or a cyano group.

6. The organic electroluminescent device according to claim 5, wherein at least one of R¹ to R⁷ is a group represented by the following general formula (2): 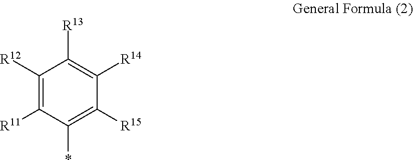
wherein R¹¹ to R¹⁵ each independently represent a hydrogen atom or a substituent, and * indicates a bonding position.

7. The organic electroluminescent device according to claim 6, wherein at least four of R¹ to R⁷ in the general formula (1) each are independently a group represented by the general formula (2).

8. The organic electroluminescent device according to claim 7, wherein R¹, R³, R⁵, and R⁷ in the general formula (1) each are independently a group represented by the general formula (2).

9. The organic electroluminescent device according to claim 5, wherein the total of the substituted or unsubstituted alkoxy group, the substituted or unsubstituted aryloxy group and the substituted or unsubstituted amino group existing in R¹ to R⁹ in the general formula (1) is 3 or more.

10. The organic electroluminescent device according to claim 5, wherein the number of the substituents having a Hammett's σp value of less than −0.2 existing in R¹ to R⁹ in the general formula (1) is 3 or more.

11. The organic electroluminescent device according to claim 1, wherein the second organic compound is a compound represented by the following general formula (3): 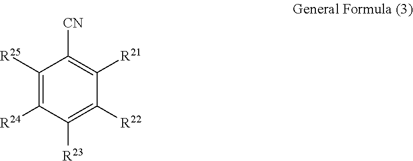
wherein one of R²¹ to R²³ represents a cyano group or a group represented by the following general formula (4), the remaining two of R²¹ to R²³ and at least one of R²⁴ and R²⁵ each independently represent a group represented by the following general formula (5), and the rest of R²¹ to R²⁵ each independently represent a hydrogen atom or a substituent, provided that the substituent is not a cyano group, a group represented by the following general formula (4) and a group represented by the following general formula (5); 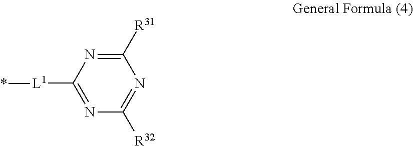
wherein L¹ represents a single bond or a divalent linking group, R³¹ and R³² each independently represent a hydrogen atom or a substituent, * indicates a bonding position, 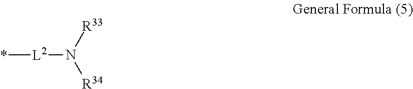
wherein L² represents a single bond or a divalent linking group, R³³ and R³⁴ each independently represent a hydrogen atom or a substituent, * indicates a bonding position.

12. The organic electroluminescent device according to claim 11, wherein one of R²¹ to R²³ in the general formula (3) is a group represented by the general formula (4).

13. The organic electroluminescent device according to claim 11, wherein one of R²¹ and R²² in the general formula (3) is a cyano group or a group represented by the general formula (4).

14. The organic electroluminescent device according to claim 11, wherein the general formula (5) is a group represented by the following general formula (6): 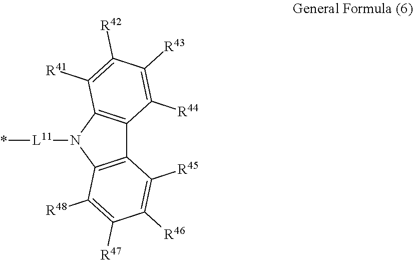
wherein L¹¹ represents a single bond or a divalent linking group, R⁴¹ to R⁴⁸ each independently represent a hydrogen atom or a substituent, * indicates a bonding position, the carbon atoms to which R⁴¹ to R⁴⁸ bond can be each independently substituted with a nitrogen atom.

15. The organic electroluminescent device according to claim 11, wherein the general formula (5) is a group represented by any of the following general formulae (7) to (12): 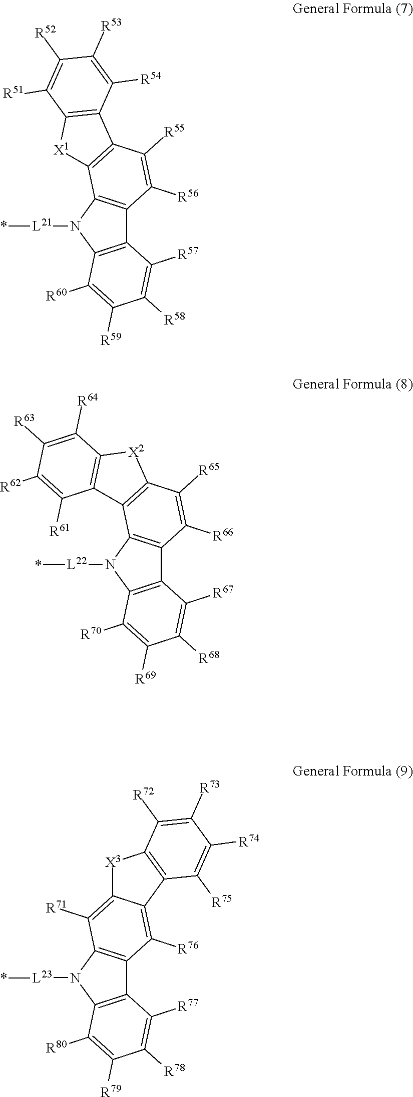 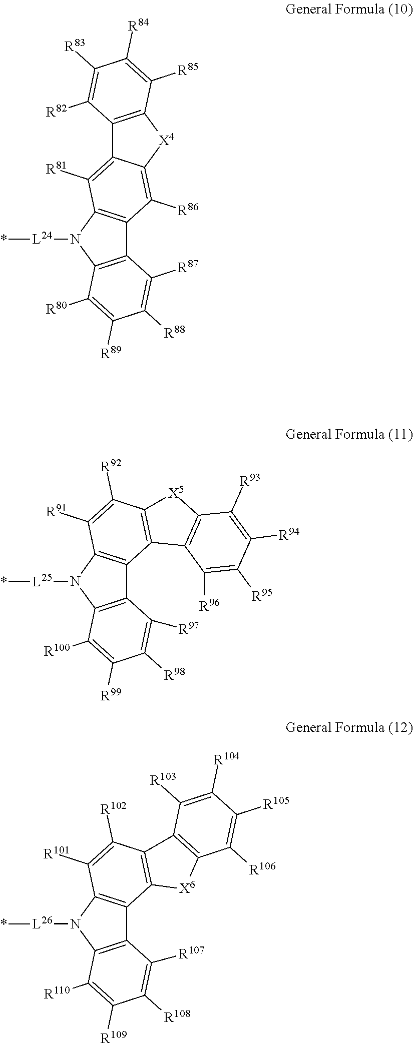
wherein L²¹ to L²⁶ each represent a single bond or a divalent linking group, R⁵¹ to R¹¹⁰ each independently represent a hydrogen atom or a substituent, X¹ to X⁶ each represent an oxygen atom, a sulfur atom or N—R, R represents a hydrogen atom or a substituent, * indicates a bonding position, the carbon atoms to which R⁵¹ to R¹¹⁰ bond each can be independently substituted with a nitrogen atom.

16. The organic electroluminescent device according to claim 1, wherein the light emitting layer contains a carbon atom, a hydrogen atom, a nitrogen atom, a boron atom, an oxygen atom and a fluorine atom, and does not contain any other element.

17. A method for designing a light emitting composition, comprising:
evaluating at least one of the light emission efficiency and the drive voltage of a composition containing a first organic compound, a second organic compound of a delayed fluorescent material and a third organic compound, and satisfying the following formula (a) and the following formula (b),
carrying out at least once evaluating at least one of the light emission efficiency and the drive voltage of a composition prepared by replacing at least one of the first organic compound, the second organic compound of a delayed fluorescent material and the third organic compound within the range satisfying the following formula (a) and the following formula (b), and
selecting a combination of compounds providing the best results of the light emission efficiency and the drive voltage evaluated,
E_{S1}(1)>E_{S1}(2)>E_{S1}(3) Formula (a)
E_{LUMO}(2)≤E_{LUMO}(3) Formula (b)
wherein:
E_{S1}(1) represents lowest excited singlet energy of the first organic compound,
E_{S1}(2) represents lowest excited singlet energy of the second organic compound,
E_{S1}(3) represents lowest excited singlet energy of the third organic compound,
E_{LUMO}(2) represents LUMO energy of the second organic compound,
E_{LUMO}(3) represents LUMO energy of the third organic compound.

18. A program embodied on a non-transitory recording medium for carrying out the method of claim 17.
